(19) United States
(12) Patent Application Publication
(10) Pub. No.: US 2025/0351372 A1
(43) Pub. Date: Nov. 13, 2025

(54) MEMORY CHIP AND MEMORY CELL ARRANGEMENTS

(71) Applicant: Ferroelectric Memory GmbH, Dresden (DE)

(72) Inventor: Stefan Müller, Dresden (DE)

(21) Appl. No.: 18/662,027

(22) Filed: May 13, 2024

(51) Int. Cl. H10B 53/20; H10B 53/30

(52) U.S. Cl. CPC H10B 53/20; H10B 53/30

(57) ABSTRACT

A memory cell arrangement and a chip including a memory cell arrangement are disclosed, including: a memory stack including a plurality of memory cell layers stacked over one another along a stacking direction, wherein each of the plurality of memory capacitor layers includes one or more memory cell arrays such that the memory stack includes one or more three-dimensional memory cell arrays; and a set of wordlines, a set of bitlines, and a set of platelines, wherein each memory cell of the one or more three-dimensional memory cell arrays is addressable by a corresponding wordline of the set of wordlines, a corresponding bitline of the set of bitlines, and a corresponding plateline of the set of platelines, and wherein each memory cell of the one or more three-dimensional memory cell arrays includes a memory capacitor that is elongated along an in-plane direction of the memory chip substantially perpendicular to the stacking direction. The sets of wordlines, bitlines, and platelines are configured to efficiently operate the memory cells of the memory cell arrangement.

### TECHNICAL FIELD

Various aspects relate to memory cell arrangements and a memory chip including a memory cell arrangement. A memory chip is described including space efficiently arranged memory cells, e.g., a memory chip including space efficiently arranged and individually addressable spontaneously polarizable memory cells.

### BACKGROUND

In general, various computer memory technologies have been developed in semiconductor industry. A fundamental building block of a computer memory may be referred to as memory cell. The memory cell may be an electronic circuit that is configured to store at least one information (e.g., bitwise). As an example, the memory cell may have at least two memory states representing, for example, a logic “1” and a logic “0”. In general, the information may be maintained (stored) in a memory cell until the memory state of the memory cell is modified, e.g., in a controlled manner. The information stored in the memory cell may be obtained (read out) by determining in which of the memory states the memory cell is residing in. At present, various types of memory cells may be used to store data. By way of example, a type of memory cell may include a thin film of a spontaneous-polarizable material, e.g., a ferroelectric material or a configuration of an anti-ferroelectric material, whose polarization state may be changed in a controlled fashion to store data in the memory cell, e.g., in a non-volatile manner. A memory cell or an arrangement of memory cells may be integrated, for example, on a wafer or a chip together with one or more logic circuits.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIG. 1A shows various aspects of a memory cell including a memory capacitor;

FIG. 1B shows various aspects of a memory cell including a memory capacitor and an access device to access the memory capacitor;

FIG. 1C shows various aspects of a circuit diagram of a memory cell arrangement including a set of memory cells addressed via two sets of control lines;

FIG. 1D and FIG. 1E each shows various aspects of a circuit diagram of a memory cell arrangement including a set of memory cells addressed via three sets of control lines;

FIG. 2A to FIG. 2G show, in various schematic views, a memory chip including a memory cell arrangement in various configurations;

FIG. 3A to FIG. 3N show, in various schematic views, aspects of a memory cell arrangement including a set of memory cells addressed via corresponding sets of control lines;

FIG. 4A to FIG. 4J show, in various schematic views, aspects of a memory cell arrangement including a set of memory cells addressed via corresponding sets of control lines;

FIG. 5A to FIG. 5C show, in various schematic views, aspects of a memory cell arrangement including a set of memory cells addressed via corresponding sets of control lines;

FIG. 6A to FIG. 6J show, in various schematic views, aspects of a memory cell arrangement including a set of memory cells addressed via corresponding sets of control lines;

FIG. 7A to FIG. 7C show, in various schematic views, aspects of a memory cell arrangement including a set of memory cells addressed via corresponding sets of control lines;

FIG. 8A to FIG. 8J show, in various schematic views, aspects of a memory cell arrangement including a set of memory cells addressed via corresponding sets of control lines;

FIG. 9A to FIG. 9G show, in various schematic views, aspects of a memory cell arrangement including a set of memory cells addressed via corresponding sets of control lines;

FIG. 10A to FIG. 10D show, in various schematic views, aspects of a memory cell arrangement and its arrangement on a carrier of a memory chip;

FIG. 11A to FIG. 11C show, in various schematic views, aspects of a memory cell arrangement and its arrangement of control lines on a carrier of a memory chip;

FIG. 12 shows, in a schematic view, aspects of a memory cell arrangement including a set of memory cells addressed via corresponding sets of control lines;

FIG. 13A to FIG. 13O show, in various schematic cross-sectional views, aspects of memory cells of a memory cell arrangement;

FIG. 14A and FIG. 14B show, in schematic cross-sectional views, aspects of a memory cell arrangement including the positioning of the memory cells relative to one another and relative to a vertical direction of a memory chip;

FIG. 15A to FIG. 15G show, in various schematic cross-sectional views, aspects of a memory capacitor of a memory cell; and

FIG. 16A and FIG. 16B each shows a schematic view of a memory cell arrangement and a sense circuit configured to operate memory cells of the memory cell arrangement, according to various aspects.

### DESCRIPTION

The following detailed description refers to the accompanying drawings that show, by way of illustration, specific details and aspects in which the invention may be practiced. These aspects are described in sufficient detail to enable those skilled in the art to practice the invention. Other aspects may be utilized and structural, logical, and electrical changes may be made without departing from the scope of the invention. The various aspects are not necessarily mutually exclusive, as some aspects may be combined with one or more other aspects to form new aspects.

Various aspects are described in connection with methods and various aspects are described in connection with devices (e.g., a memory cell, or a memory capacitor). However, it may be understood that aspects described in connection with methods may similarly apply to the devices, and vice versa.

Various aspects relate on an integration of memory cells of a computer memory efficiently on a chip (referred to as a memory chip). The integration of memory cells on a chip may include various technology aspects to be considered, e.g., cost efficiency that may include a memory design that consumes possibly least chip area. However, other aspects may include performance parameters, e.g., representing an efficient addressing of the memory cells of the computer memory. An efficient addressing may include considerations related to-on the one hand—a fast operation and an individual operation of the memory cells and-on the other hand—the design of the control lines (e.g., number, routing, and operation principle) used for the addressing of the memory cells.

A chip that includes one or more sets of memory cells and optionally respective control lines to operate one or more sets of memory cells and/or operation (e.g., read/rewrite/write/erase) circuitry (e.g., sense amplifier and/or voltage driver) may be referred to as a memory chip. In some aspects, at least a part of the control lines to operate the memory cells and/or at least part of the operation circuitry may be provided by another device (e.g., another chip) that is connected to the memory chip. A memory chip may be connected, for example, by any suitable connection type (e.g., a ball grid array, vertical connection pillars, only as example) to a processor chip to provide an efficient memory/processor chip architecture.

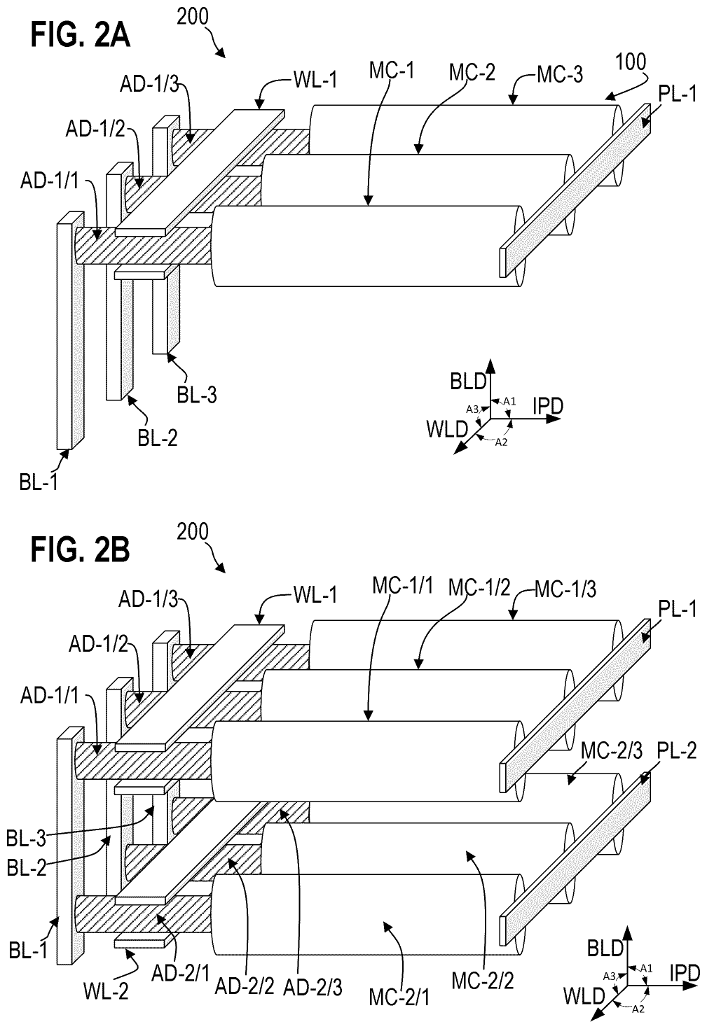

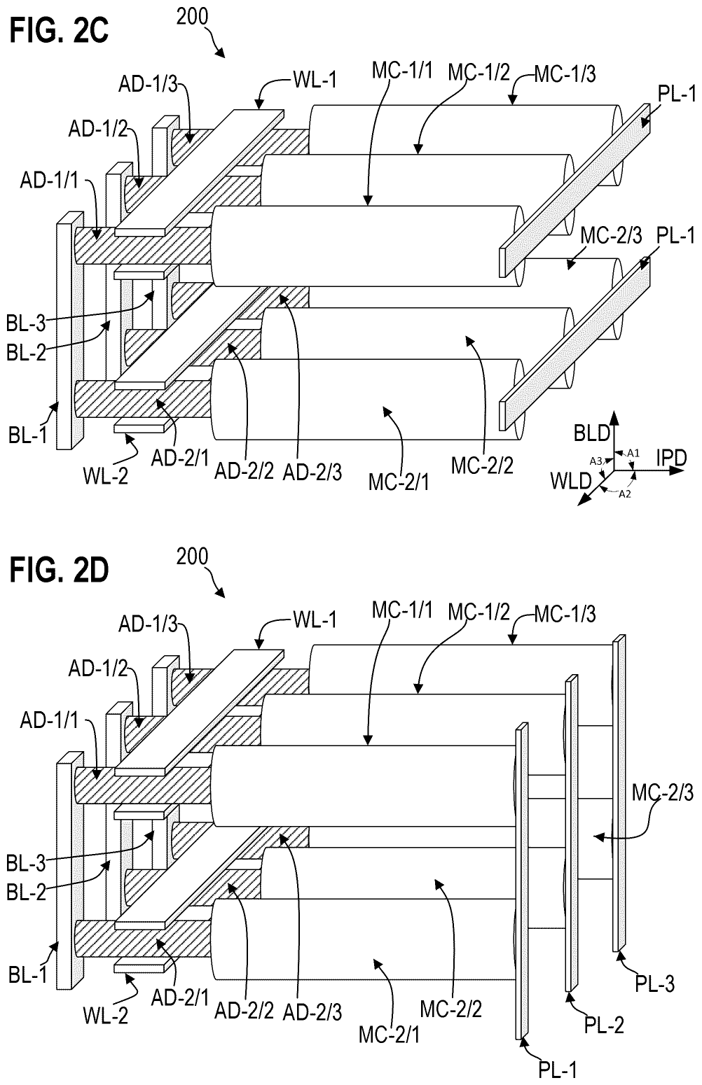

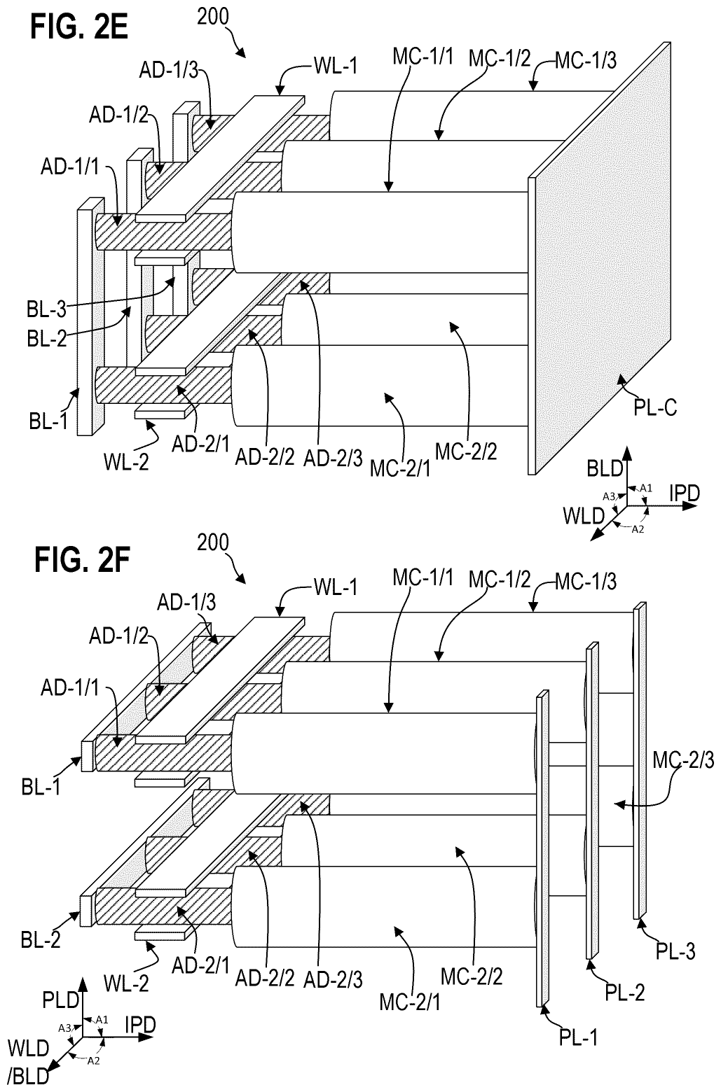

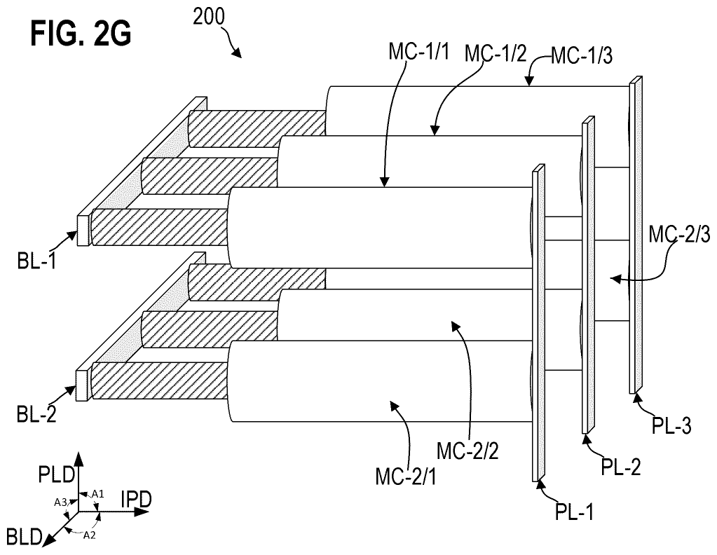

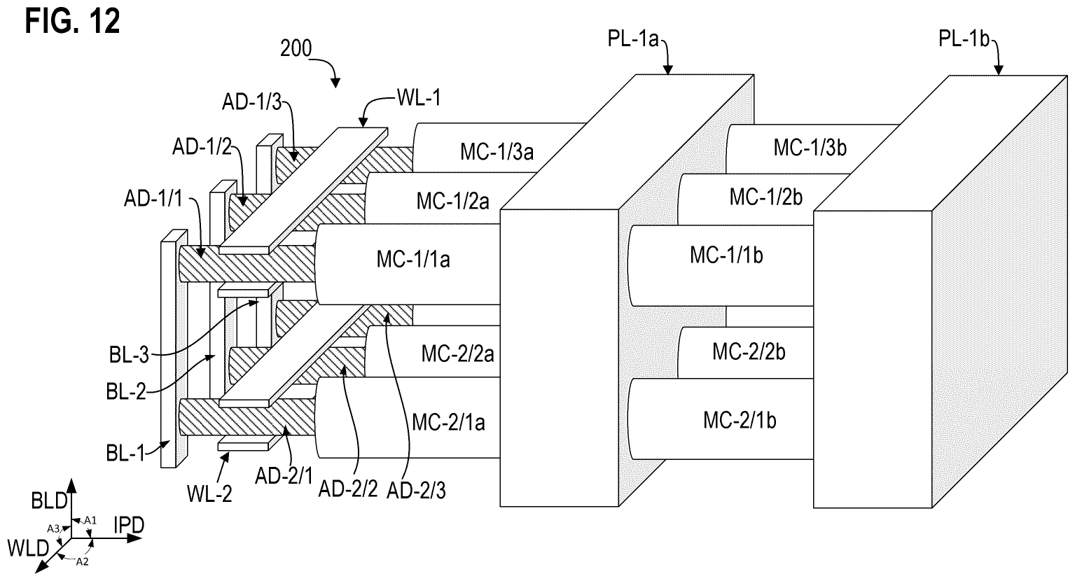

A memory cell may include a memory element. The memory element may include at least a memory material to store information in the memory element (and therefore in the memory cell). In various aspects, a memory cell may include a memory capacitor (the memory capacitor being the memory element), wherein a memory material of the memory capacitor may be a spontaneously polarizable (e.g., remanent-polarizable) memory material. A memory capacitor that is configured to store information based on polarization properties of a spontaneously polarizable (e.g., remanent-polarizable) memory material may be a ferroelectric capacitor (FeCAP). Even though a memory capacitor may be designed to remanently store a charge (referred to as switching charge) by a remanent polarization remaining in the spontaneously polarizable (e.g., remanent-polarizable) memory material included in the memory capacitor, the memory cell may additionally include an access device (e.g., an access field-effect transistor) to control a resistive coupling of the memory capacitor with at least one of the control lines (e.g., the bitline) configured to operate the memory cell. In the following, various aspects are described exemplarily for a memory cell including a single memory capacitor having a spontaneously polarizable (e.g., remanent-polarizable) memory material included therein. However, it is understood that the principles described herein are applicable to any kind device having a similar design of the memory cell, e.g., a memory cell design in which more than one of such memory capacitors are controlled via a single corresponding access device (see FIG. 12, only as an example), e.g., a memory cell design in which a memory capacitor is controlled without a corresponding access device (see FIG. 2G, only as an example).

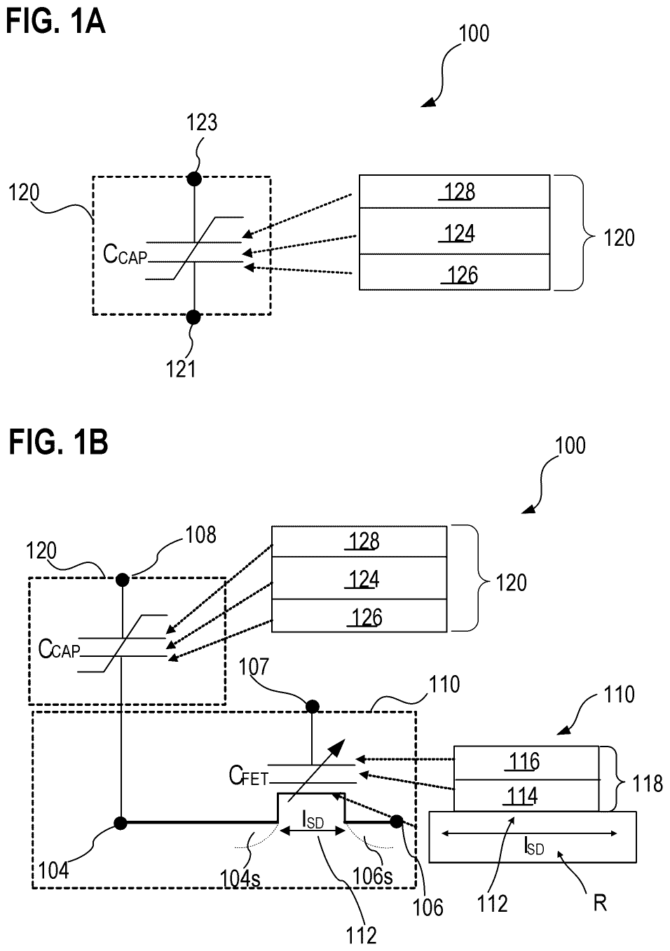

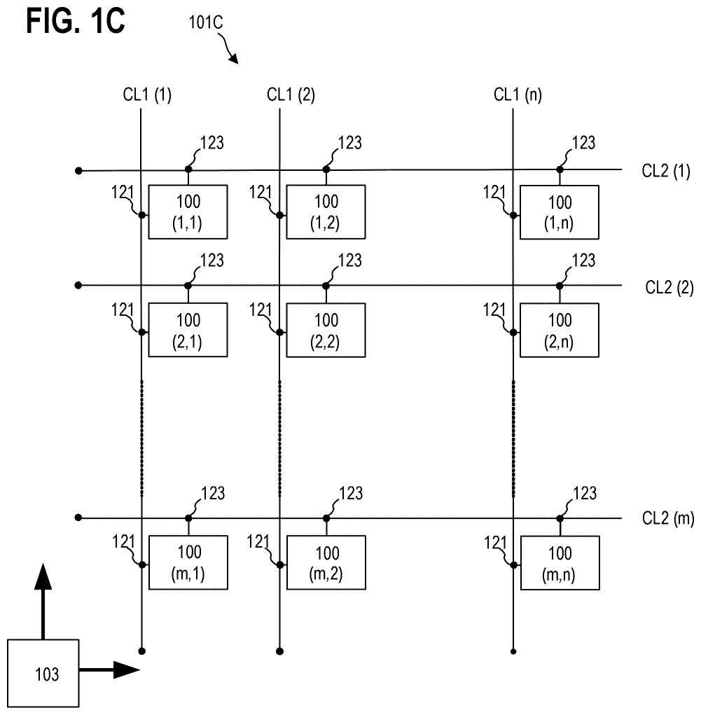

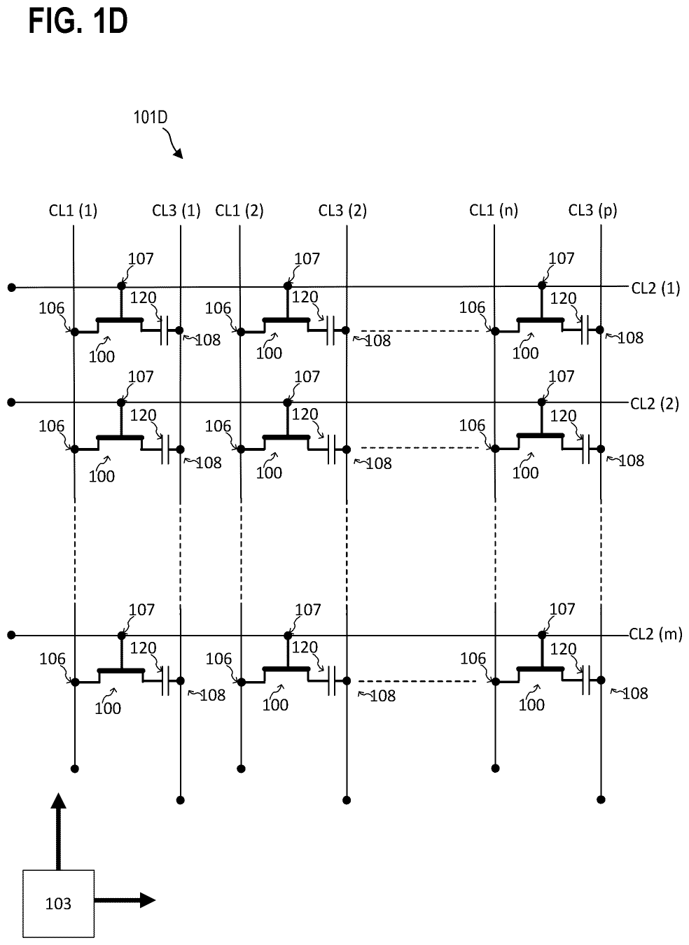

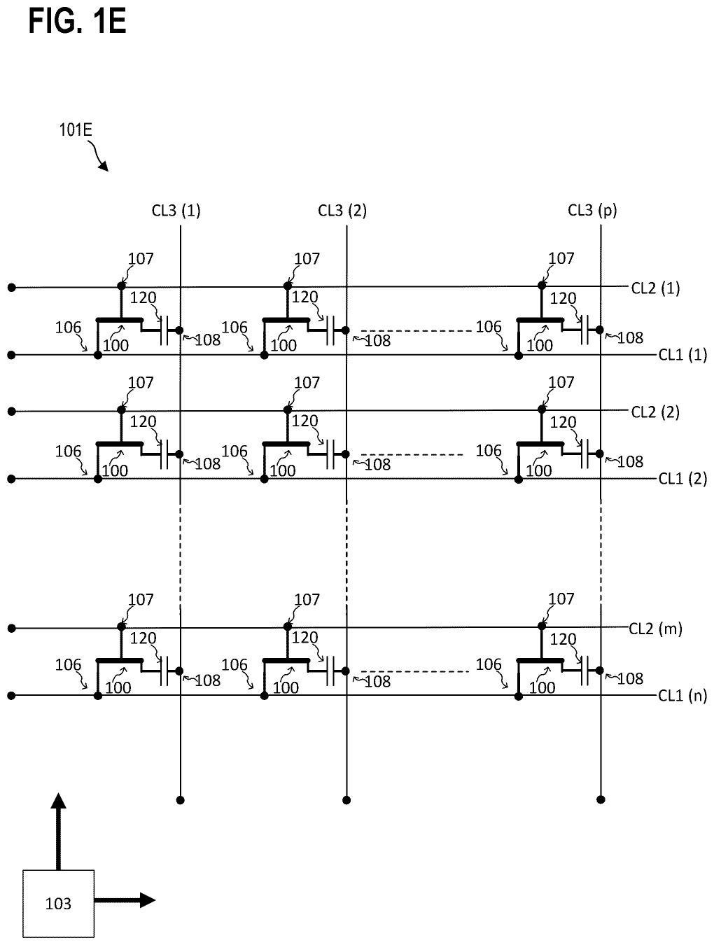

FIG. 1A shows various aspects of a memory cell 100 in a configuration without a corresponding access device. In other words, FIG. 1A shows various aspects of a memory capacitor 120 that can be a memory cell 100 or that can be part of a memory cell. The memory cell 100 may include (e.g., may be) any suitable memory capacitor 120. The memory capacitor 120 may include at least two electrodes (e.g., a first electrode 126 and a second electrode 128) and at least one memory element (e.g., a memory element 124) including (e.g., consisting of) a spontaneously polarizable (e.g., remanent-polarizable) memory material, wherein the at least two electrodes 126, 128 and the at least one memory element 124 are in a capacitive arrangement with an effective capacitance C_{CAP}.

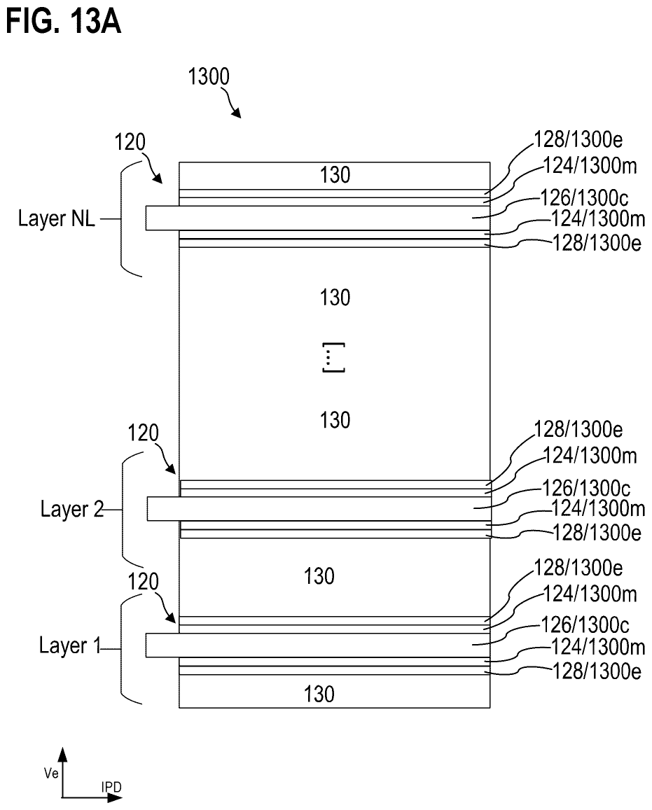

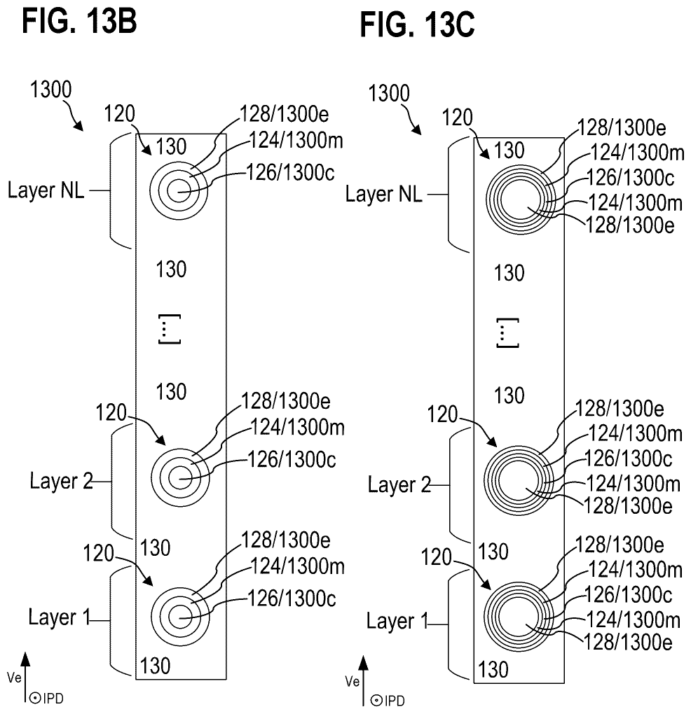

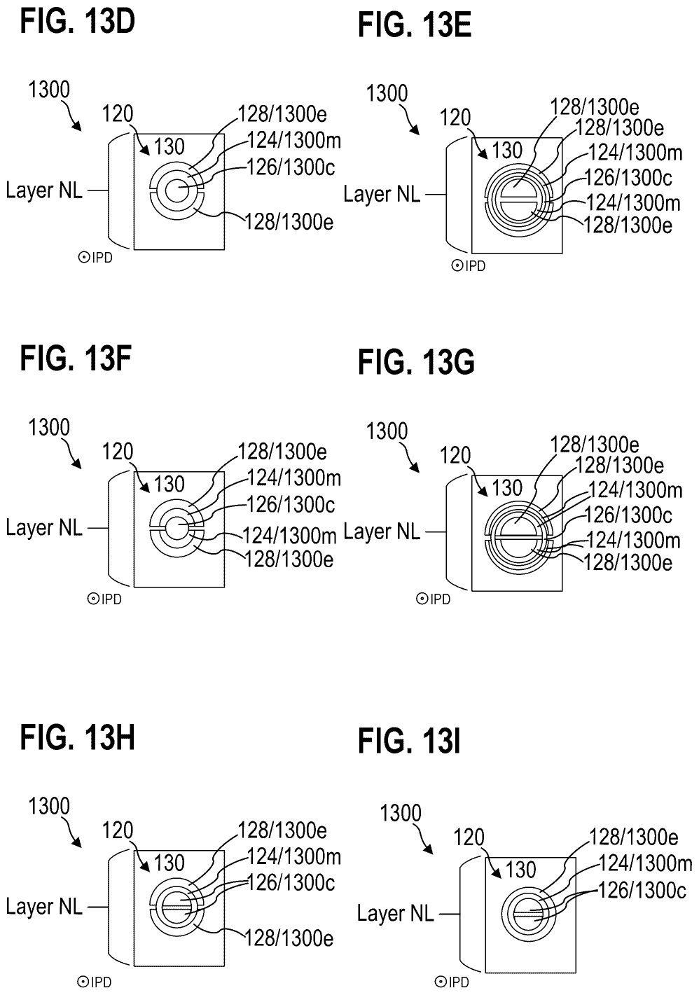

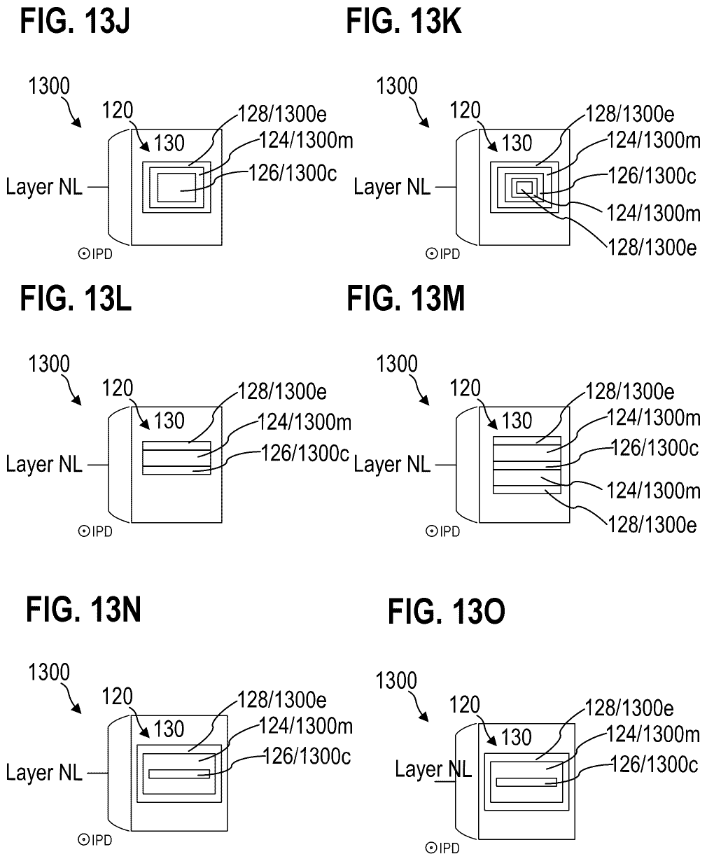

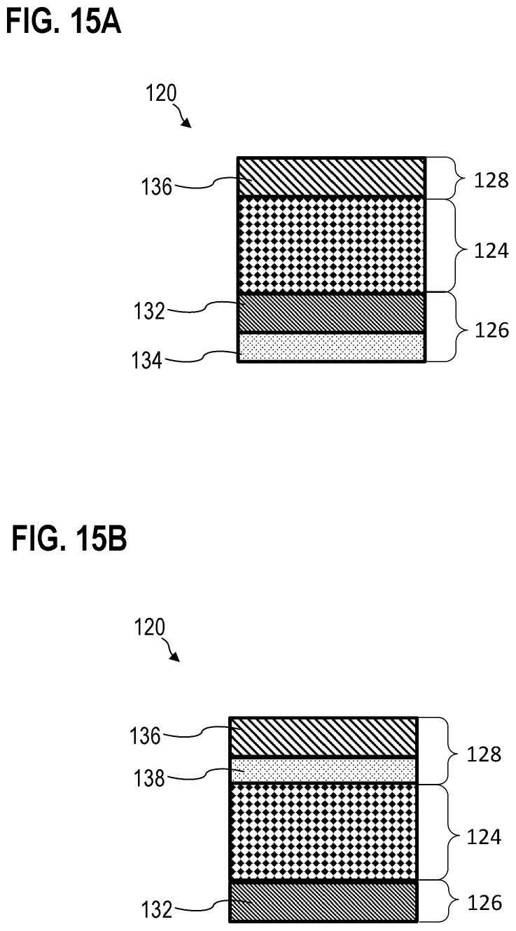

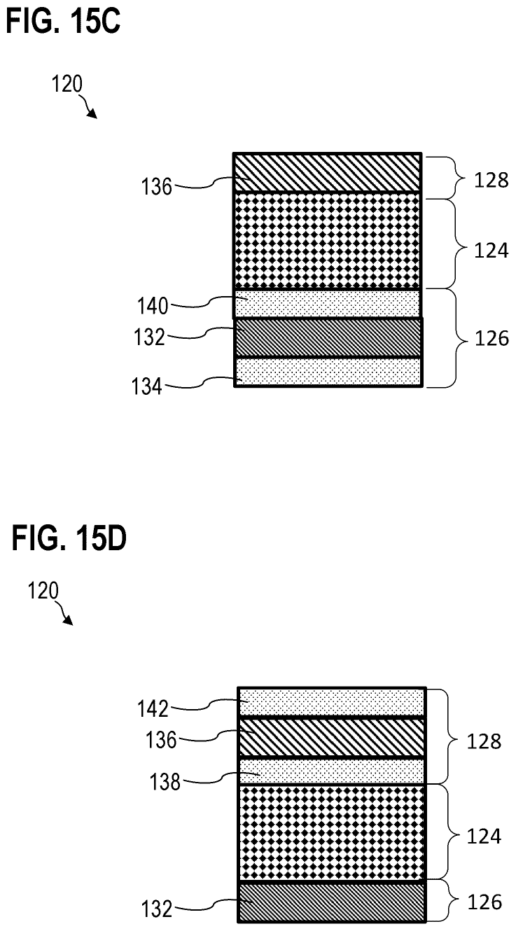

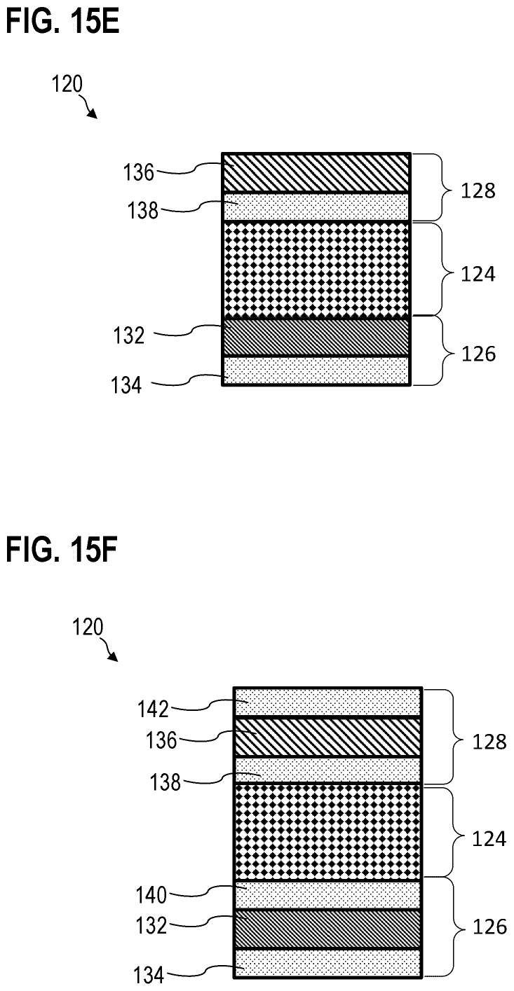

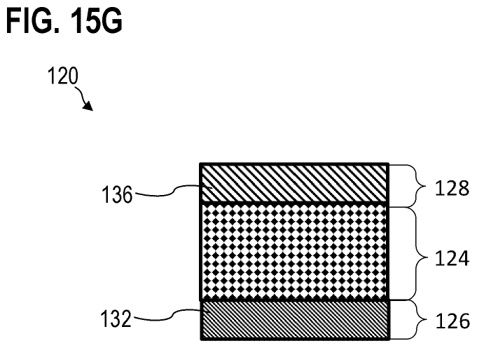

The memory capacitor 120 may be part of a memory layer stack (e.g., in 3D configuration), the memory layer stack including at least two electrode layers, e.g., the first electrode 126 may be part of a first electrode layer of the memory layer stack and the second electrode 128 may be part of a second electrode layer of the memory layer stack and at the least one memory element 124 may be part of a memory material layer of the memory layer stack disposed between the at least two electrode layers of the memory layer stack (see FIGS. 13A to 130, only as examples). The memory material layer may include (e.g., consist of) a spontaneously polarizable (e.g., a remanent-polarizable) memory material. According to various aspects, the memory element 124 may be in direct physical contact with both the first electrode 126 and the second electrode 128. According to various aspects, the memory element 124 may include one or more additional functional material layers to enhance properties of the memory capacitor 120 (see FIGS. 15A to 15G, only as examples).

In some aspects, the first electrode 126 and/or the second electrode 128 may include a respective first and/or second electrode layer stack. The electrode layer stack may include at least two material layers forming sublayers of the respective electrode layer, wherein a first material layer of the electrode layer stack is in direct physical contact with spontaneously polarizable (e.g., remanent-polarizable) memory material of the memory element 124 and wherein the first material layer of the electrode layer stack separates the spontaneously polarizable (e.g., remanent-polarizable) memory material of the memory element 124 from a second material layer of the electrode layer stack. In some aspects, the second material layer may include an electrically conductive metal (e.g., tungsten and/or titanium) or an electrically conductive metal nitride (e.g., tungsten nitride and/or titanium nitride) and the first material layer may include an electrically conductive oxide material (e.g., electrically conductive tungsten oxide W_{y}Oₓ with x and y representing a non-stochiometric material composition that makes the tungsten oxide electrically conductive). Using a multilayer electrode (e.g., an electrode layer stack including at least two material layers) may allow for fabrication of mechanically stable electrodes that provide at the same time suitable crystal structure interfaces to connect the multilayer electrode to the spontaneously polarizable (e.g., remanent-polarizable) memory material of the memory element 124, wherein the spontaneously polarizable memory material may include a spontaneously polarizable metal oxide.

According to various aspects, the memory element 124 may include (e.g., may consist of) a spontaneously polarizable (e.g., remanent-polarizable) material, as described herein. A memory element including a spontaneously polarizable material may also be referred to as spontaneously polarizable (e.g., remanent-polarizable) memory element 124. For example, the spontaneously polarizable material may be a remanent-polarizable material, such as a ferroelectric material, or a non-remanent-polarizable material, such as an anti-ferroelectric material. A memory element including a spontaneously polarizable material may be understood such that the memory element has (e.g., included in the memory capacitor 120) spontaneously polarizable properties.

The spontaneously polarizable memory element 124 may show a hysteresis in the (voltage dependent) polarization. The spontaneously polarizable memory element 124 may show non-remanent spontaneous polarization properties (e.g., may show anti-ferroelectric properties), e.g., the spontaneously polarizable memory element may have no substantial remanent polarization remaining in the case that no externally applied voltage drops over the spontaneously polarizable memory element 124. In other aspects, the spontaneously polarizable memory element 124 may show remanent spontaneous polarization properties (e.g., may show ferroelectric properties), e.g., the spontaneously polarizable memory element 124 may have a substantial remanent polarization remaining in the case that no externally applied voltage drops over the spontaneously polarizable memory element.

The terms “spontaneously polarized” or “spontaneous polarization” may be used herein, for example, with reference to the polarization capability of a material beyond dielectric polarization. A “spontaneously polarizable” (or “spontaneous-polarizable”) material may include (e.g., may be) a material that shows a remanence, e.g., a ferroelectric material, and/or a material that shows no remanence, e.g., an anti-ferroelectric material. The coercivity of the spontaneously polarizable material may be a measure of the strength of the reverse polarizing electric field that may be required to remove a remanent polarization.

A spontaneous polarization (e.g., a remanent or non-remanent spontaneous polarization) may be evaluated via analyzing one or more hysteresis measurements (e.g., hysteresis curves), e.g., in a plot of polarization, P, versus electric field, E, in which the material is polarized into opposite directions. The polarization capability of a material (dielectric polarization, spontaneous polarization, and a remanence characteristics of the polarization) may be analyzed using capacity spectroscopy, e.g., via a static (C-V) and/or time-resolved measurement or by polarization-voltage (P-V) or positive-up-negative-down (PUND) measurements.

In a memory capacitor, the amount of charge stored therein may be used to define a memory state thereof, e.g., first amount of charge stored in the capacitor structure may define a first memory state and a second amount of charge stored in the capacitor structure may define a second memory state. In general, a remanent polarization (also referred to as retentivity or remanence) may be present in a material layer in the case that the material layer may remain polarized upon reduction of an applied electric field (E) to zero, therefore, a certain value for the electrical polarization (P) of the material layer may be detected. Illustratively, a polarization remaining in a material when the electric field is reduced to zero may be referred to as remanent polarization. Therefore, the remanence of a material may be a measure of the residual polarization in the material in the case that an applied electric field is removed. In general, ferroelectricity and anti-ferroelectricity may be concepts to describe a spontaneous polarization of a material similar to ferromagnetism and anti-ferromagnetism used to describe remanent magnetization in magnetic materials. According to various aspects, an electric coercive field, Ec, (also referred to as coercive field) may be or may represent the electric field required to depolarize a remanent-polarizable layer.

According to various aspects, the spontaneously polarizable memory element 124 may include (e.g., may consist of) of a remanent-polarizable material. A remanent-polarizable material may be a material that is remanently polarizable and shows a remanence of the spontaneous polarization, such as a ferroelectric material. In other aspects, remanent-polarizable material may be a material that is spontaneously polarizable and that shows no remanence, e.g., an anti-ferroelectric material under the additional conditions that measures are implemented to generate an internal electric-field within the anti-ferroelectric material. Hence, an inherently non-remanently polarizable material, such as an anti-ferroelectric (“antiferroelectric”) material may exhibit remanent-polarizable properties within certain structures. An internal electric-field within an anti-ferroelectric material may be caused (e.g., applied, generated, maintained, as examples) by various strategies: e.g., by implementing floating nodes that may be charged to voltages different from zero volts, and/or by implementing charge storage layers, and/or by using doped layers, and/or by using electrode layers that adapt electronic work-functions to generate an internal electric field, by using an encapsulation structure which introduces compressive stress or tensile stress onto the memory element 124, thereby establishing the spontaneously polarizable properties, only as examples. The spontaneously polarizable memory element 124 including (e.g., being made of) a remanent-polarizable material may be referred to herein as remanent-polarizable memory element (e.g., implemented as remanent-polarizable layer in a memory layer stack).

In some aspects, the spontaneous-polarizable material (e.g., a remanent-polarizable material) may include one or more metal oxides. The spontaneous-polarizable material may include at least one of HfₐO_{b}, ZrₐO_{b}, SiₐO_{b}, YₐO_{b}, as examples, wherein the subscripts “a” and “b” may indicate the stoichiometry of the spontaneous-polarizable material.

In some aspects, the spontaneous-polarizable material (e.g., the remanent-polarizable material) may include (e.g., may be) a ferroelectric material, illustratively the memory element 124 may be ferroelectric memory element (for example a ferroelectric layer). A ferroelectric material may be an example of a material used in a spontaneously polarizable memory element (e.g., in a remanent-polarizable element). The ferroelectric material may include (e.g., may be) at least one of the following: hafnium oxide (ferroelectric hafnium oxide, HfO₂), zirconium oxide (ferroelectric zirconium oxide, ZrO₂), a (ferroelectric) mixture of hafnium oxide and zirconium oxide (also referred to as hafnium zirconium oxide. Ferroelectric hafnium oxide may include any form of hafnium oxide that may exhibit ferroelectric properties. Ferroelectric zirconium oxide may include any form of zirconium oxide that may exhibit ferroelectric properties. This may include, for example, hafnium oxide, zirconium oxide, a solid solution of hafnium oxide and zirconium oxide (e.g., but not limited to it, a 1:1 mixture) or hafnium oxide and/or zirconium oxide doped or substituted with one or more of the following elements (non-exhaustive list): silicon, aluminum, gadolinium, yttrium, lanthanum, strontium, zirconium, any of the rare earth elements or any other dopant (also referred to as doping agent) that is suitable to provide or maintain ferroelectricity in hafnium oxide or zirconium oxide. The ferroelectric material may be doped at a concentration from about 2 mol % to about 6 mol %, only as an example.

In some aspects, the spontaneous-polarizable material may include hafnium oxide (e.g., may consist of hafnium oxide, hafnium zirconium oxide (e.g., Hf_{0.75} Zr_{0.25} O₂ or Hf_{0.5} Zr_{0.5} O₂), hafnium silicon oxide, hafnium lanthanum oxide, or hafnium lanthanum zirconium oxide), zirconium oxide, and/or aluminum nitride (e.g., may consist of aluminum nitride, aluminum scandium nitride or aluminum boron nitride). In some aspects, the spontaneous-polarizable material may include (e.g., may consist of) Hf₁₋ₓZrₓO₂, Hf₁₋ₓSiₓO₂, Hf₁₋ₓLaₓO₂, Hf_{1-x-y}LaₓZr_{y}O₂, Al₁₋ₓScₓN, or Al₁₋ₓBₓN.

According to various aspects, the memory cell described herein may be configured complementary metal oxide semiconductor (CMOS) compatible, e.g., including standard CMOS-materials only and may require no special integration considerations (e.g., no special thermal budget which may avoid diffusion and/or contamination during manufacturing). CMOS compatible spontaneously polarizable materials may be used to implement the one or more memory cell based on, for example, HfO₂ and/or ZrO₂. Doped HfO₂ (e.g., Si:HfO₂ or Al:HfO₂) or other suitable spontaneously polarizable materials may allow for an integration of the spontaneously polarizable layer via known integration schemes.

According to various aspects, the memory capacitor 120 may be a ferroelectric capacitor or an anti-ferroelectric capacitor. An information may be stored by the memory capacitor via at least two remanent polarization states of the memory capacitor 120. The programming of the memory capacitor 120 (illustratively the storage of information therein) may be carried out by providing (e.g., applying) an electric field to thereby set or change the remanent polarization state of the spontaneously polarizable memory element 124. Illustratively, the spontaneous-polarizable material (e.g., a ferroelectric material, e.g., an anti-ferroelectric material) may be used to store data in non-volatile manner in integrated circuits.

It may be understood that, even though various aspects refer to a memory element including (e.g., being made of) a spontaneously polarizable material, other memory elements whose state may be altered by an electric field provided across a capacitive memory structure may be used as long as the structure of the material can be changed via application of an electric field, as described herein.

The memory capacitor 120 may have a capacitive configuration with a (first) capacitance, C_{CAP}, associated therewith (see equivalent circuit 100e in FIG. 1A with respect to the capacitive properties). The first electrode 126, the memory element 124, and the second electrode 128 may form a memory capacitor layer stack. In some aspects, the memory capacitor layer stack may be a planar layer stack; however, other shapes may be suitable as well, e.g., curved shapes, angled shapes, coaxially aligned shapes, as examples. Illustratively, the memory capacitor 120 may include planar electrodes, or, in other aspects, the memory capacitor 120 may be configured as 3D capacitor including, for example, angled or curved electrodes.

The memory cell 100 exemplarily illustrated in FIG. 1A may be a two-terminal memory cell (see FIG. 1C, only as an example), wherein the first electrode 126 may be a first terminal 121 of the two-terminal memory cell or may be coupled to a first terminal 121 two-terminal memory cell and wherein the second electrode 128 may be a second terminal 123 two-terminal memory cell or may be coupled to a second terminal 123 two-terminal memory cell.

FIG. 1B illustrates the memory cell 100 in a configuration that includes an access device 110. As illustrated exemplarily, a field-effect transistor structure FET can be used as access device 110. The memory capacitor 120 is coupled to the access device 110, e.g., the access device 110 can be configured to decouple the memory capacitor 120 from a terminal of the memory cell 100. The field-effect transistor structure FET may include a gate structure 118, wherein the gate structure 118 may include a gate isolation 114 and a gate electrode 116. The gate structure 118 is illustrated exemplarily as a planar gate stack; however, it is understood that the planar configuration shown in FIG. 1B is only an example, and that other field-effect transistor designs may include a gate structure 118 with a non-planar shape, for example a trench gate transistor design, a vertical field-effect transistor design, or other designs, such as a fin-FET design or a gate-all-around design. The field-effect transistor structure FET may include a first source/drain region 104s (e.g., a drain region) and a second source/drain region 106s (e.g., a source region).

The gate structure 118 may define a channel region 112, e.g., provided in a semiconductor portion (e.g., in a semiconductor layer). The gate structure 118 may allow for a control of an electrical behavior (e.g., a resistance R) of the channel region 112, e.g., a current flow in the channel region 112 may be controlled (e.g., allowed, increased, prevented, decreased, etc.). In some aspects, the gate structure 118 may, for example, allow to control (e.g., allow or prevent) a source/drain current, IsD, from a first source/drain region of the field-effect transistor structure FET to a second source/drain region of the field-effect transistor structure FET (the source/drains are provided in or adjacent to the channel but are not shown in FIG. 1B). The channel region 112 and the source/drain regions may be formed, e.g., via doping one or more semiconductor materials or by the use of intrinsically doped semiconductor materials, within a layer and/or over a layer. With respect to the operation of the field-effect transistor structure FET, a voltage may be provided at the gate electrode 116 to control the current flow, IsD, in the channel region 112, the current flow, IsD, in the channel region 112 being caused by voltages supplied via the source/drain regions.

According to various aspects, the channel region 112 may be a polysilicon channel region that has a channel length of a least possible length to avoid undesired (e.g., lateral) space consumption related with the channel length. In the case that the memory capacitor 120 is configured to store information based on remanent polarization, the access device 110 may be configured to allow for an off-current through the access device 110 of greater than 10⁻¹⁴ ampere. Since the off-current through the access device 110 of greater than 10-14 ampere can be comparatively high without disturbing the function of the memory cell operation, e.g., compared to memory capacitors having solely a dielectric capacitance and showing no remanent polarization, the channel length of the field-effect transistor structure FET of the memory cell 100 can be implemented comparatively short and therefore the memory cell 100 including the access device 110 can be implemented in a chip area saving manner.

According to various aspects, the semiconductor portion (illustratively, where the channel region 112 may be formed), may include silicon, e.g., in some aspects polysilicon. However, other semiconductor materials of various types may be used in a similar way, e.g., germanium, Group III to V (e.g., SiC), or other types, including for example carbon nanotubes, organic materials (e.g., organic polymers), etc. In various aspects, the semiconductor portion may be a deposited layer of silicon, e.g., polysilicon, (e.g., p-type doped or n-type doped). In other aspects, the semiconductor portion may be provided by a semiconductor structure, e.g., by one or more semiconductor fins, one or more semiconductor nanosheets, one or more semiconductor nanowires, etc., formed over a carrier.

The gate electrode 116 may include an electrically conductive material, for example, a metal, a metal alloy, a degenerate semiconductor (in other words a semiconductor material having such a high level of doping that the material acts like a metal and not anymore as a semiconductor), and/or the like. As an example, the gate electrode 116 may include or may be made of aluminum. As another example, the gate electrode 116 may include or may be made of polysilicon. According to various aspects, the gate electrode 116 may include one or more electrically conductive portions, layers, etc. The gate electrode 116 may include, for example, one or more metal layers (also referred to as a metal gate), one or more polysilicon layers (also referred to as poly-Si-gate), etc. A metal gate may include, for example, at least one work-function adaption metal layer disposed over the gate isolation 114 and an additional metal layer disposed over the work-function adaption metal layer. A poly-Si-gate may be, for example, p-type doped or n-type doped. The gate structure 118 may surround the channel region partially or completely with respect to a plane substantially perpendicular to the current flow, IsD, direction, e.g., the gate structure 118 may have a direct physical contact to at least two opposing surfaces of the channel region 112.

The gate isolation 114 may be configured to provide an electrical separation of the gate electrode 116 from the channel region 112 and further to influence the channel region 112 via an electric field generated by the gate electrode 116. The gate isolation 114 may include one or more electrically insulating layers, as an example. Some designs of the gate isolation 114 may include at least two layers including different materials, e.g., a first gate isolation layer (e.g., a first dielectric layer including a first dielectric material) and a second gate isolation layer (e.g., a second dielectric layer including a second dielectric material distinct from first dielectric material).

The memory cell 100 exemplarily illustrated in FIG. 1B may be a three-terminal memory cell (see FIG. 1D and FIG. 1E, only as examples). The memory cell 100 may have a first terminal 106 (e.g., a source terminal, e.g., a bitline terminal), a second terminal 107 (e.g., a gate terminal, e.g., a wordline terminal), a storage node 104, and a third terminal 108 (e.g., a memory capacitor terminal, e.g., a plateline terminal). The first source/drain region 104s of the field-effect transistor structure FET may provide at least a part of the storage node 104 of the memory cell 100 or may be connected to the storage node 104 of the memory cell 100. The first electrode 126 of the memory capacitor 120 may provide at least a part of the storage node 104 of the memory cell 100 or may be connected to the storage node 104 of the memory cell 100. The second source/drain region 106s of the field-effect transistor structure FET may provide at least a part of the first terminal 106 of the memory cell 100 or may be connected to the first terminal 106 of the memory cell 100. The gate electrode 116 of the gate structure 118 of the field-effect transistor structure FET may provide at least a part of the second terminal 107 of the memory cell 100 or may be connected to the second terminal 107 of the memory cell 100. The second electrode 128 of the memory capacitor 120 may be at least a part of the third terminal 108 of the memory cell 100 or may be connected to the third terminal 108 of the memory cell 100.

As illustrated by the circuit equivalent in FIG. 1B, a (second) capacitance, CFET, may be associated with the field-effect transistor structure FET. Illustratively, the channel region 112, the gate isolation 114, and the gate electrode 116 may have a capacitance, CFET, associated therewith, originating from the conductive regions (the channel region 112 and the gate electrode 116) separated from one another by the gate isolation 114. Further illustratively, the channel region 112 may be considered as a first capacitor electrode, the gate electrode 116 as a second capacitor electrode, and the gate isolation 114 as a dielectric medium between the two capacitor electrodes. The capacitance, CFET, of the field-effect transistor structure FET may define one or more operating properties of the field-effect transistor structure FET. The configuration of the field-effect transistor structure FET (e.g., of the gate isolation 114) may be adapted according to a desired behavior or application of the field-effect transistor structure FET during operation (e.g., according to a desired capacitance).

In general, the capacitance, C, of a planar capacitor structure may be expressed as,

$$C = {ε}_{0} {ε}_{r} \frac{A}{d} ,$$

with ε₀ being the relative permittivity of the vacuum, A being the effective area of the capacitor, d being the distance of the two capacitor electrodes from one another, and & being the relative permittivity of the dielectric material disposed between two capacitor electrodes assuming that the whole gap between the two capacitor electrodes is filled with the dielectric material. It is noted that the capacitance of a non-planar capacitor structure or of a modified variant of a planar capacitor structure may be calculated based on equations known in the art, commonly by assuming the geometric projection of the two electrodes on each other as the effective area of the capacitor. The memory capacitor 120 of a memory cell including a spontaneously polarizable memory element 124 may have a dielectric capacitance less than 10 fF (ten femtofarad). However, an effective capacitance (defined by delta Q over delta V) including both dielectric and a contribution from a switching of the spontaneous polarization may be greater than 10 fF (ten femtofarad). The effective capacitance is greater than the dielectric capacitance since a switching charge delta Q is caused by switching the memory capacitor 120 into another polarization state based on a switching voltage delta V. In memory technology as described herein, this may allow for a use of smaller memory capacitors compared to technology based on dielectric capacitors that show no spontaneous polarization switching.

According to various aspects, a memory cell may be addressed via the corresponding access device 110, for example, via the field effect transistor structure FET, such as an n-type or p-type field-effect transistor. However, a transmission gate, such as an n-type-based or p-type-based transmission gate, or any other suitable access device 110 may be used alternatively. An access device 110 may have a threshold voltage associated therewith. A threshold voltage of an access device 110 may be defined by the properties of the access device, such as the material(s), the doping(s), etc., and it may thus be a (e.g., intrinsic) property of the access device 110.

According to various aspects, the residual polarization of the memory element 124 (e.g., the polarization of the spontaneously polarizable material of the memory element 124) may define the memory state a memory cell is residing in. According to various aspects, a memory cell may reside in a first memory state in the case that the memory element is in a first polarization state, and the memory cell may reside in a second memory state in the case that the memory element is in a second polarization state (e.g., opposite to the first polarization state). As an example, the polarization state of the memory element may determine the amount of charge stored in the memory capacitor 120. The amount of charge stored in the memory capacitor 120 may be used to define a memory state of the memory cell. A current flow (e.g., a switching current) through nodes (e.g., through the second terminal 106) to which the access device 110 couples the memory capacitor 120 may be used to determine the memory state in which the memory cell is residing in. In some aspects, the switching current may be caused by applying a switching voltage drop over the memory capacitor 120 (e.g., between the storage node 104 and the third terminal 108) and the switching current may develop—as long as the access device 110 is active (e.g., controlled by a voltage at the second terminal) and electrically conductively connects the storage node 104 and the first terminal with one another—a read voltage at the floating bitline connected to the first terminal 106 to read out the memory capacitor 120.

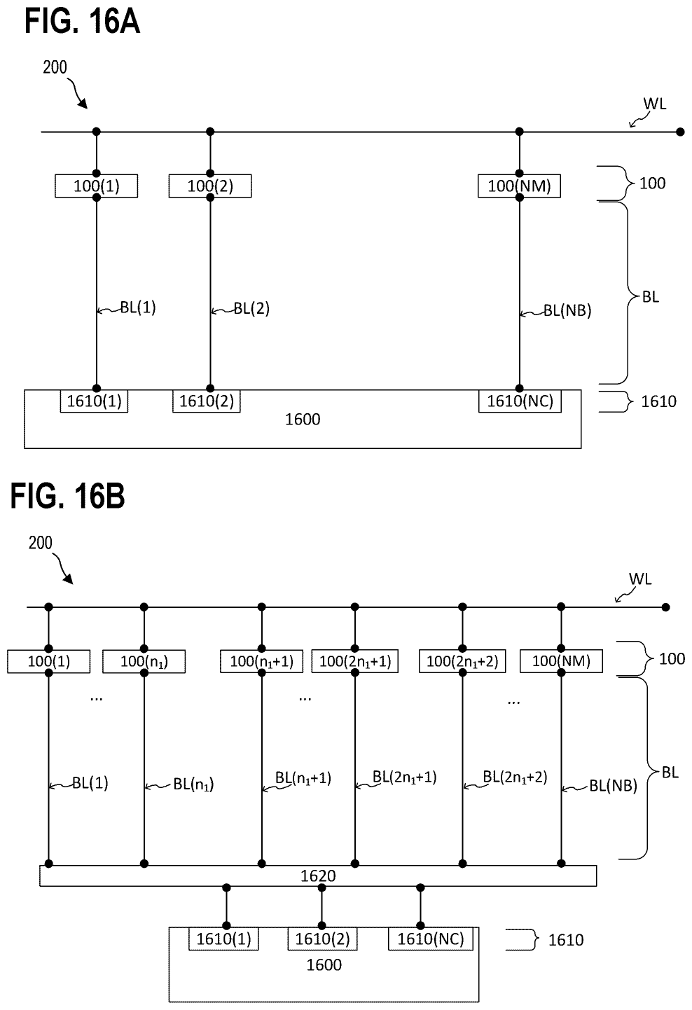

According to various aspects, a memory device (e.g., a memory chip) or a memory cell arrangement may include a set of memory cells and a controller (e.g., a memory controller, e.g., a control circuit 103 as shown in FIGS. 1C to 1E, e.g., a sense circuit 1600 as shown in FIGS. 16A and 16B) configured to operate (e.g., read and write) memory cells of a memory cell arrangement. It is noted that some aspects are described herein with reference to a memory cell of a memory chip and/or with reference to a memory cell of memory cell arrangement; it is understood that a memory chip and/or a memory cell arrangement may include a plurality of such described memory cells according to various aspects that can be operated in the same way by the controller, e.g., at the same time or in a time sequence. A memory cell arrangement may further include respective sets of control lines and voltage supply levels configured to operate the memory cells of the memory chip and/or the memory cell arrangement.

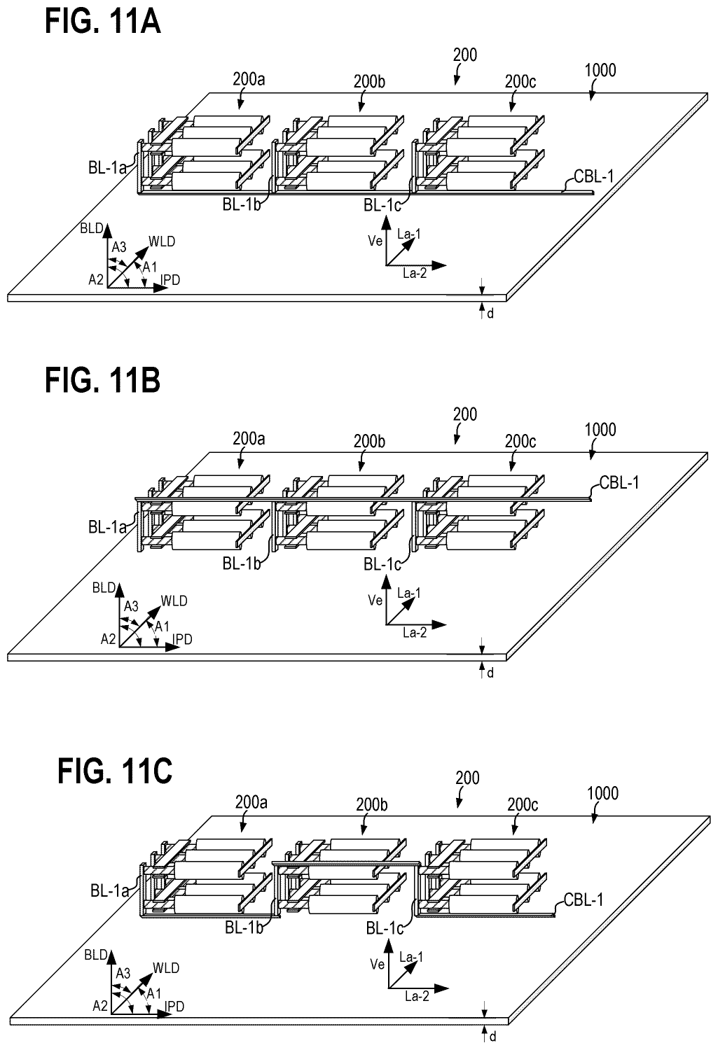

It is noted that a memory cell arrangement is usually configured in a planar matrix-type arrangement, wherein lateral columns and lateral rows define the addressing of the memory cells according to the control lines connecting respectively subsets of memory cells of the memory cell arrangement along the lateral rows and lateral columns of the matrix-type arrangement. However, as described herein, a three-dimensional matrix-type arrangement, wherein (lateral) columns, (lateral) rows, and (vertical) stacks define the addressing of the memory cells according to the control lines connecting respectively subsets of memory cells of the memory cell arrangement along the rows, columns, and stacks of the matrix-type arrangement. In some aspects, neighboring three-dimensional matrix-type arrays of memory cell are connected by the control lines to a logical memory cell array that is greater than a single three-dimensional matrix-type array (see FIGS. 11A to 11C for example), in particular, this may be useful in the case that the number of stacks is lower than the desired number of memory cells in stacking direction that are to be logically addressed (e.g., that are to be part of a same logic sector). As an example, in the case that a control line running along the stacking direction shall logically address and connect a number of memory cells with one another (e.g., it may be desired that a wordline may logically address 512 memory cells, e.g., it may be desired that a bitline may logically address 1024 memory cells), and the number of stacks and therefore the number of stacked memory cells is lower than the number of memory cells to be logically addressed, this control line may connect a number of memory cells of a plurality of neighboring three-dimensional matrix-type arrays of memory cells (e.g., if the number of stacks is 64, it may be desired that a wordline may logically address 512 memory cells of 8 neighboring three-dimensional matrix-type arrays, e.g., if the number of stacks is 128, it may be desired that a wordline may logically address 512 memory cells of 4 neighboring three-dimensional matrix-type arrays; e.g., if the number of stacks is 64, it may be desired that a bitline may logically address 1024 memory cells of 16 neighboring three-dimensional matrix-type arrays, e.g., if the number of stacks is 128, it may be desired that a bitline may logically address 1024 memory cells of 8 neighboring three-dimensional matrix-type arrays, only as an example).

In general, a memory cell arrangement may include a plurality of memory cells, which may be accessed individually or on groups via a corresponding addressing scheme. The matrix architecture may be, for example, referred to as “OR”, “AND”, “NOR”, or “NAND” architecture, depending on the way neighboring memory cells are connected to each other, i.e., depending on the way the terminals of neighboring memory cells are shared, but are not limited to these two types (another type is for example an “AND” architecture). For example, in a NAND architecture the memory cells may be organized in sectors (also referred to as blocks) of memory cells, wherein the memory cells are serially connected in a string (e.g., source and drain regions are shared by neighboring transistors), and the string is connected to a first control line and a second control line. For example, groups of memory cells in a NAND architecture may be connected in series with one another. In a NOR architecture the memory cells may be connected in parallel with one another. A NAND architecture may thus be more suited for serial access to data stored in the memory cells, whereas a NOR architecture may be more suited for random access to data stored in the memory cells.

The one or more memory cells described herein (e.g., as part of a memory cell arrangement or of a memory chip) may be used in connection with any type of suitable controller, e.g., a controller that may generate only two or only three different voltage levels for writing the memory cell (e.g., for writing one or more memory cells of a memory cell arrangement). However, in other aspects, more than four different voltage levels may be used for operating (e.g., for reading) the memory cell or for operating one or more memory cells of a memory cell arrangement.

FIG. 1C shows a schematic view of a memory cell arrangement 101C including a set of two-terminal memory cells according to various aspects. Each two-terminal memory cell 100 may be configured, for example, as described with reference to FIG. 1A. The memory cell arrangement 101C may include a logically addressable array of N times M memory cells. “N” may be any integer number greater than one. “M” may be any integer number greater than one. The memory cell arrangement 101C may include a first set of control lines CL1(n=1 to N) and a second set of control lines CL2(m=1 to M) for individually addressing one or more memory cells 100 of the set of memory cells. The memory cell arrangement 101C may include a control circuit 103 (e.g., including a read-out circuit and/or a write circuit). The control circuit 103 may be configured to apply a first voltage at the first terminal 121 of a memory cell 100(m, n) via the corresponding control line CL1(n) of the first set of control lines and to apply a second voltage at the second terminal 123 of the memory cell 100(m, n) via the corresponding control line CL2(m) of the second set of control lines in order to address the memory cell 100(m, n). In a three-dimensional configuration, a plurality of such memory cell arrangements 101C may be stacked over one another and addressed by corresponding sets of control lines, as described herein.

FIG. 1D shows a schematic view of a memory cell arrangement 101D including a set of three-terminal memory cells according to various aspects. Each three-terminal memory cell 100 may be configured, for example, as described with reference to FIG. 1B. The memory cell arrangement 101D may include a plurality, n, of first control lines CL1(n), for example, a plurality of bitlines. The memory cell arrangement 101D may include a plurality, m, of second control lines CL2(m), for example, a plurality of wordlines. The first control lines CL1(n) and the second control lines CL2(m) may be configured to address the respective access device 110 of a respective memory cell 100. The memory cell arrangement 101D may include a plurality, p, of third control lines CL3(p), for example, a plurality of platelines. For each memory cell 100(m, n) of the plurality of memory cells, the first terminal 106 may be connected to a corresponding first control line CL1(n), the second terminal 107 may be connected to a corresponding second control line CL2(m), and the third terminal 108 may be connected to a corresponding third control line CL3(p). In some aspects, two or more of the third control lines CL3(p) may be implemented as a shared third control line CL3(s), such that memory cells 100 addressed by distinct first control lines CL1(x) . . . . CL1(y) are connected to the shared third control line CL3(s). In a three-dimensional configuration, a plurality of such memory cell arrangements 101D may be stacked over one another and addressed by corresponding sets of control lines, as described herein.

FIG. 1E shows a schematic view of a memory cell arrangement 101E including a set of three-terminal memory cells according to various aspects. Each three-terminal memory cell 100 may be configured, for example, as described with reference to FIG. 1B. The memory cell arrangement 101E may include a plurality, n, of first control lines CL1(n), for example, a plurality of bitlines. The memory cell arrangement 101D may include a plurality, m, of second control lines CL2(m), for example, a plurality of wordlines. The first control lines CL1(n) and the second control lines CL2(m) may be configured to address respective sets of access devices 110 of a memory cells100(1, 1; 2, 2; . . . ; m=n) that share the same pair of first control lines CL1(n) and second control lines CL2(m). The memory cell arrangement 101D may include a plurality, p, of third control lines CL3(p), for example, a plurality of platelines. An individual addressing of the memory cell 100(m=n, p) may be realized by the corresponding third control line CL3(p). For each memory cell 100(m=n, p) of the plurality of memory cells, the first terminal 106 may be connected to a corresponding first control line CL1(n), the second terminal 107 may be connected to a corresponding second control line CL2(m), and the third terminal 108 may be connected to a corresponding third control line CL3(p). In a three-dimensional configuration, a plurality of such memory cell arrangements 101E may be stacked over one another and addressed by corresponding sets of control lines, as described herein.

The control circuit 103 may be configured to apply one or more voltage schemes to the respective control lines to address (to operate, e.g., to read and/or write) memory cells 100 of the respective memory cell arrangement 101C, 101D, 101E. It is understood that the memory cell arrangements 101C, 101D, 101E described above serve as examples and that the memory cells 100 may be part of any suitable memory cell arrangement including corresponding control lines for addressing the memory cells 100. Further, it is understood that a memory cell arrangement may include further components such as one or more access devices for addressing the memory cells.

Various exemplary configurations of the memory capacitor 120 are provided herein. For illustration, various of the configurations of the memory capacitor 120 are exemplarily shown for a planar configuration with planar layers. It is noted that other shapes may be suitable as well, such as curved shapes, angled shapes, coaxially aligned shapes, as examples. In this case, any layer described herein may have a non-planar (e.g., curved) structure. According to various aspects, the memory capacitor 120 may conformally cover a three-dimensional structure. Thus, the shape of the memory capacitor 120 may depend on (e.g., may substantially correspond to) the shape of this three-dimensional structure.

The phrase that “a layer conformally covers a structure” or that “a layer is disposed conformally over a structure” may be understood to mean that a thickness, which is measured normal (e.g., substantially perpendicular) to a surface of the structure (e.g., the three-dimensional structure described herein), is substantially constant along the surface.

In various scenarios, it may be desired to form one or more layers conformally over or on a three-dimensional structure, such as a trench, a pillar, a tube, as examples. Here, atomic layer deposition (ALD) may be an advantageous processing technology compared to other deposition techniques. In some cases, e.g., when a feature size (e.g., an aspect ratio) of the three-dimensional structure is equal to or greater than a threshold value (e.g., an aspect ratio equal to or greater than ten), ALD may be a deposition technique to conformally cover the three-dimensional structure.

According to various aspects, one or more three-dimensional structures may be used to fabricate the memory cells described herein, wherein the one or more three-dimensional structures may have a feature size (e.g., an aspect ratio) equal to or greater than six (e.g., equal to or greater than ten, e.g., equal to or greater than fifteen, e.g., equal to or greater than twenty, etc.). As an example, the memory capacitor 120 described herein may be fabricated by forming a core structure (e.g., a pillar, a tube, a sheet, only as example), and conformally covering the core structure by one or more layers that form a memory layer stack that provides the memory capacitor 120. The core structure may include (e.g., may be) the first electrode 126 of the memory capacitor 120, at least one first conformal layer of the memory layer stack may include the memory material and form the memory element 124 of the memory capacitor 120, and at least one second conformal layer of the memory layer stack may include (e.g., may be) the second electrode 128 of the memory capacitor 120. According to various aspects, the core structure may be formed to extend laterally along a main surface of a carrier to form in-plane memory capacitors, as described herein.

To increase the efficiency of fabrication, the at least one first conformal layer and the at least one second conformal layer of the memory layer stack deposited over a plurality of core structures to form a plurality of memory capacitors 120 at the same time. It is understood that atomic layer deposition (ALD) generally forms a layer conformally. Thus, in the case that herein a layer is formed over a structure using ALD, the layer is understood to be formed conformally over the structure. Hence, a layer formed over a structure using ALD conformally covers the structure.

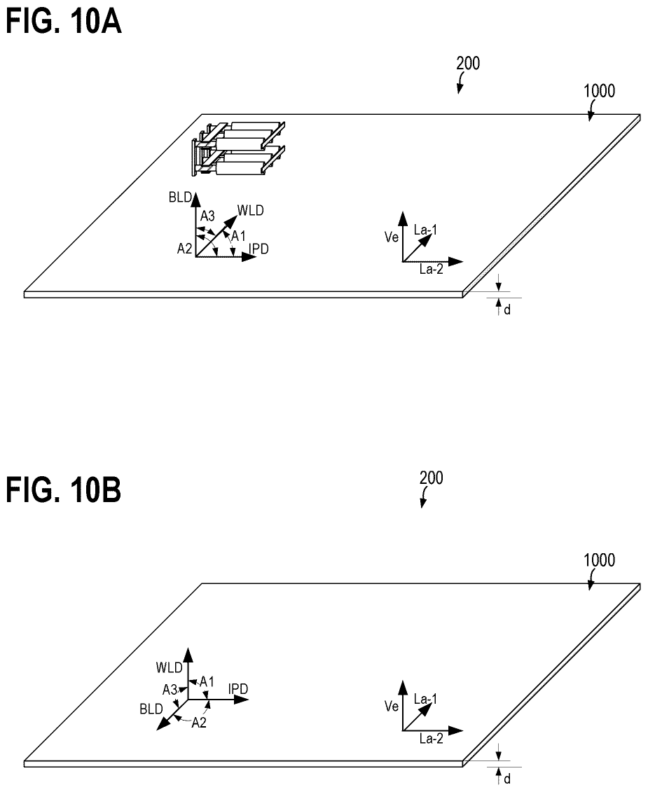

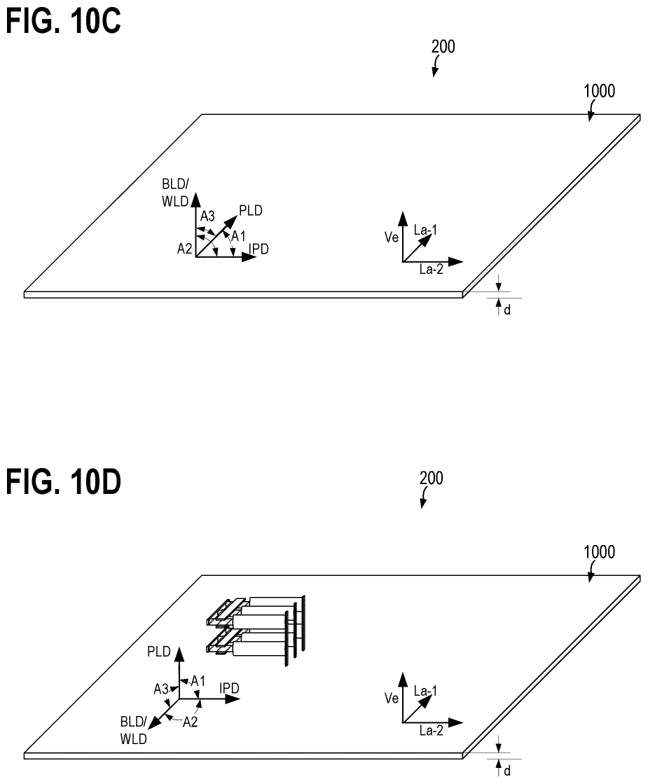

FIG. 2A to FIG. 2G show various schematic views of a memory chip 200 including a memory cell arrangement in various configurations. The memory chip 200 may include a set of memory cells 100 (a set of memory cells 100 may be also referred to as a memory cell array, memory cell arrangement, etc.) operable by an arrangement of control lines (e.g., by wordlines WL, bitlines BL, and platelines PL; e.g., by bitlines BL and platelines PL). Each memory cell 100 of the memory cell array may include (e.g., may be) a memory capacitor MC that is elongated along an in-plane direction IPD of the memory chip. The in-plane direction IPD is oriented in substantially parallel to a main processing surface of the memory chip 200, see FIGS. 10A to 10D. In the case that the memory cells 100 of the memory cell array are operable by an arrangement of three types of control lines (e.g., by wordlines WL, bitlines BL, and platelines PL), each memory cell 100 of the memory cell array includes a memory capacitor MC and a corresponding access device AD, wherein the access device may be controlled by a corresponding wordline and wherein the memory capacitor MC can be accessed through the access device AD by a corresponding bitline/plateline pair. As an example, the access device may be an access field-effect transistor (FET); wherein, in this case, the wordlines are configured to control the gate of the access field-effect transistor. The memory capacitor MC can be accessed through the access field-effect transistor by the corresponding bitline and the corresponding plateline in the case that the access field-effect transistor is in an open-state (in other words in a conducting-state) controlled by the corresponding wordline.

According to various aspects, the memory chip 200 may include a set of memory cells, e.g., a plurality of memory cells 100 as described herein. FIG. 2A to FIG. 2F illustrate exemplarily a set of memory cells 100, wherein each memory cell 100 has three operation terminals (to be operated by three types of control lines) and includes a memory capacitor MC and an access device AD corresponding to the memory capacitor MC (e.g., as described herein with reference to FIGS. 1B, 1D, and 1E). However, in another configuration as illustrated in FIG. 2G, the memory cells of the set of memory cell array may have only two operation terminals (to be operated by only two types of control lines) and includes only a memory capacitor MC (and no access device AD corresponding to the memory capacitor MC), e.g., as described herein with reference to FIG. 1A and FIG. 1C.

As exemplarily illustrated in FIG. 2A to FIG. 2F, the memory chip 200 may include a set of wordlines WL including, for example, wordlines WL-1, WL-2, WL-3 (e.g., a number of m wordlines WL-m, see second control lines CL2(m) in FIGS. 1C to 1E). The wordlines of the set of wordlines WL may define a wordline direction WLD. The wordlines of the set of wordlines WL may extend at least partially within a plane substantially perpendicular to the in-plane direction IPD, e.g., the wordlines of the set of wordlines WL may at least partially extend along the wordline direction WLD. The wordline direction WLD may be substantially perpendicular to the in-plane direction IPD. In some aspects, the wordlines may be implemented as elongated electrodes extending along (e.g., substantially parallel to) the wordline direction WLD within a three-dimensional memory layer stack that includes the set of memory cells 100.

As exemplarily illustrated in FIGS. 2A to 2G, the memory chip 200 may include a set of bitlines BL including, for example, bitlines BL-1, BL-2, BL-3 (e.g., up to a number of n bitlines BL-n, see first control lines CL1(n) in FIGS. 1C to 1E) defining a bitline direction BLD. The bitlines of the set of bitlines BL may extend at least partially within a plane substantially perpendicular to the in-plane direction IPD, e.g., the bitlines of the set of bitlines BL may at least partially extend along the bitline direction BLD. The bitline direction BLD may be substantially perpendicular to the in-plane direction IPD. In some aspects, the bitlines of the set of bitlines BL may be implemented as electrodes extending along (e.g., substantially parallel to) the bitline direction BLD within the three-dimensional memory layer stack that includes the set of memory cells 100.

As exemplarily illustrated in FIGS. 2A to 2G, the memory chip 200 may include a set of platelines PL including platelines PL-1, PL-2, PL-3 (e.g., up to a number of p platelines PL-p, see third control lines CL3(p) in FIGS. 1C to 1E). The platelines of the set of platelines PL may extend at least partially within a plane substantially perpendicular to the in-plane direction IPD, e.g., the platelines of the set of platelines PL may extend at least partially along the bitline direction BLD or along the wordline direction WLD. In the case that the wordline direction is substantially perpendicular to the bitline direction BLD (as illustrated in FIGS. 2A to 2E), the set of platelines PL may include platelines extending at least partially along the bitline direction BLD (see FIG. 2D), platelines extending at least partially along the wordline direction WLD (see FIG. 2A to FIG. 2C), and/or shared platelines PL-C extending along both the wordline direction WLD and the bitline direction BLD (see FIG. 2E). In the case that the wordline direction is substantially parallel to the bitline direction BLD (as illustrated in FIG. 2F), the set of platelines PL may include platelines extending at least partially along a plateline direction PLD (see FIG. 2F), wherein the plateline direction PLD is substantially perpendicular to the in-lane direction IPD, substantially perpendicular to the wordline direction WLD, and substantially perpendicular to the bitline direction BLD.

According to various aspects, as illustrated in FIG. 2A to FIG. 2F, each memory cell of the set of memory cells 100 may be addressable by a corresponding wordline of the set of wordlines WL, a corresponding bitline of the set of bitlines BL, and a corresponding plateline of the set of platelines PL. The addressing of each memory cell of the set of memory cells 100 may include addressing (e.g., supplying a respective operation voltage to) the respective memory capacitor MC of the set of memory cells 100 via a bitline and a plateline corresponding to the memory cell to be addressed. In the case that each memory cell of the set of memory cells 100 shall be individually addressable and the memory cell includes no access device (see FIG. 2G), the bitlines may be directly connected to the memory capacitor MC and the platelines may run substantially perpendicular to the bitlines to allow for a selective (cross-type) addressing. In the case that each memory cell of the set of memory cells 100 shall be individually addressable and the memory cell includes an access device AD that can be individually addressed by a corresponding wordline/bitline pair (e.g., with wordlines arranged substantially perpendicular to the bitlines), the platelines may run in any desired manner since the individual addressing is realized by the access device AD (see FIG. 2A to FIG. 2E). In the case that each memory cell of the set of memory cells 100 shall be individually addressable and the memory cell includes an access device AD that cannot be individually addressed by a corresponding wordline/bitline pair (with wordlines arranged substantially parallel to the bitlines), the platelines may run substantially perpendicular to the bitlines to allow for a selective addressing (see FIG. 2F).

With respect to the individual addressing of the memory cells (and the memory capacitors MC) of the set of memory cells 100 of the memory chip 200, various examples are as follows: the memory capacitor MC-1/1 may be individually addressed by a corresponding wordline/bitline pair including the wordline WL-1 and the bitline BL-1 individually addressing the access device AD-1/1 corresponding to the memory capacitor MC-1/1, the memory capacitor MC-1/2 may be individually addressed by a corresponding wordline/bitline pair including the wordline WL-1 and the bitline BL-2 individually addressing the access device AD-1/2 corresponding to the memory capacitor MC-1/2, the memory capacitor MC-2/1 may be individually addressed by a corresponding wordline/bitline pair including the wordline WL-2 and the bitline BL-1 individually addressing the access device AD-2/1 corresponding to the memory capacitor MC-2/1, the memory capacitor MC-2/2 may be individually addressed by a corresponding wordline/bitline pair including the wordline WL-2 and the bitline BL-2 individually addressing the access device AD-2/2 corresponding to the memory capacitor MC-2/2, etc. (see FIGS. 2A to 2E). In another example: the memory capacitor MC-1/1 may be individually addressed by a corresponding plateline/bitline pair including the plateline PL-1 and the bitline BL-1 individually addressing the corresponding memory capacitor MC-1/1 with open access device AD-1/1 and closed access device AD-2/1, the memory capacitor MC-1/2 may be individually addressed by a corresponding plateline/bitline pair including the plateline PL-2 and the bitline BL-1 individually addressing the corresponding memory capacitor MC-1/2 with open access device AD-1/2 and closed access device AD-2/2, the memory capacitor MC-2/1 may be individually addressed by a corresponding plateline/bitline pair including the plateline PL-1 and the bitline BL-2 individually addressing the corresponding memory capacitor MC-2/1 with open access device AD-2/1 and closed access device AD-1/1, the memory capacitor MC-2/2 may be individually addressed by a corresponding plateline/bitline pair including the plateline PL-2 and the bitline BL-2 individually addressing the corresponding memory capacitor MC-2/2 with open access device AD-2/2 and closed access device AD-1/2, etc. (see FIG. 2F). In still another example: the memory capacitor MC-1/1 may be individually addressed by a corresponding plateline/bitline pair including the plateline PL-1 and the bitline BL-1 individually addressing the corresponding memory capacitor MC-1/1 without use of an access device for the individual addressing, the memory capacitor MC-1/2 may be individually addressed by a corresponding plateline/bitline pair including the plateline PL-2 and the bitline BL-1 individually addressing the corresponding memory capacitor MC-1/2 without use of an access device for the individual addressing, the memory capacitor MC-2/1 may be individually addressed by a corresponding plateline/bitline pair including the plateline PL-1 and the bitline BL-2 individually addressing the corresponding memory capacitor MC-2/1 without use of an access device for the individual addressing, the memory capacitor MC-2/2 may be individually addressed by a corresponding plateline/bitline pair including the plateline PL-2 and the bitline BL-2 individually addressing the corresponding memory capacitor MC-2/2 without use of an access device for the individual addressing, etc. (see FIG. 2G).

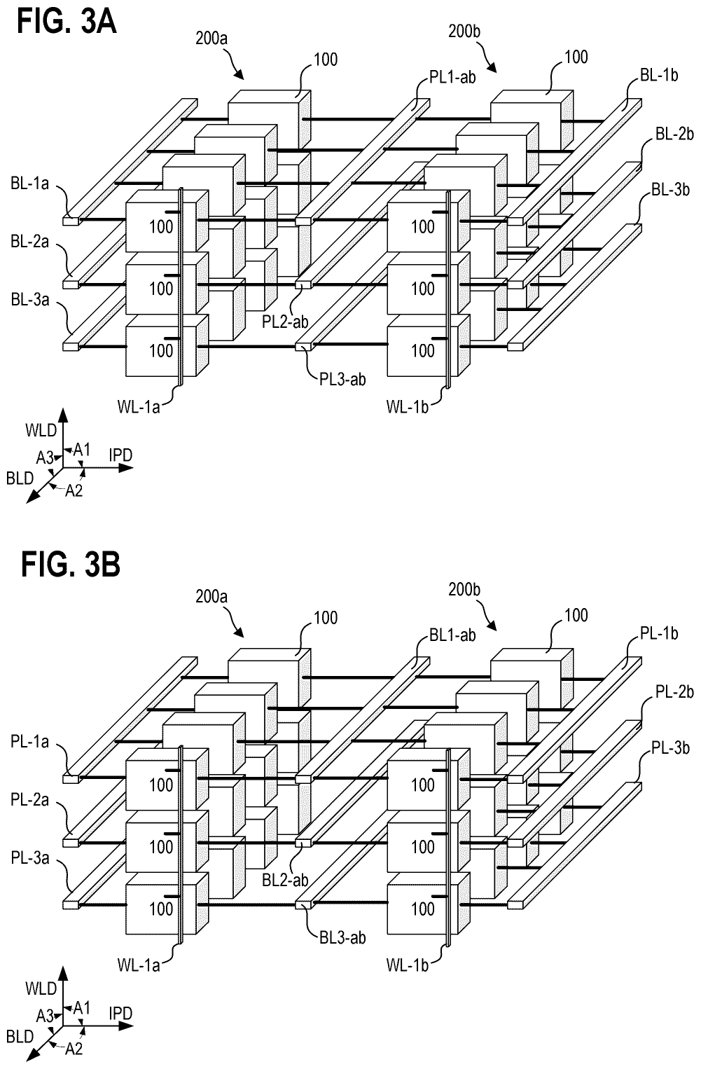

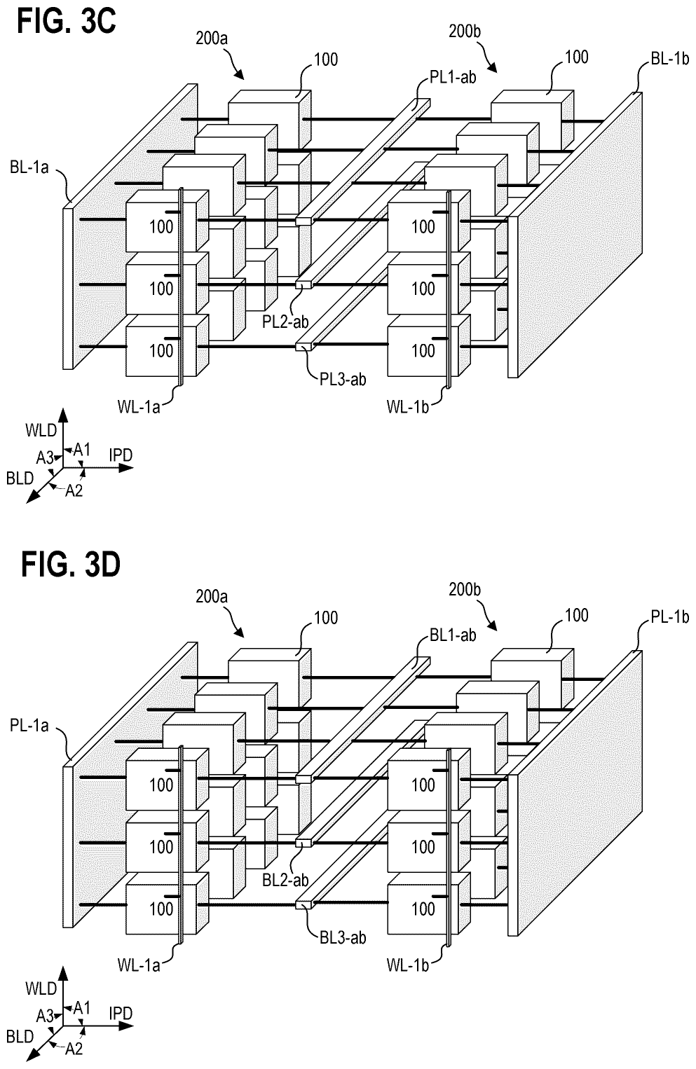

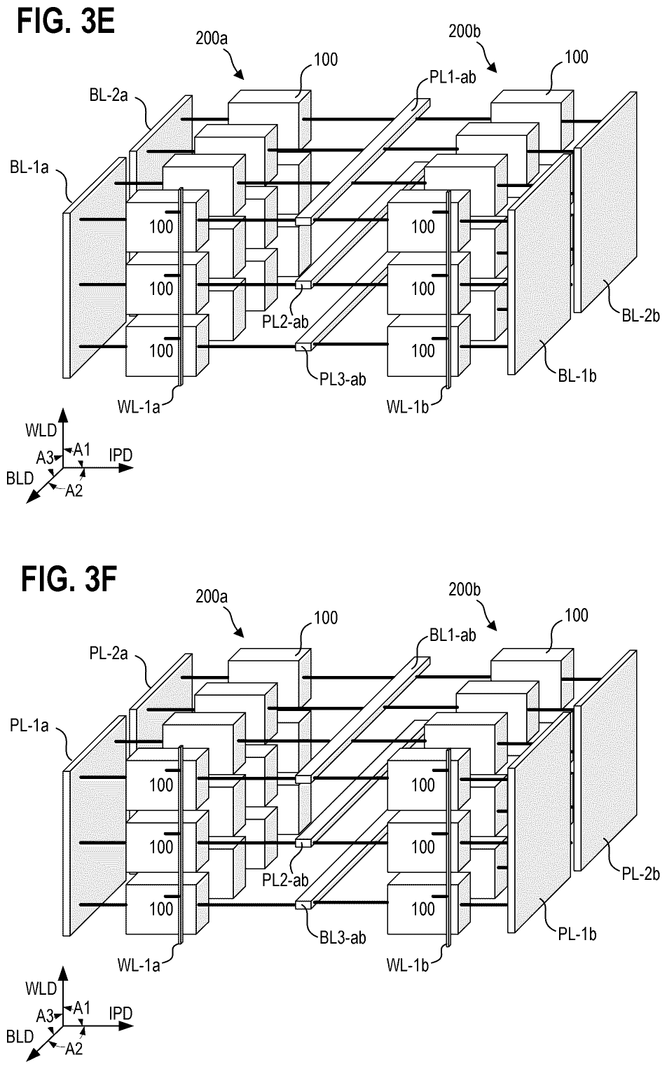

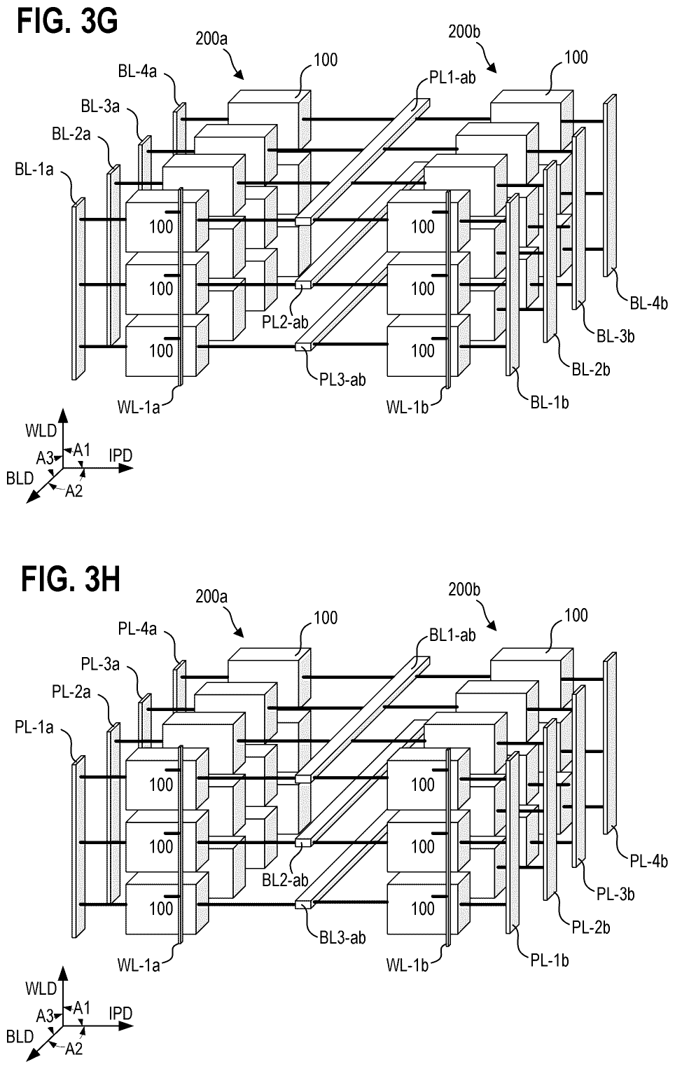

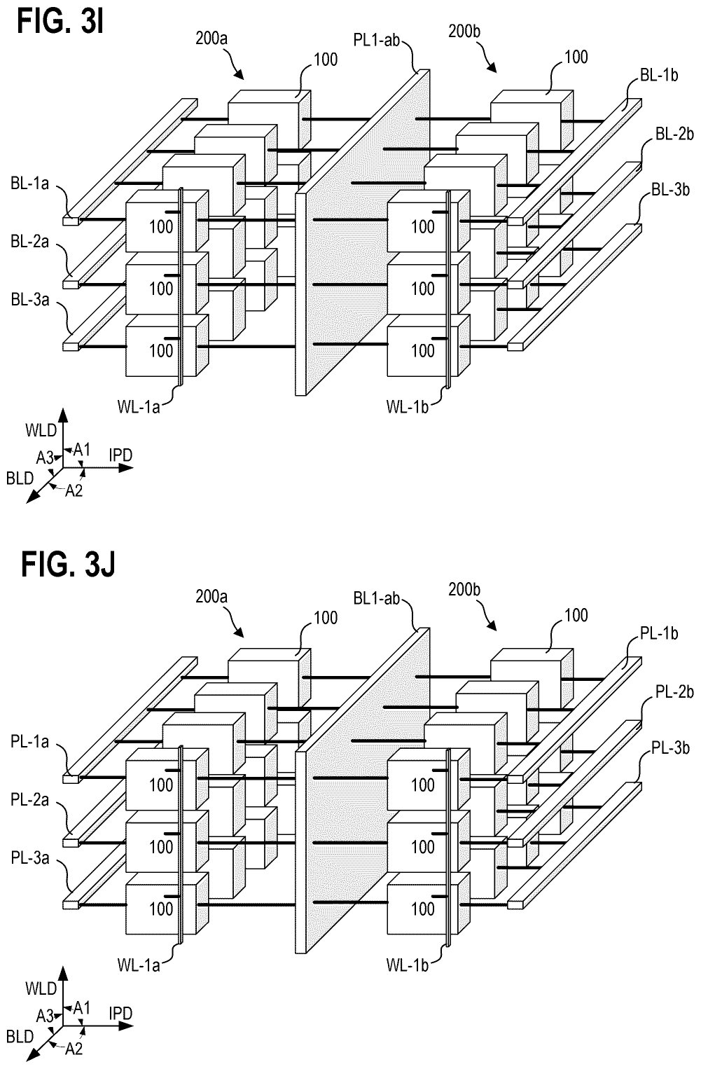

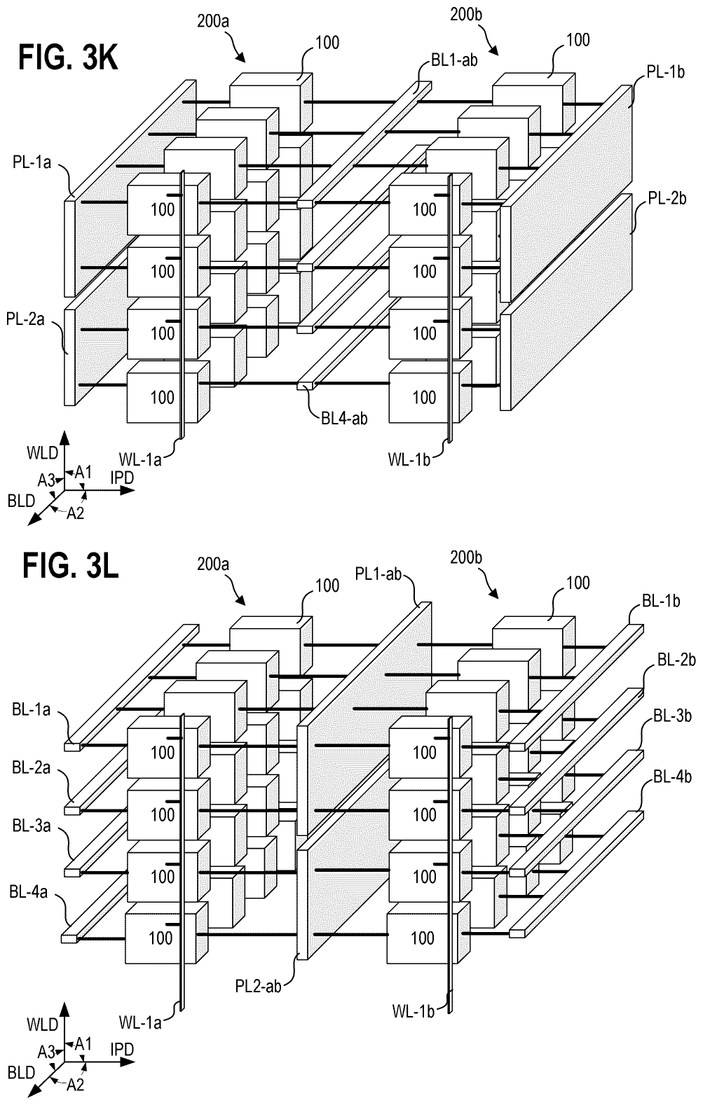

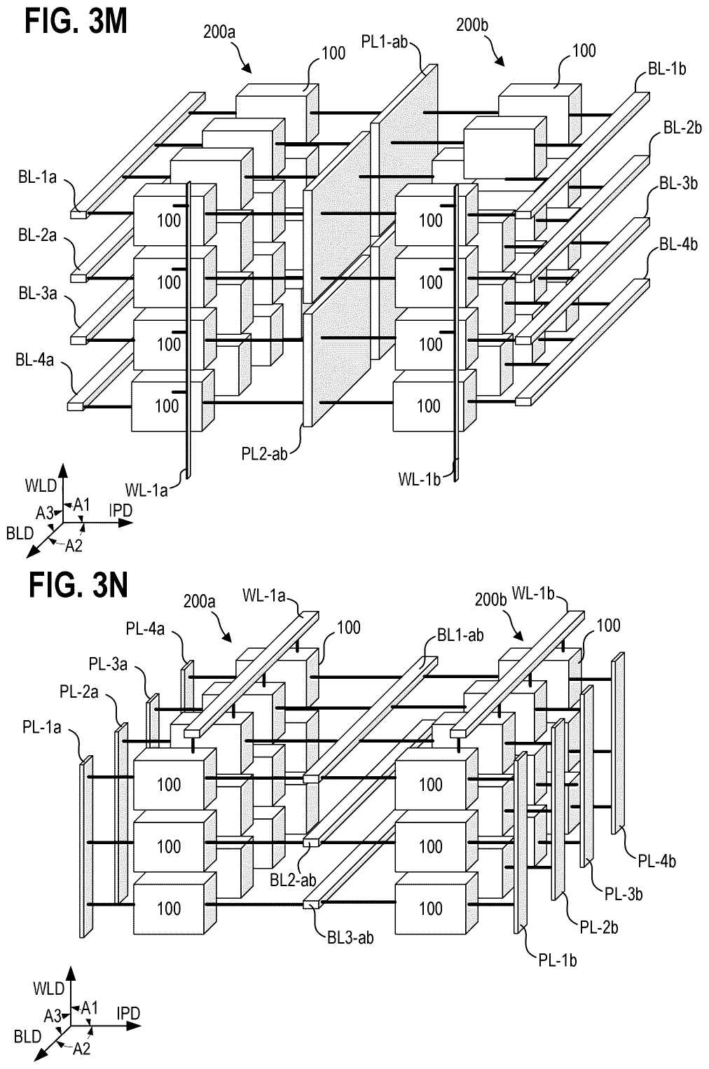

FIG. 2A to FIG. 2G illustrate an example of a memory stack (including memory cells associated with the memory capacitors MC), wherein the memory stack includes a plurality of memory cell layers stacked over one another along a stacking direction. In this exemplary illustration, the stacking direction is substantially perpendicular to the in-plane direction defined by the memory capacitors MC. Each of the plurality of memory capacitor layers may include one or more memory cell arrays such that a memory stack is provided that includes one or more three-dimensional memory cell arrays. As an example, the stacking direction may be substantially perpendicular to the in-plane direction (e.g., substantially parallel to the bitline direction, substantially parallel to the wordline direction, or substantially parallel to the plateline direction, see FIGS. 10A to 10D) and the memory capacitors MC-1/1, MC-1/2, MC-1/3 are arranged as a first memory cell array in a first memory cell layer and the memory capacitors MC-2/1, MC-2/2, MC-2/3 are arranged as a second memory cell array in a second memory cell layer stacked over the first memory cell layer. FIGS. 2A to 2G illustrate a three-dimensional memory cell array including a one-dimensional memory cell array in each of the memory cell layers stacked over one another. FIGS. 3A to 9G and FIGS. 11A, 11B, 12 illustrate a three-dimensional memory cell array including a two-dimensional memory cell array in each of the memory cell layers stacked over one another, the two-dimensional memory cell array extending along the in-plane direction and substantially perpendicular to the stacking direction.

Some aspects described herein may be related to a cost-efficient fabrication of the memory cell array (e.g., the set of memory cells 100 of the memory chip 200). A vertical stacking of memory cells over one another may be efficient to reduce chip area consumption and therefore may reduce processing costs. A stacking of memory capacitors may be related to various challenges. A useful approach may include processing layer stacks to form stacked memory cells on a chip. Therefore, it may be beneficial to form memory capacitors on the chip that are oriented in-plane, i.e., that are elongated substantially parallel to the main processing surface of a wafer during chip fabrication. Therefore, in some aspects, the first dimension each of the memory capacitors MC along the in-plane direction IPD may be greater than both a second dimension of the memory capacitor MC along the wordline direction WLD or plateline direction PLD and a third dimension of the memory capacitor MC along the bitline direction. The first dimension of the memory capacitor MC along the in-plane direction IPD may be greater by at least a factor of 3 and less by a factor of 45 than both a second dimension of the memory capacitor MC along the plateline or wordline direction PLD/WLD and a third dimension of the memory capacitor MC along the bitline direction BLD. The first dimension may be, for example, greater than 30 nm and less than 900 nm. The second dimension may be, for example, greater than 10 nm and less than 100 nm. The third dimension may be, for example, greater than 10 nm and less than 200 nm.

According to various aspects, the memory capacitor MC may be a spontaneously polarizable memory capacitor with a dielectric capacitance less than 10 fF (ten femtofarad) and with an effective capacitance (e.g., defined by delta Q/delta V) than 10 fF (ten femtofarad). The effective capacitance includes both a dielectric and spontaneous polarization properties of the memory capacitor MC. In the case that the memory capacitor MC is a remanently polarizable memory capacitor, the memory capacitor is configured to be voltage switchable into at least two distinct memory states. The at least two distinct memory states may be defined by at least two distinct residual polarization states of a remanently polarizable (e.g., of a ferroelectric) memory layer of the memory capacitor MC (see, for example, memory element 124 of the memory capacitor 120).

According to various aspects, the vertical stacking of memory cells, as described herein, may allow for an efficient use of the control lines to operate the memory cells of the memory cell array, as described in more detail below. In the following, various aspects of one or more memory cell arrays are described in herein. Each memory cell array includes a plurality of (e.g., all) memory cells 100. In some aspects, a spatial arrangement of the plurality of memory cells 100 may define one or more memory cell arrays 200a, 200b, 200c, 200d, 200e, 200f (referred to herein also as three-dimensional memory cell array, three-dimensional arrangement of memory cells, three-dimensional matrix-type arrangement, or three-dimensional matrix-type array). Furthermore, a logical addressing of the plurality of memory cells 100 by the respective control lines may define a logic memory cell array (e.g., a logic sector of memory cells) that is different from the memory cell arrays 200a, 200b, 200c, 200d, 200e defined by the spatial arrangement of the plurality of memory cells 100. This is, for example, useful, since the number of memory cells that can be stacked over on another (along the vertical direction Ve, as illustrated in FIGS. 10A to 10D) may be less than beneficial for the logical addressing. Therefore, two or more (e.g., neighboring or next but one) of the memory cell arrays 200a, 200b, 200c, 200d, 200e, 200f may be operably by (e.g., connected to) a same set of control lines to form a logic memory cell array that is greater than each of the memory cell arrays 200a, 200b, 200c, 200d, 200e (as illustrated, for example, in FIG. 3A to FIG. 9E). This may be useful in the case that the number of memory cell stacks—and therefore, the number of memory cells arranged along the vertical direction Ve—is lower than the desired number of memory cells to be logically addressed by the corresponding one or more control lines connecting the memory cells along the stacking direction (e.g., along the vertical direction Ve). In these configurations, memory cells of a subset of the memory cells 100 arranged on the memory chip 200 may be electrically conductively connected with one another by a respective control line running at least partially along the stacking direction (e.g., along the vertical direction Ve) and at least partially along a direction substantially perpendicular to the stacking direction (e.g., along the in-plane direction IPD). In these configurations, memory cells of a subset of the memory cells 100 arranged on the memory chip 200 may be operable by a segmented control line, wherein the segments of the control line running along the stacking direction (e.g., along the vertical direction Ve) and wherein the segments of the control line running along the stacking direction are electrically conductively connected with one another.

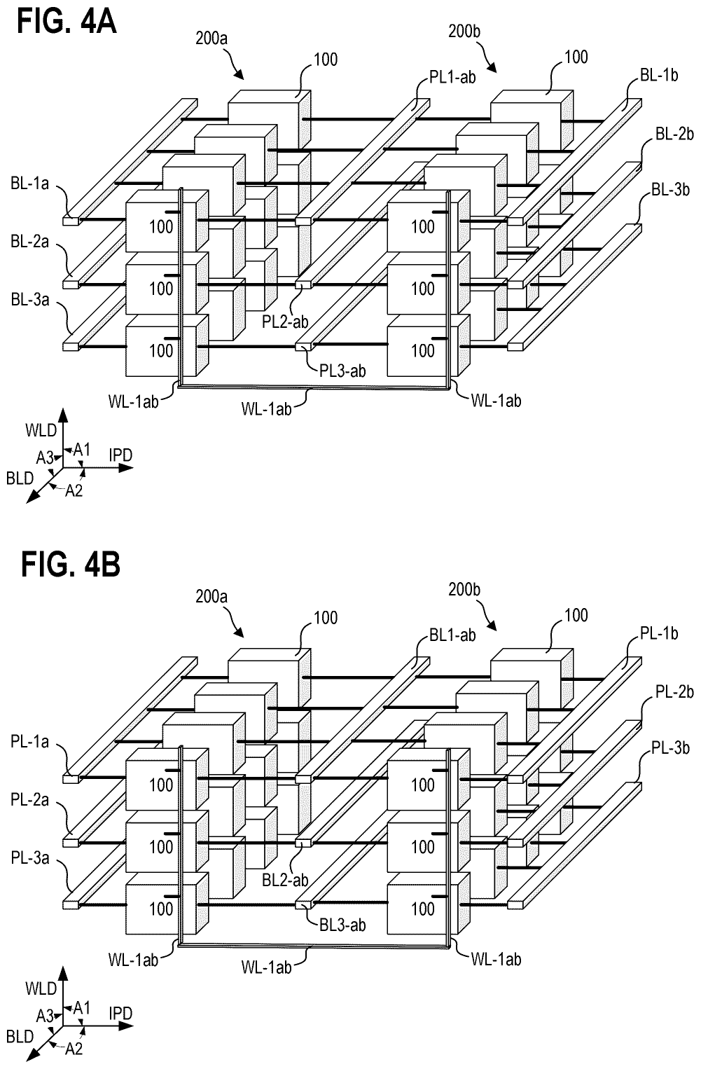

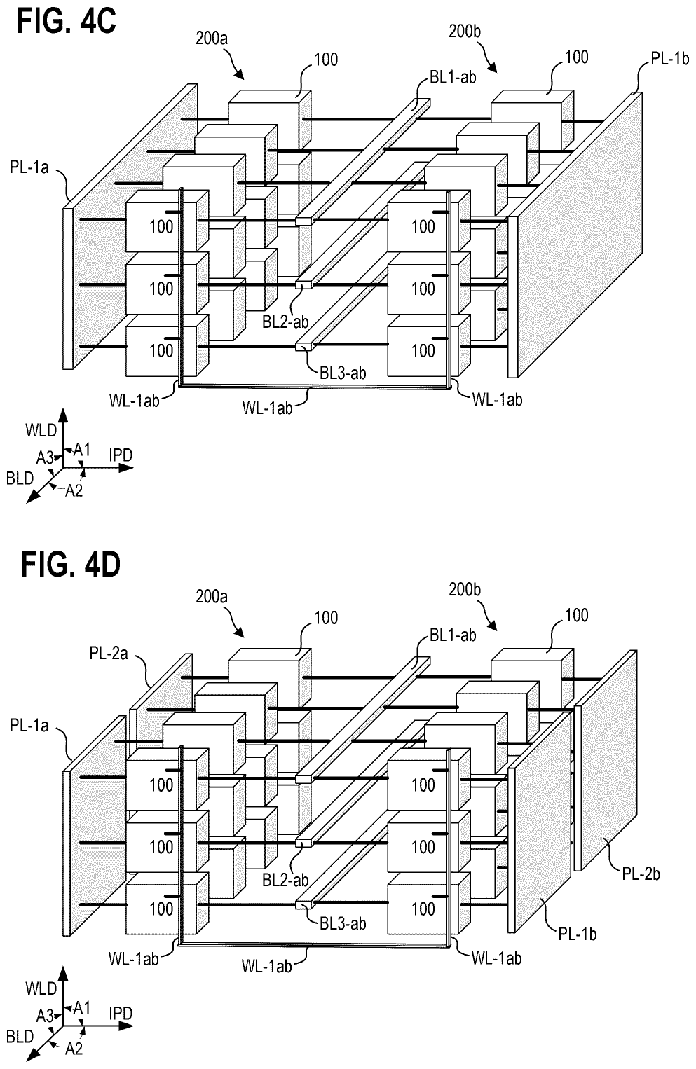

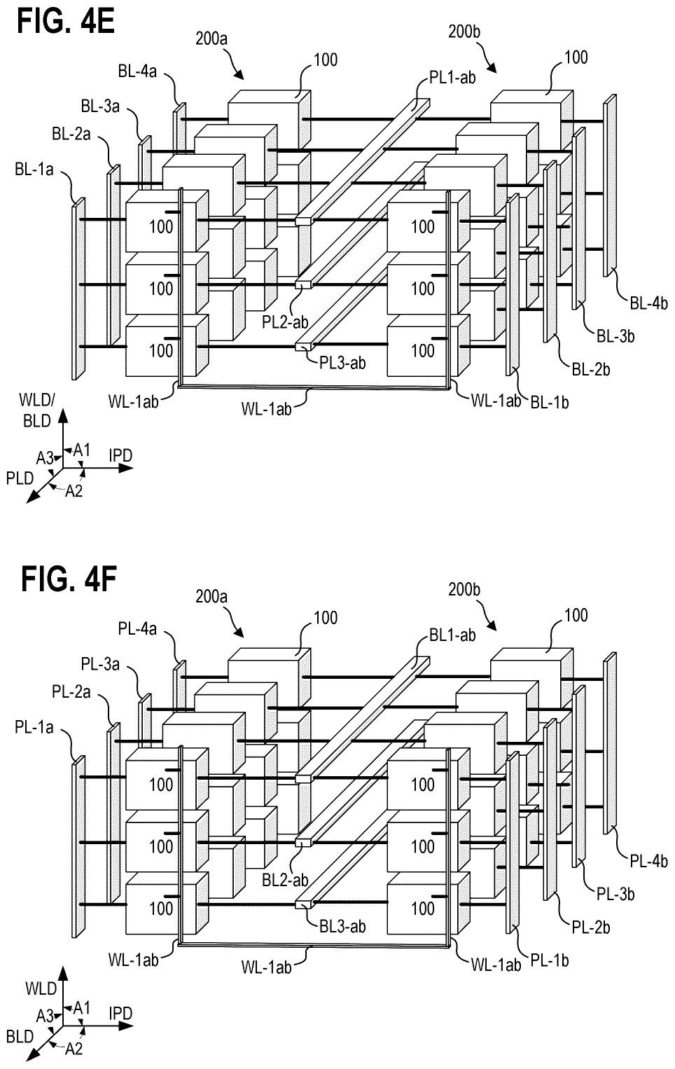

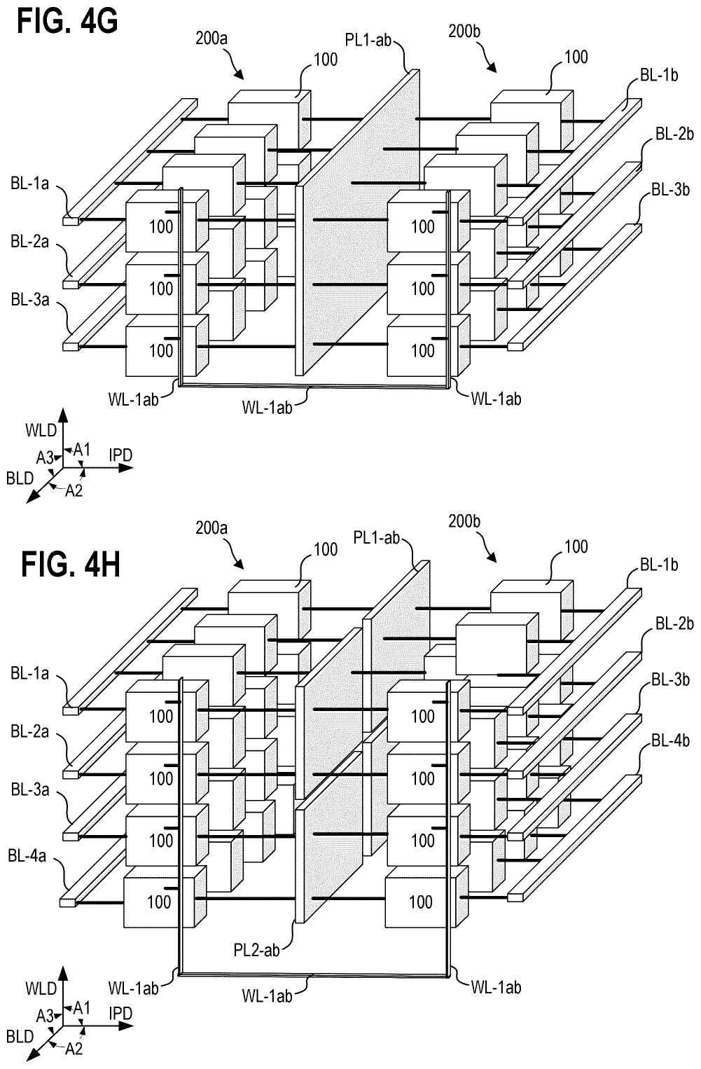

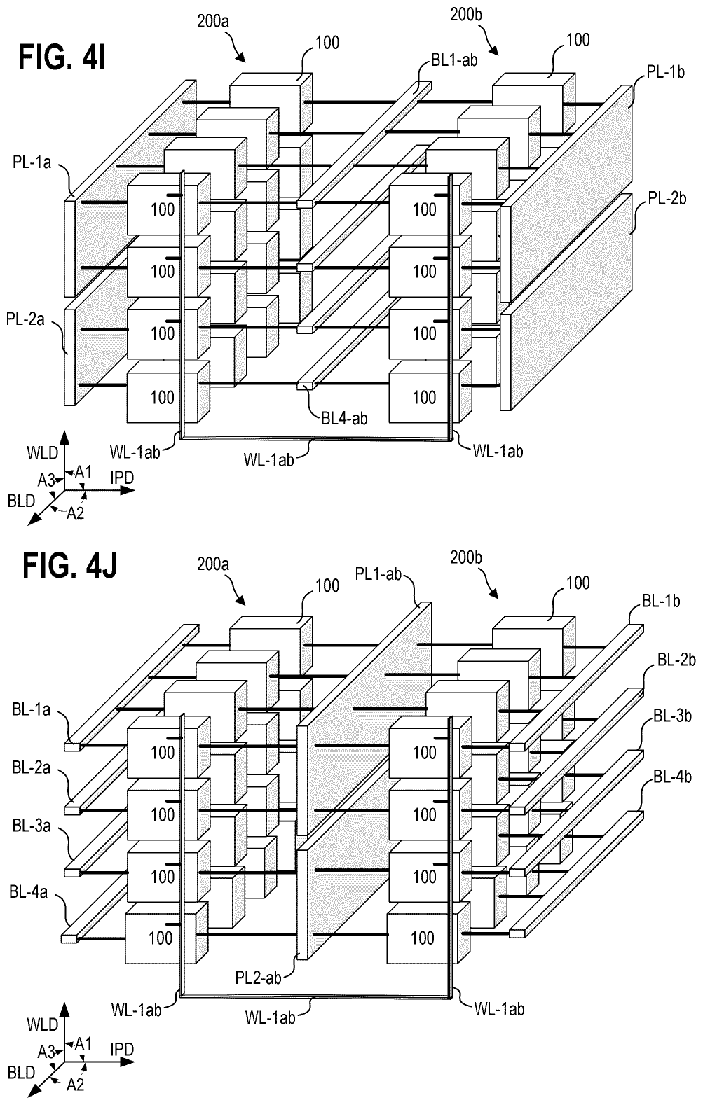

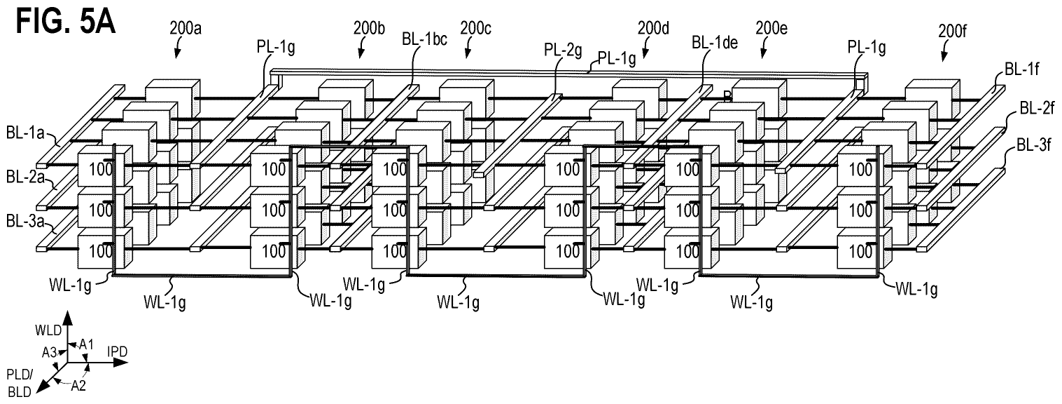

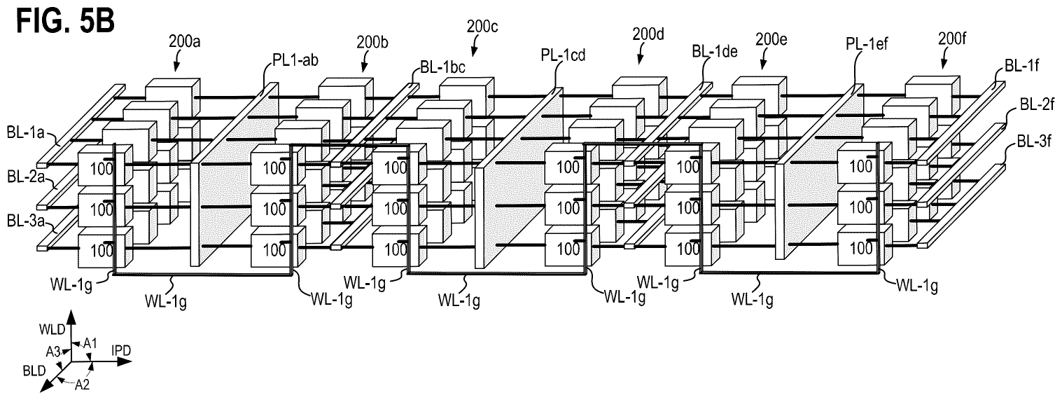

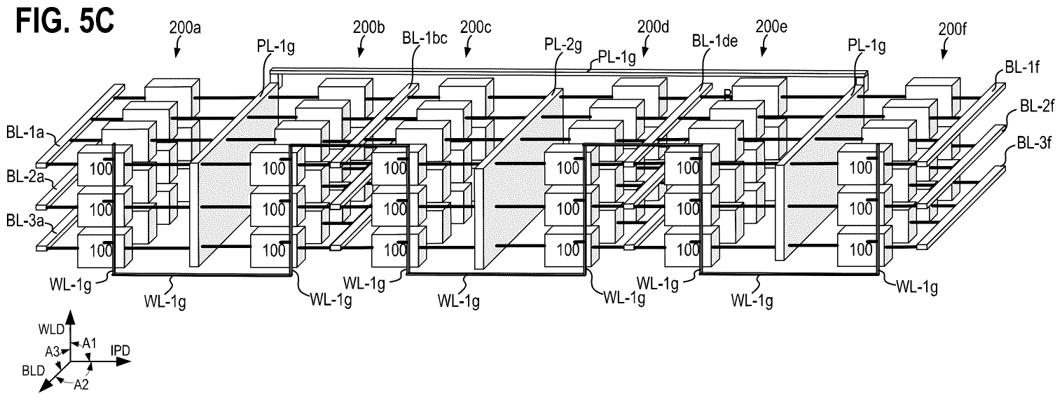

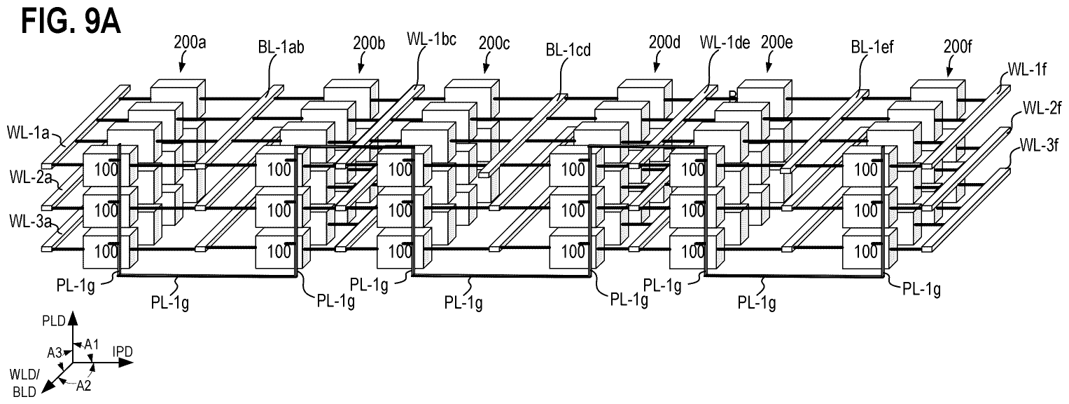

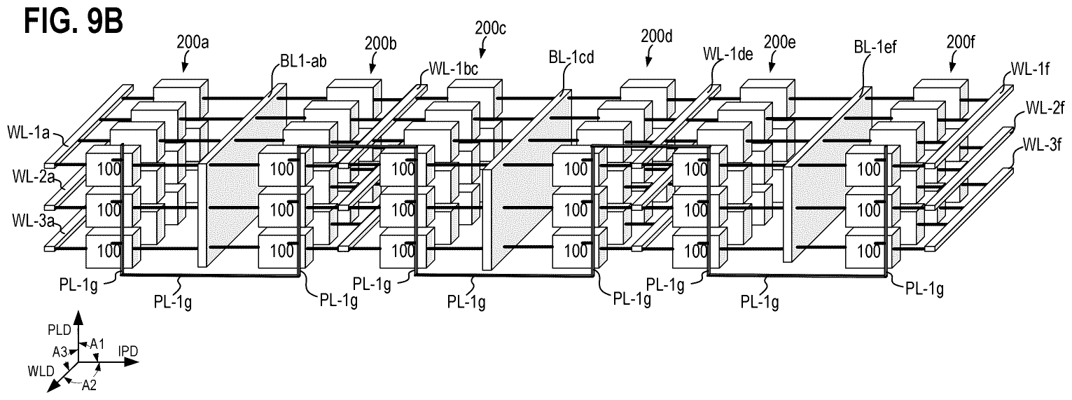

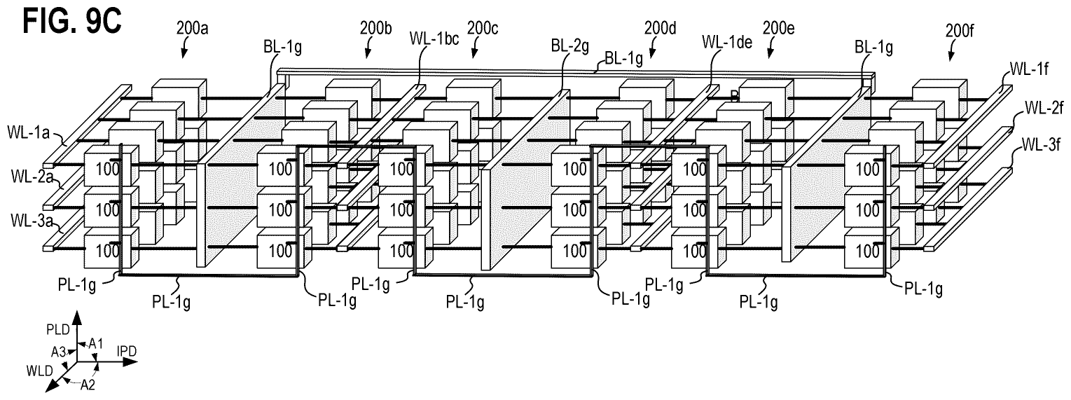

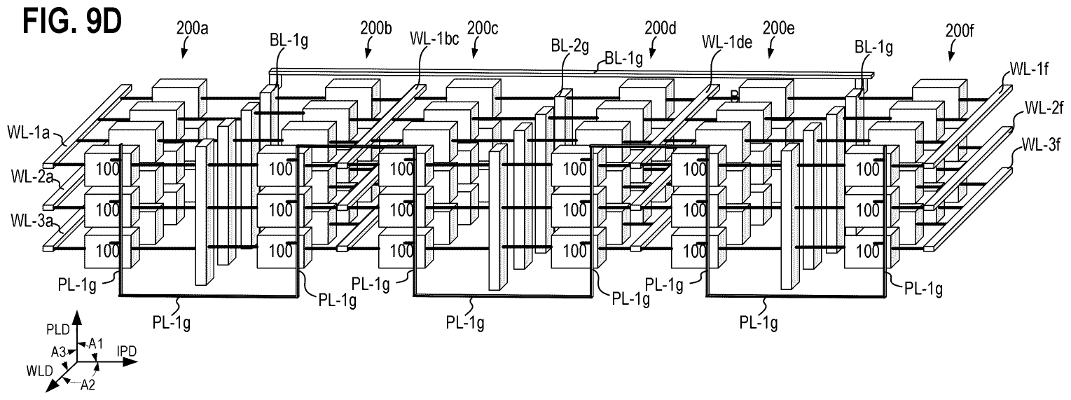

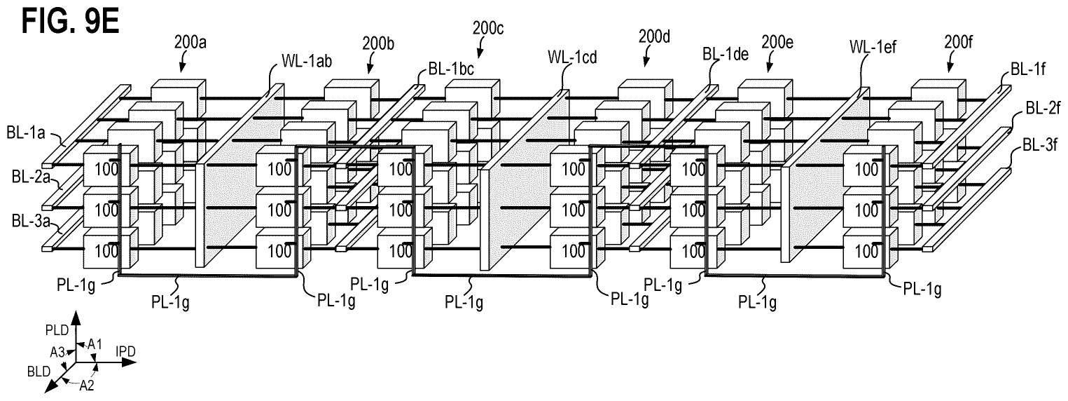

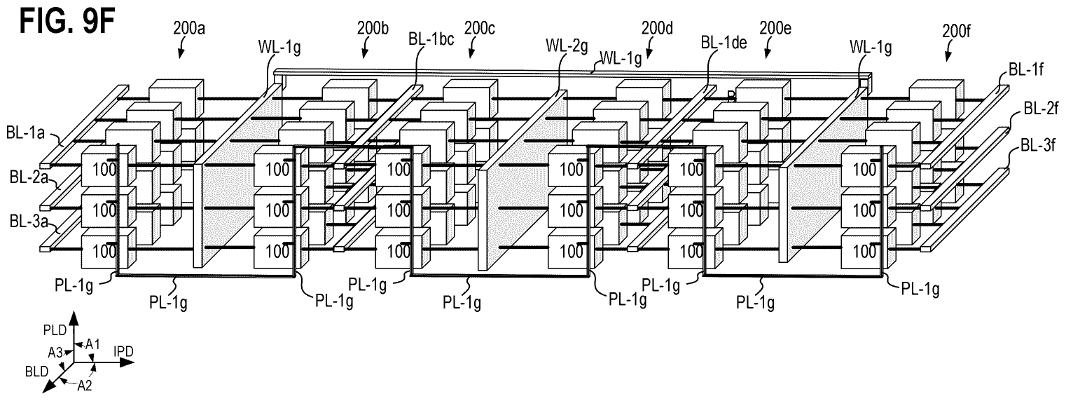

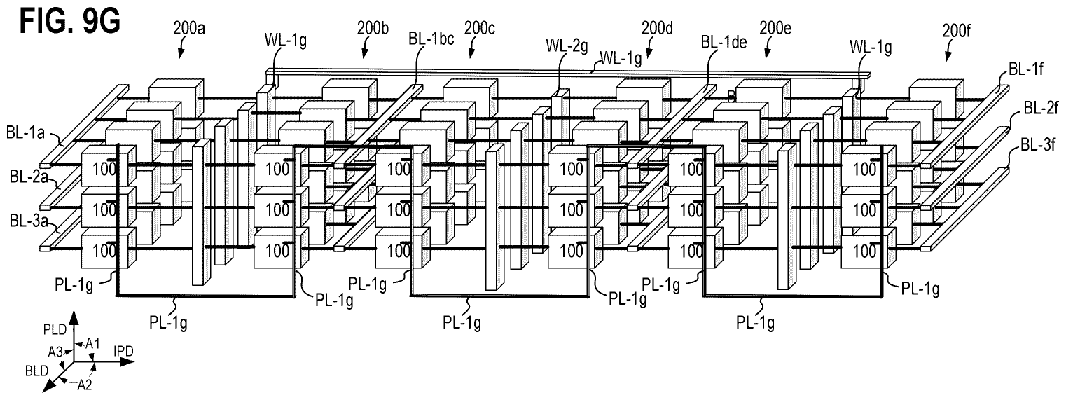

As an example, in the case that the word lines run along the stacking direction and each of the wordlines shall logically address and connect a number of memory cells with one another (e.g., it may be desired that a wordline may logically address 512 memory cells), and the number of stacks and therefore the number of stacked memory cells is lower than the number of memory cells to be logically addressed, each of the wordlines (see, for example, wordline WL1-ab in FIG. 4A to FIG. 4J; see, for example, wordline WL-1g in FIG. 5A to FIG. 5C; see, for example, wordlines WL-1bc, WL-1de in FIG. 9A to FIG. 9D; wordlines WL-1ab, WL-1cd, WL-1ef in FIG. 9E; and see, for example, wordlines WL-1g, WL-2g in FIG. 9F and FIG. 9G) may connect a number of memory cells of a plurality of memory cell arrays with one another. FIG. 4A to FIG. 4J illustrate a subset of memory cells of each of the two memory cell arrays 200a, 200b connected by a corresponding (shared) wordline WL1-ab. FIG. 5A to FIG. 5C illustrate a subset of memory cells of each of the more than two memory cell arrays 200a, 200b, 200c, 200d, 200e, 200f connected by a corresponding (shared) wordline WL-1g. FIG. 9A to FIG. 9D illustrate a subset of memory cells of each of the two memory cell arrays 200b, 200c and memory cell arrays 200d, 200e connected by corresponding (shared) wordline WL-1bc, WL-1de respectively. FIG. 9E illustrates a subset of memory cells of each of the two memory cell arrays 200a, 200b and memory cell arrays 200c, 200d and memory cell arrays 200e, 200f connected by corresponding (shared) wordline WL-1ab, WL-1cd, WL-1ef respectively. FIG. 9F, 9G illustrate a subset of memory cells of each of the more than two memory cell arrays 200a, 200b, 200e, 200f and memory cell arrays 200c, 200d connected by a corresponding (shared) wordline WL-1g, WL-2g respectively. In the case that the number of memory cell stacks is 64, it may be desired that a wordline may logically address 512 memory cells of 8 (e.g., neighboring or next but one) memory cell arrays and in the case that the number of memory cell stacks is 128, it may be desired that a wordline may logically address 512 memory cells of 4 (e.g., neighboring or next but one) memory cell arrays, only as numerical examples.

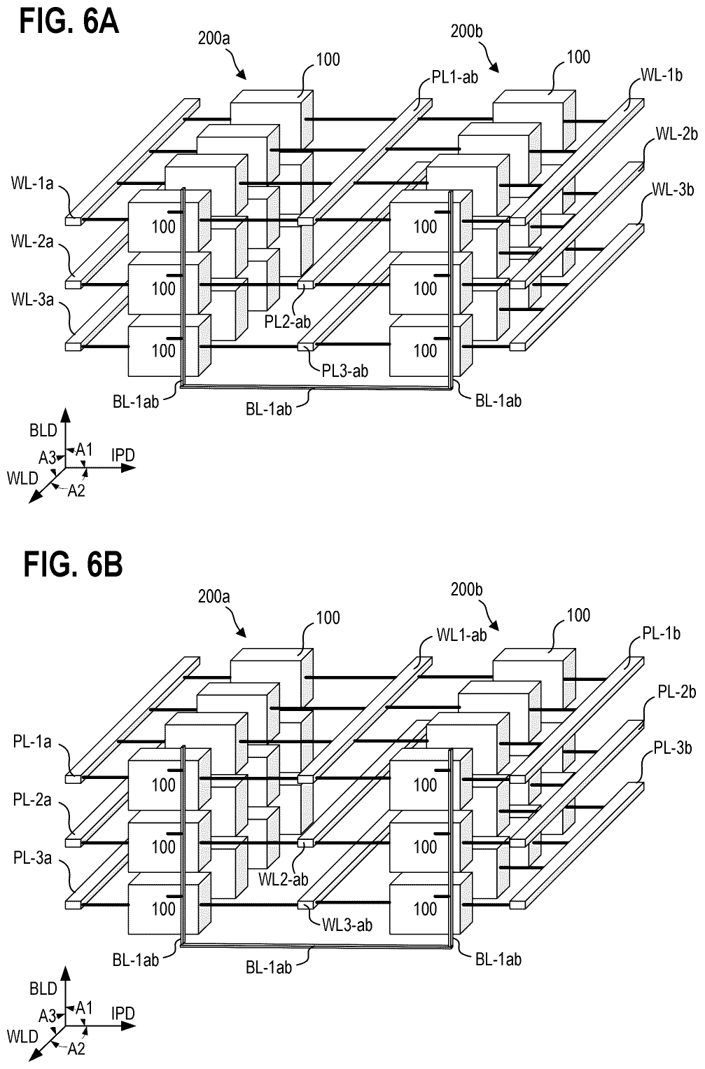

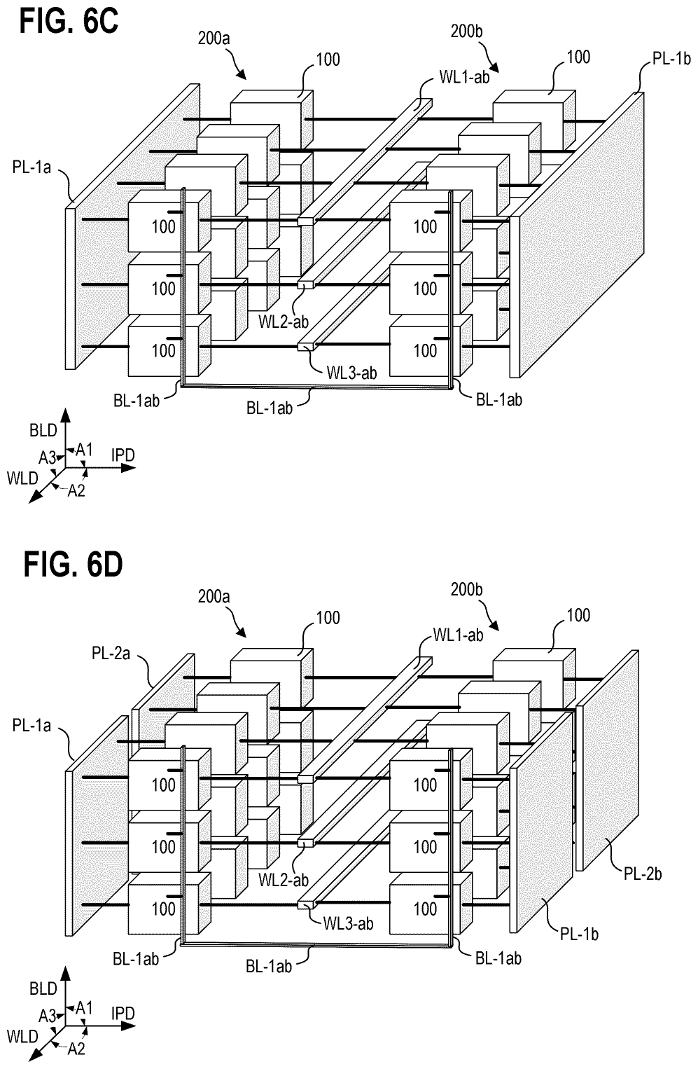

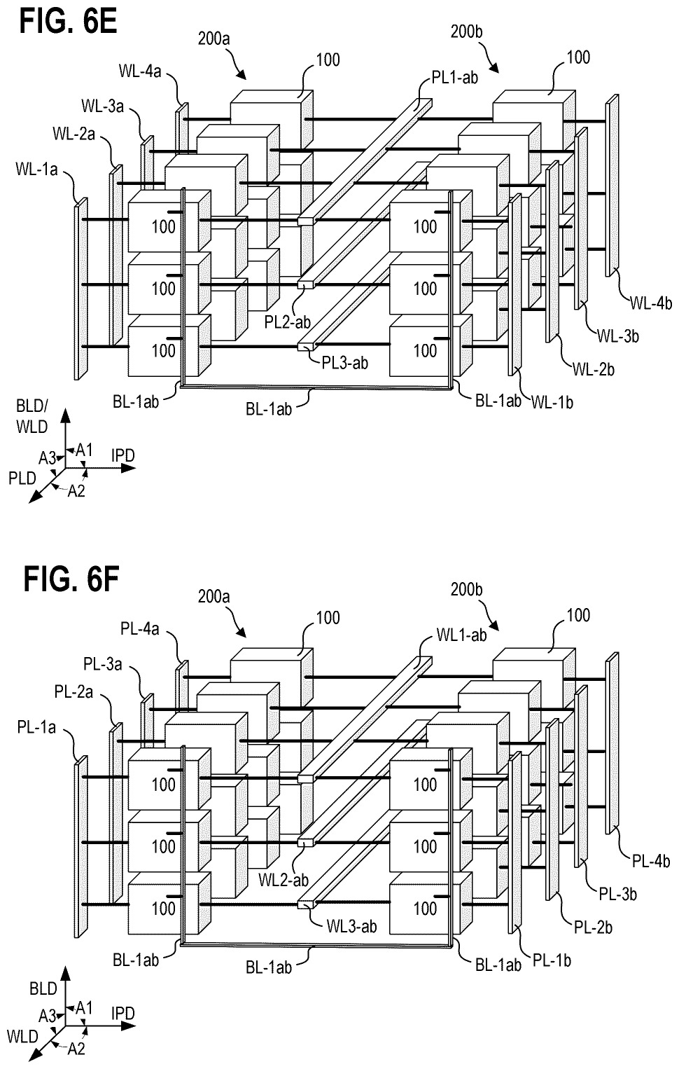

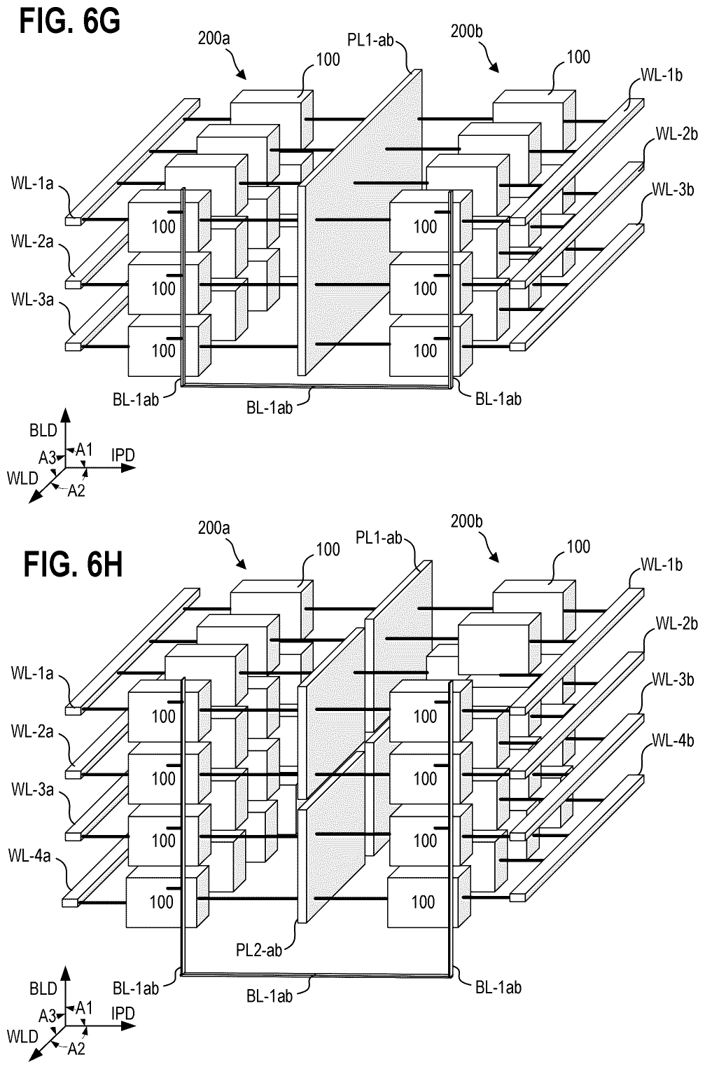

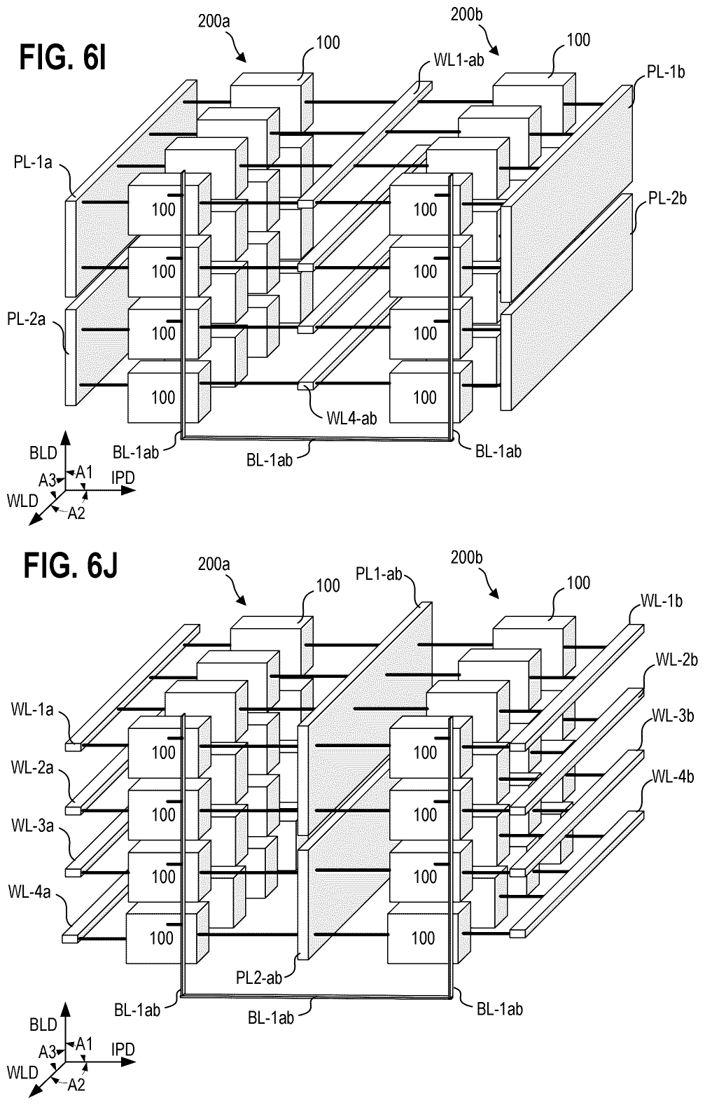

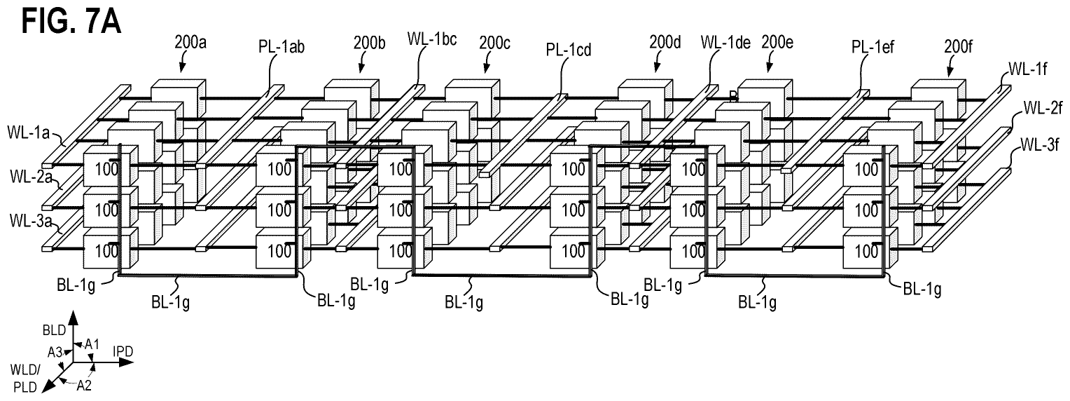

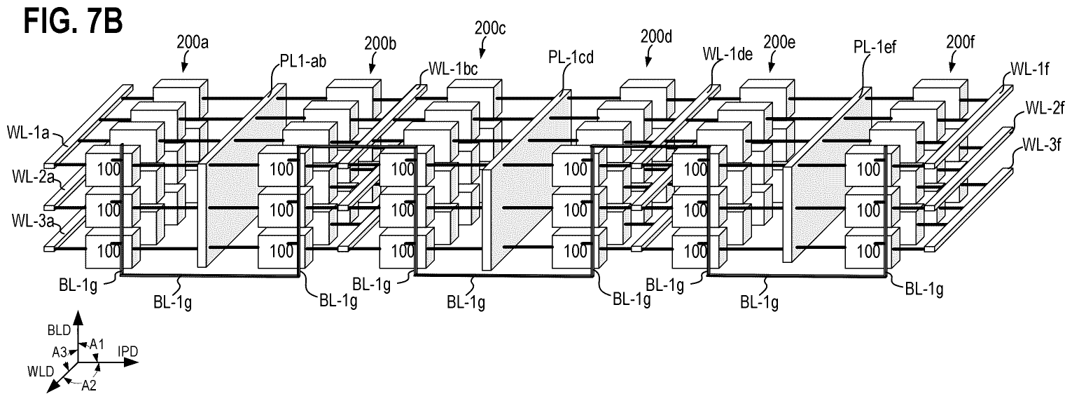

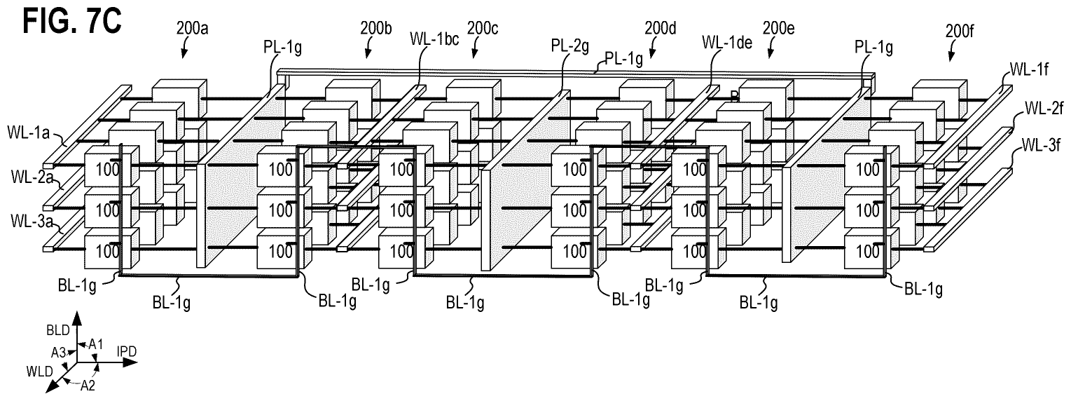

As an example, in the case that the bitlines run along the stacking direction and each of the bitlines shall logically address and connect a number of memory cells with one another (e.g., it may be desired that a bitline may logically address 1024 memory cells 100), and the number of stacks and therefore the number of stacked memory cells is lower than the number of memory cells to be logically addressed, each of the bitlines (see, for example, bitline BL1-ab in FIGS. 6A to 6J; for example, bitline BL-1g in FIGS. 7A to 7C; see, for example, bitlines BL-1ab, BL-1cd, BL-1ef in FIGS. 9A, 9B; see, for example, bitlines BL-1bc, BL-1de in FIGS. 9E, 9F, 9G; see, for example, bitlines BL-1g, BL-2g in FIGS. 9C, 9D) may connect a number of memory cells of a plurality of memory cell arrays with one another. FIGS. 6A to 6J illustrate a subset of memory cells of each of the two memory cell arrays 200a, 200b connected by a corresponding (shared) bitline BL1-ab. FIGS. 7A to 7C illustrate a subset of memory cells of each of the more than two memory cell arrays 200a, 200b, 200c, 200d, 200e, 200f connected by a corresponding (shared) bitline BL-1g. FIGS. 9A, 9B illustrate a subset of memory cells of each of the two memory cell arrays 200a, 200b and memory cell arrays 200c, 200d and memory cell arrays 200e, 200f connected by corresponding (shared) bitline BL-1ab, BL-1cd, BL-1ef respectively. FIGS. 9C, 9D illustrate a subset of memory cells of each of the more than two memory cell arrays 200a, 200b, 200e, 200f and memory cell arrays 200c, 200d connected by a corresponding (shared) bitline BL-1g, BL-2g respectively. FIGS. 9E, 9F, 9G illustrate a subset of memory cells of each of the two or more memory cell arrays 200b, 200c and memory cell arrays 200d, 200e connected by a corresponding (shared) bitline BL-1bc, BL-1de respectively. In the case that the number of memory cell stacks is 64, it may be desired that a bitline may logically address 1024 memory cells of 16 (e.g., neighboring or next but one) memory cell arrays and in the case that the number of memory cell stacks is 128, it may be desired that a bitline may logically address 1024 memory cells of 8 (e.g., neighboring or next but one) memory cell arrays, only as numerical examples.

As described herein, the addressing of the memory cells 100 of the one or more memory cell arrays may be realized by two or three types of control lines, a set of wordlines (in some aspects the wordlines may not be needed), a set of bitline, and a set of plateline. This allows for individually addressing and therefore individually operating (reading, writing, erasing, rewriting, etc.) each memory cell of the memory cell array.

Various aspects described herein may be related to directions related to the configuration of the control lines; wherein the directions are defined by the logically addressing of the one or more memory cell arrays of the memory chip 200. In some aspects, a control line direction (e.g., a wordline direction, a bitline direction, a plateline direction) may be defined by the direction along which a control line of a respective type of control lines (e.g., wordline, bitline, plateline) connects corresponding memory cells 100 of the one or more memory cell arrays with one another. In the case that a control line is configured as a control plate (e.g., a plateline may have a plate shape in some configurations), such a control plate may define (and, for example, run along) two directions, i.e., such a control plate may define a plane along which the control plate extends. In some aspects, a control plate may extend along a plane substantially perpendicular to the in-plane direction IPD, as illustrated for the control lines in plate configuration in FIGS. 2E, 3D, 3D, 3E, 3F, 3I, 3J, 3K, 3L, 3M, 4C, 4D, 4G, 4H, 4I, 4J, 5B, 5C, 6C, 6D, 6G, 6H, 6I, 6J, 7B, 7C, 8C, 8D, 8G, 8H, 8I, 8J, 9B, 9C, 9E, 9F.

FIG. 10A to FIG. 10D illustrate various configurations of the memory chip 200 with distinct relative positionings of the one or more memory cell arrays over the carrier 1000 of the memory chip 200. The carrier 1000 has a thickness d (e.g., a shortest dimension of the carrier may be usually its thickness) vertical to a main surface of the carrier over which the memory cells of the memory cell arrangement are disposed. The memory chip 200 has therefore a vertical direction Ve (substantially parallel to the thickness direction) and lateral directions La-1, La-2 associated therewith. The memory cells of the memory chip may be arranged such that the in-plane direction IPD is substantially perpendicular to the vertical direction Ve of the memory chip 200 and therefore substantially parallel to the main surface of the carrier 1000 of the memory chip defined by the lateral directions La-1, La-2. However, there may be various configurations for the orientation of the control lines relative to the carrier 1000.

As an example, the wordline direction WLD may be oriented substantially perpendicular to the bitline direction BLD and the bitline direction BLD may be oriented substantially parallel to the vertical direction Ve of the memory chip 200, as illustrated in FIG. 10A. In this case, the platelines may run along a plateline direction PLD substantially parallel to the bitline direction BLD or substantially parallel to the wordline direction WLD or may extend in a plate configuration in a plane substantially perpendicular to the in-plane direction IPD.

As an example, the wordline direction WLD may be oriented substantially perpendicular to the bitline direction BLD and the wordline direction WLD may be oriented substantially parallel to the vertical direction Ve of the memory chip 200, as illustrated in FIG. 10B. In this case, the platelines may run along a plateline direction PLD substantially parallel to the bitline direction BLD or substantially parallel to the wordline direction WLD or may extend in a plate configuration in a plane substantially perpendicular to the in-plane direction IPD.

As an example, the wordline direction WLD may be oriented substantially parallel to the bitline direction BLD and both the wordline direction WLD and the bitline direction BLD may be oriented substantially parallel to the vertical direction Ve of the memory chip 200, as illustrated in FIG. 10C. In this case, the platelines may run along a plateline direction PLD substantially perpendicular to the bitline direction BLD (therefore substantially perpendicular to the wordline direction WLD as well) and substantially perpendicular to the in-plane direction IPD.

As an example, the wordline direction WLD may be oriented substantially parallel to the bitline direction BLD and both the wordline direction WLD and the bitline direction BLD may be oriented substantially perpendicular to the vertical direction Ve of the memory chip 200, as illustrated in FIG. 10D. In this case, the platelines may run along a plateline direction PLD substantially parallel to the vertical direction Ve of the memory chip 200 (substantially perpendicular to the bitline direction BLD and therefore substantially perpendicular to the wordline direction WLD as well) and substantially perpendicular to the in-plane direction IPD.

In some aspects, control lines of the same type of control lines (e.g., wordlines, bitlines, platelines) extending along a vertical direction Ve of the memory chip (see FIGS. 10A to 10D) may be electrically conductively connected with one another to form connected control lines that address more memory cells than each vertically running segment of the connected control lines. Therefore, the connecting segments of such connected control lines may extend along a lateral direction La-1, La-2 of the memory chip 200. The connecting segments of such connected control lines may be arranged above and/or below the memory cell array on the memory chip 200, as illustrated in FIGS. 11A to 11C exemplarily for a connected bitline CBL-1.

As an example, a memory chip configuration with connected control lines is exemplarily illustrated in FIG. 11A to FIG. 11C. The connected bitline CBL-1 includes the (e.g., vertically running) bitlines BL-1a, BL-1b, BL-1c, wherein each of the bitlines BL-1a, BL-1b, BL-1c connect memory cells of the respective memory cell array 200a, 200b, 200c along the bitline direction BLD substantially parallel to the vertical direction Ve of the memory chip 200. The bitlines BL-la, BL-1b, BL-1c connecting memory cells of the respective memory cell array 200a, 200b, 200c may be (vertically arranged) segments of the connected bitline CBL-1. The connected bitline CBL-1 additionally includes bitline segments (at least partially running along a lateral direction, e.g., lateral direction La-2 substantially parallel to the in-plane direction IPD) connecting the bitlines BL-1a, BL-1b, BL-1c with one another.

In some aspects, the connecting segments of such connected control lines may be arranged below the one or more memory cell arrays 200a, 200b, 200c of the memory chip 200, e.g., the one or more memory cell arrays 200a, 200b, 200c of the memory chip 200 may be arranged between a part of the connected bitline CBL-1 (e.g., the connecting segments) and the carrier 1000 of the memory chip 200, as illustrated in FIGS. 11A. In other aspects, the connecting segments of such connected control lines may be arranged above the one or more memory cell arrays 200a, 200b, 200c of the memory chip 200, e.g., a part of the connected bitline CBL-1 (e.g., the connecting segments) may be arranged between the one or more memory cell arrays 200a, 200b, 200c and the carrier 1000 of the memory chip 200, as illustrated in FIGS. 11B. Furthermore, in a meander configuration, one or more first connecting segments of the connected bitline CBL-1 may be arranged below the one or more memory cell arrays 200a, 200b, 200c and one or more second connecting segments of the connected bitline CBL-1 may be arranged above the one or more memory cell arrays 200a, 200b, 200c, as illustrated in FIGS. 11C.

According to various aspects, a plurality of (e.g., all) memory cells 100 that are operable by (and, for example, connected to) a very same wordline WL may be operable by (and, for example, connected to) a very same plateline PL, as illustrated, for example, in FIGS. 2A, 2B, 2C, 2E and FIGS. 3D, 3F, 3H, 3I and FIG. 4G and FIGS. 6A, 6G, 6J and FIG. 9G. This configuration may allow for an operation of all memory cells logically addressed via a respective wordline by only one corresponding plateline PL. However, in this configuration, each of the memory cells that are logically addressed via a respective wordline may be operable by (and, for example, connected to) an individually assigned bitline BL to allow for an individual operation of the memory cells that are logically addressed via the respective wordline. In some aspects, the memory cells that are logically addressed via a respective wordline may not share a bitline with one another.

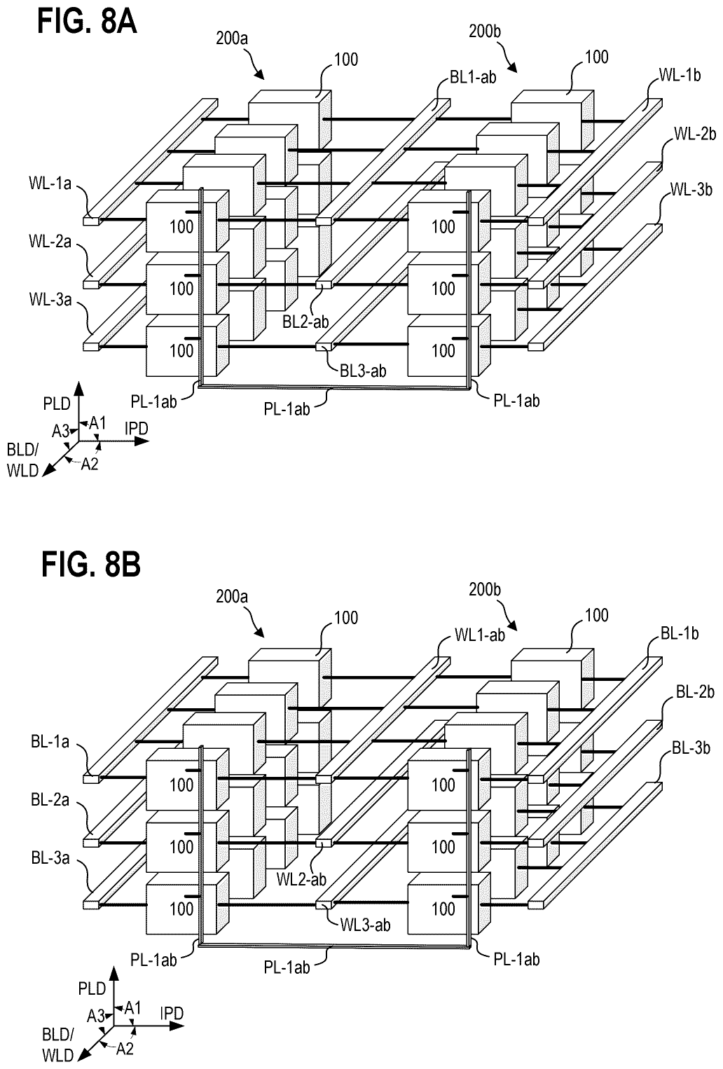

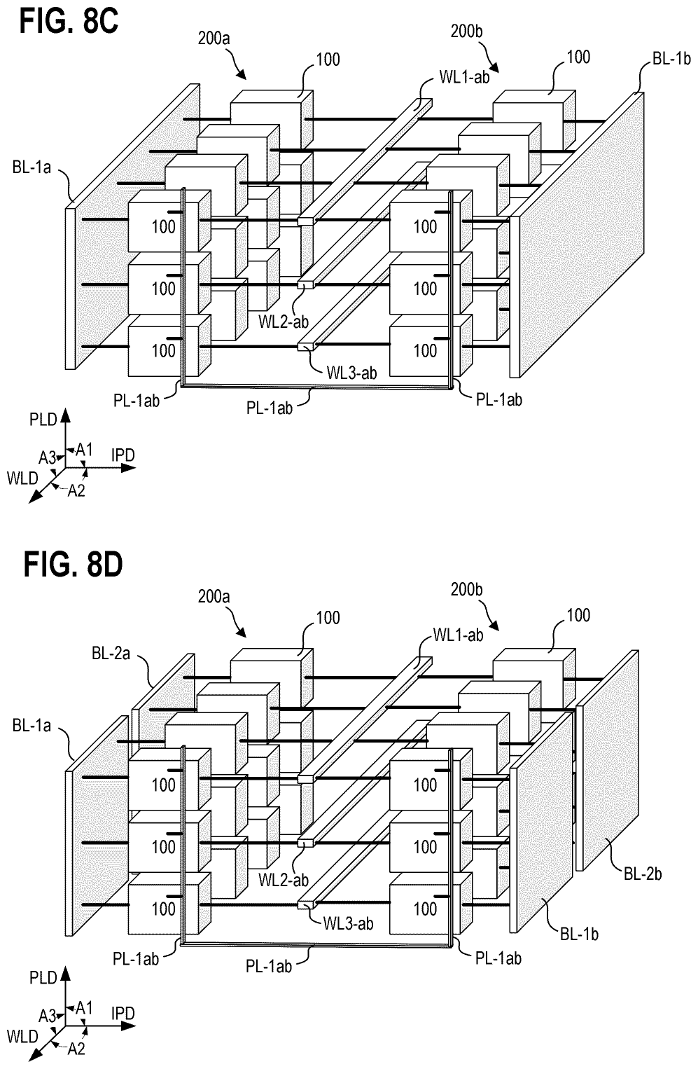

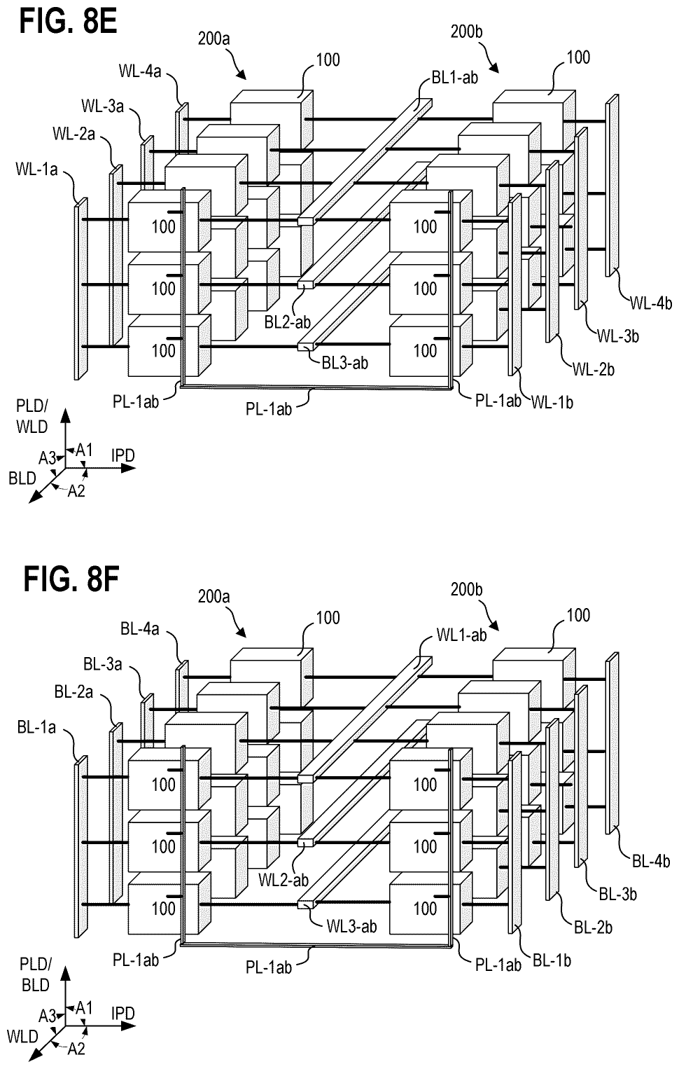

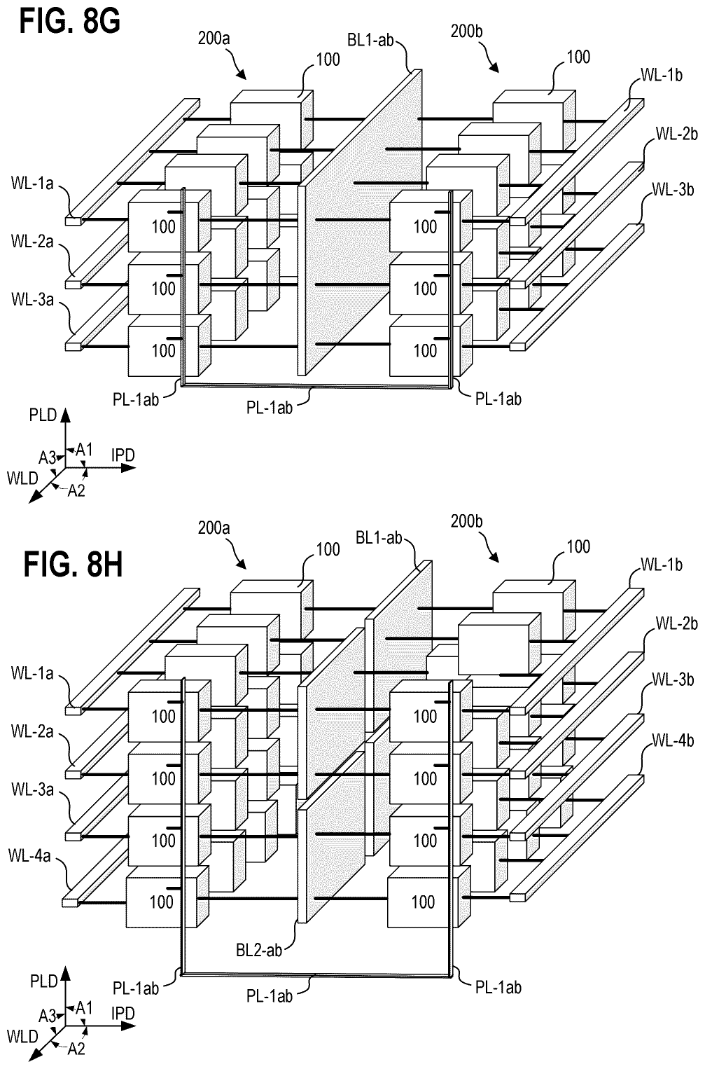

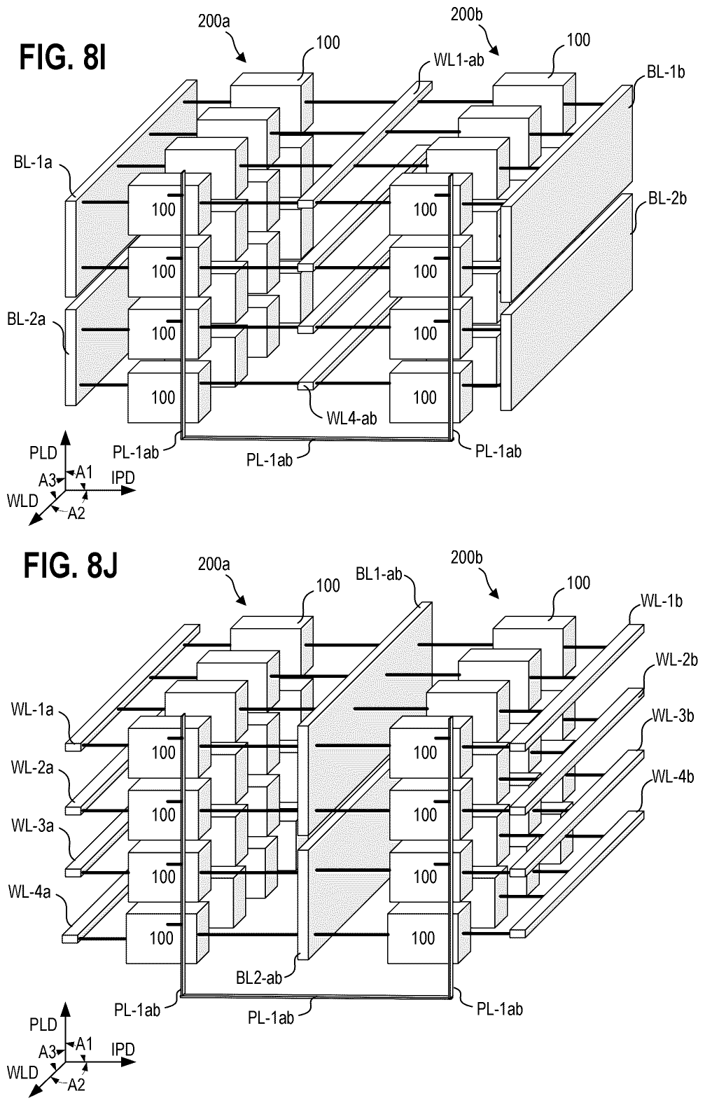

According to various aspects, each memory cell of a plurality of (e.g., all) memory cells 100 that are operable by (and, for example, connected to) a very same wordline WL of the set of wordlines may be unambiguously assigned to a corresponding plateline PL of the set of platelines. Therefore, each memory cell may be individually operable by (and, for example, connected to) a corresponding wordline/plateline pair, as illustrated, for example, in FIGS. 2D, 2F and FIGS. 3A, 3B, 3D, 3E, 3G, 3J, 3N and FIG. 4B and FIGS. 6E, 6F and FIGS. 8A, 8J. In this configuration, the bitlines may be optionally used to individually address the memory cells, e.g., two or more memory cells (e.g., all memory cells) that share a very same wordline WL may share a bitline as well (as illustrated for example in FIG. 2F and FIGS. 3D, 3E, 3G, 3J, 3N and FIG. 4B and FIGS. 6E, 6F and FIGS. 8A, 8J) or the memory cells (e.g., all memory cells) that share a very same wordline WL may be operable by (and, for example, connected to) individual bitlines (as illustrated for example in FIG. 2D and FIGS. 3A, 3B).

According to other aspects, a plurality of (e.g., all) memory cells 100 that are operable by (and, for example, connected to) a very same wordline WL may be operable by (and, for example, connected to) a set of two or more distinct platelines PL associated with the very same wordline, as illustrated, for example, in FIGS. 2D, 2F and FIGS. 3A, 3B, 3D, 3E, 3G, 3J, 3K, 3L, 3M, 3N and FIGS. 4A, 4B, 4C, 4D, 4E, 4F, 4H, 4I, 4J and FIGS. 5A, 5B, 5C and FIGS. 6B, 6C, 6D, 6E, 6F, 6H, 6I and FIGS. 7A, 7B, 7C and FIGS. 8A, 8B, 8C, 8D, 8F, 8G, 8H, 8I, 8J and FIGS. 9A, 9B, 9C, 9D, 9E, 9F.

According to various aspects, a first subset of memory cells of the set of memory cells 100 and a second subset of memory cells of the set of memory cells 100 may be operable by a very same wordline of the set of wordlines, and a plurality of (e.g., all) memory cells of the first subset of memory cells may be connected to a first plateline of the set of platelines and a plurality of (e.g., all) memory cells of the second subset of memory cells are connected to a second plateline (distinct from the first plateline, e.g., not electrically conductively connected to the first plateline) of the set of platelines, as illustrated, for example, in FIGS. 3K, 3L, 3M, and FIGS. 4C, 4D, 4F, 4H, 4I, 4J and FIGS. 5A, 5B, 5C and FIGS. 6B, 6C, 6D, 6H, 6I and FIGS. 7A, 7B, 7C and FIGS. 8B, 8C, 8D, 8F, 8I and FIGS. 9A, 9B, 9C, 9D, 9E, 9F. This configuration may allow for an operation of the memory cells logically addressed via a respective wordline by a corresponding set of platelines PL, wherein the memory cells logically addressed via the respective wordline may share one or more bitlines and one or more platelines. In some aspects, the memory cells that are logically addressed via a respective wordline and operable by distinct platelines (e.g., do not share a plateline as well) may share a bitline with one another and the memory cells that are logically addressed via a respective wordline and operable by distinct bitlines (e.g., do not share a bitline as well) may share a plateline with one another.

According to various aspects, each memory cell of a plurality of (e.g., all) memory cells 100 that are operable by (and, for example, connected to) a very same wordline WL of the set of wordlines may be unambiguously assigned to a corresponding bitline BL of the set of bitlines. Therefore, each memory cell may be individually operable by (and, for example, connected to) a corresponding wordline/bitline pair, as illustrated, for example, in FIGS. 2A, 2B, 2C, 2D, 2E and FIGS. 3A, 3B, 3D, 3F, 3H, 3I, 3K, 3L, 3M and FIGS. 4A, 4G, 4H, 4J, and FIGS. 6A, 6G, 6H, 6J, and FIGS. 8E, 8F and FIGS. 9D, 9G. In this configuration, the platelines may be optionally used to individually address the memory cells, e.g., two or more memory cells (e.g., all memory cells) that share a very same wordline WL may share a plateline as well (as illustrated for example in FIGS. 2A, 2B, 2C, 2E and FIGS. 3D, 3F, 3H, 3I, 3K, 3L, 3M and FIGS. 4A, 4G, 4H, 4J, and FIGS. 6A, 6G, 6H, 6J, and FIG. 8E, 8F and FIGS. 9D, 9G) or the memory cells (e.g., all memory cells) that share a very same wordline WL may be operable by (and, for example, connected to) individual platelines (as illustrated for example in FIG. 2D and FIGS. 3A, 3B).

According to various aspects, a plurality of memory cells of the set of memory cells 100 may be operable by (e.g. connected to) a very same wordline of the set of wordlines, and all memory cells of the plurality of memory cells operable by (e.g. connected to) the very same wordline may be operable by (e.g. connected to) a very same bitline of the set of bitlines, as illustrated, for example, in FIG. 2F and FIGS. 3G, 3J, 3N and FIGS. 8C, 8G, 8I, 8J and FIGS. 9A, 9B, 9C. In this configuration, memory cells that share the same wordline may share a bitline as well.

According to various aspects, at least two memory cells of the set of memory cells 100 may be operable by (e.g. connected to) a very same wordline of the set of wordlines, and the least two memory cells operable by (e.g. connected to) the very same wordline may be operable by (e.g. connected to) a very same bitline of the set of bitlines, as illustrated, for example, in FIG. 2F and FIGS. 3D, 3E, 3G, 3J, 3N and FIGS. 4B, 4C, 4D, 4E, 4F, 4I and FIGS. 5A, 5B, 5C and FIGS. 6B, 6C, 6D, 6E, 6F, 6I and FIGS. 7A, 7B, 7C and FIGS. 8A, 8B, 8C, 8D, 8G, 8H, 8I, 8J and FIGS. 9A, 9B, 9C, 9E, 9F. In this configuration, memory cells that share the same wordline may share a same bitline as well.

According to various aspects, a first subset of memory cells of the set of memory cells 100 and a second subset of memory cells of the set of memory cells 100 may be operable by (e.g. connected to) a very same wordline of the set of wordlines, and a plurality of (e.g., two or more, e.g., all) memory cells of the first subset of memory cells may be operable by (e.g. connected to) a first bitline of the set of bitlines and a plurality of (e.g., two or more, e.g., all) memory cells of the second subset of memory cells may be operable by (e.g. connected to) a second bitline (distinct from the first bitline, e.g., not electrically conductively connected to the first bitline) of the set of bitlines, as illustrated, for example, in FIGS. 4B, 4C, 4D, 4E, 4F, 4I and FIGS. 5A, 5B, 5C and FIGS. 6B, 6C, 6D, 6F, 6I and FIGS. 7A, 7B, 7C and FIGS. 8B, 8C, 8D, 8H, 8I and FIGS. 9A, 9B, 9C, 9E, 9F. In this configuration, memory cells that share the same wordline may share subset-wise a bitline as well.

According to various aspects, a subset of memory cells of the set of memory cells 100 may be operable by (e.g. connected to) a very same wordline of the set of wordlines, and two or more memory cells of the subset of memory cells may be operable by (e.g. connected to) a same bitline of the set of bitlines and wherein two or more other memory cells of the subset of memory cells may be connected to a same plateline of the set of platelines, as illustrated, for example, in FIGS. 4C, 4D, 4E, 4F, 4I and FIGS. 5A, 5B, 5C and FIGS. 6B, 6C, 6D, 6I and FIGS. 7A, 7B, 7C and FIGS. 8B, 8C, 8D, 8E, 8I and FIGS. 9A, 9B, 9C, 9E. In this configuration, memory cells that share the same wordline may share subset-wise a bitline and subset-wise a plateline as well. In this configuration, each of the subsets that shares a same bitline may not share a same plateline and each of the subsets that shares a same plateline may not share a same bitline to allow for an individual addressing of the memory cells that share a same wordline.

Several aspects are described with reference to a memory cell 100 including one access device AD and one memory capacitor MC. However, it is noted that in some aspects, no access device may be needed to address the memory cells of the memory cell array. In other aspects, more than one memory capacitor can be accessed by a shared access device.

FIG. 12 shows an exemplary configuration of a memory chip 200, wherein more than one memory capacitor MC is connected and addressed via a shared access device AD. It is noted that any of the memory cell arrays described herein can be implemented in a configuration in which more than one memory capacitor MC is connected and addressed via a shared access device AD similar to the example described with reference to FIG. 12. With respect to the individual addressing of a plurality of memory capacitors MC with a shared access device AD, various examples are as follows. The memory capacitors MC and access devices AD can be configured in the same way as described herein with reference to a memory cell 100 in which only one memory capacitor MC is addressed via a corresponding access device AD.

As an example (cf., FIG. 2A to FIG. 2F), a first memory capacitor MC-1/1a and a second memory capacitor MC-1/1b (and, for example, in the same manner MC-1/2a:MC-1/2b, MC-1/3A:MC-1/3B, MC-2/1a:MC-2/1b, MC-2/2a:MC-2/2b, MC-2/3A:MC-2/3B) may be addressed by a corresponding (shared) access device AD-1/1 (and, for example, in the same manner AD-1/2, AD-1/3, AD-2/1, AD-2/2, AD-2/3) controlled by a wordline/bitline pair connected to the corresponding (shared) access device AD-1/1 including the wordline WL-1 and the bitline BL-1 (and, for example, in the same manner WL-1/BL-2, WL-1/BL-3, WL-2/BL-1, WL-2/BL-2, WL-2/BL-3). For individually addressing two or more memory capacitors MC-1/1a:MC-1/1b sharing a corresponding access device AD-1/1, the first memory capacitor MC-1/1a may be operable by (e.g., connected to) a corresponding first plateline PL-1a and the second memory capacitor MC-1/1b may be operable by (e.g., connected to) a corresponding second plateline PL-1b.

According to various aspects, as described herein, the set of memory cells may include a first memory cell array (e.g., memory cell array 200a as example) and a second memory cell array (e.g., memory cell array 200b as example) arranged laterally next to one another. The first memory cell array and the second memory cell array may each include a number (SZ) of (lateral) memory cell sub-arrays stacked over one another along a stacking direction substantially perpendicular to a main surface of the memory chip and therefore substantially parallel to the vertical direction Ve. Various figures show exemplarily two (FIG. 2A to FIG. 2G) or three (FIG. 3A to FIG. 3J, FIG. 3N, FIG. 4A to FIG. 4G, FIG. 5A to FIG. 5C, FIG. 6A to FIG. 6G,

FIG. 7A to FIG. 7C, FIG. 8A to FIG. 8G, FIG. 9A to FIG. 9G) or four (FIG. 3K to FIG. 3M, FIG. 4H to FIG. 4J, FIG. 6H to FIG. 6J, FIG. 8H to FIG. 8J) (lateral) memory cell sub-arrays stacked over one another along the vertical direction Ve. The memory chip 200 may be configured to have any suitable number (SZ) of memory cell sub-arrays stacked over one another along the vertical direction Ve, e.g., with SZ=16, SZ=32, SZ=64, SZ=128 only as examples. In some aspects, the (lateral) memory cell sub-arrays stacked over one another are defined by the vertical direction Ve, since these memory cell sub-arrays are arrays that extend substantially perpendicular to the vertical direction and that are stacked over one another along the vertical direction.

According to various aspects, as described herein, both the in-plane direction IPD and the wordline direction WLD may be substantially parallel to the main surface of the memory chip 200 (substantially perpendicular to the vertical direction Ve), and the bitline direction BLD may be substantially perpendicular to the main surface of the memory chip and (therefore) substantially parallel to the stacking direction (the stacking direction may be the vertical direction Ve). In this configuration, a respective bitline BL of the set of bitlines may be configured to operate both a first number (SZ1) of memory cells of the first memory cell array that equals the number (SZ) of memory cell sub-arrays and a second number (SZ2) of memory cells of the second memory cell array that equals the number (SZ) of memory cell sub-arrays. See, for example, FIG. 6A to FIG. 6G showing exemplarily that for SZ-3 the bitline BL-1ab may be configured to operate a first column (a first vertical sub-array) of three memory cells 100 (SZ1=3) of the first memory cell array 200a and a second column (a second vertical sub-array) of three memory cells 100 (SZ2=3) of the second memory cell array 200b. See, for example, FIG. 6H to FIG. 6J showing exemplarily that for SZ=4 the bitline BL-1ab may be configured to operate a first column of four memory cells 100 (SZ1=4) of the first memory cell array 200a and a second column of four memory cells 100 (SZ2=4) of the second memory cell array 200b. See, for example, FIG. 7A to FIG. 7C showing exemplarily that for SZ=3 the bitline BL-1g may be configured to operate respective columns of three memory cells 100 of each of the memory cell arrays 200a, 200b, 200c, 200d, 200e, 200f. In this configuration, the number of wordlines may be the same as the number (SZ) of (lateral) memory cell sub-arrays stacked over one another. Each of the wordlines or one or more of the wordlines may define the size of the respective (lateral) sub-array. As an example, each (lateral) sub-array may include a row of memory cells 100 connected to a respective wordline. The memory chip 200 may be configured to have any suitable number of memory cells 100 included in each of the (lateral) sub-arrays, e.g., 32, 64, 128, 256, 512, 1024, 2048 memory cells (each connected and operated by a respective one of the wordlines).

According to various aspects, as described herein, both the in-plane direction IPD and the bitline direction BLD may be substantially parallel to the main surface of the memory chip 200 (substantially perpendicular to the vertical direction Ve), and the wordline direction WLD may be substantially perpendicular to the main surface of the memory chip and (therefore) substantially parallel to the stacking direction (the stacking direction may be the vertical direction Ve). In this configuration, a respective wordline WL of the set of wordlines may be configured to operate both a first number (SZ1) of memory cells of the first memory cell array that equals the number (SZ) of memory cell sub-arrays and a second number (SZ2) of memory cells of the second memory cell array that equals the number (SZ) of memory cell sub-arrays. See, for example, FIG. 4A to FIG. 4G showing exemplarily that for SZ=3 the wordline WL-1ab may be configured to operate a first column (a first vertical sub-array) of three memory cells 100 (SZ1=3) of the first memory cell array 200a and a second column (a second vertical sub-array) of three memory cells 100 (SZ2=3) of the second memory cell array 200b. See, for example, FIG. 4H to FIG. 4J showing exemplarily that for SZ=4 the wordline WL-1ab may be configured to operate a first column of four memory cells 100 (SZ1=4) of the first memory cell array 200a and a second column of four memory cells 100 (SZ2=4) of the second memory cell array 200b. See, for example, FIG. 5A to FIG. 5C showing exemplarily that for SZ-3 the wordline WL-1g may be configured to operate respective columns of three memory cells 100 of each of the memory cell arrays 200a, 200b, 200c, 200d, 200e, 200f. In this configuration, the number of bitlines may be the same as the number (SZ) of (lateral) memory cell sub-arrays stacked over one another. Each of the bitlines or one or more of the bitlines may define the size of the respective (lateral) sub-array. As an example, each (lateral) sub-array may include a row of memory cells 100 connected to a respective bitline. The memory chip 200 may be configured to have any suitable number of memory cells 100 included in each of the (lateral) sub-arrays, e.g., 32, 64, 128, 256, 512, 1024, 2048 memory cells (each connected and operated by a respective one of the bitlines).

According to various aspects, as described herein, the in-plane direction IPD and at least one of the wordline direction WLD and/or the bitline direction BLD may be substantially parallel to the main surface of the memory chip 200 (substantially perpendicular to the vertical direction Ve), and the plateline direction PLD may be substantially perpendicular to the main surface of the memory chip and (therefore) substantially parallel to the stacking direction (the stacking direction may be the vertical direction Ve). In this configuration, a respective plateline PL of the set of platelines may be configured to operate both a first number (SZ1) of memory cells of the first memory cell array that equals the number (SZ) of memory cell sub-arrays and a second number (SZ2) of memory cells of the second memory cell array that equals the number (SZ) of memory cell sub-arrays. See, for example, FIG. 8A to FIG. 8G showing exemplarily that for SZ=3 the plateline PL-1ab may be configured to operate a first column (a first vertical sub-array) of three memory cells 100 (SZ1=3) of the first memory cell array 200a and a second column (a second vertical sub-array) of three memory cells 100 (SZ2=3) of the second memory cell array 200b. See, for example, FIG. 4H to FIG. 4J showing exemplarily that for SZ=4 the plateline PL-1ab may be configured to operate a first column of four memory cells 100 (SZ1=4) of the first memory cell array 200a and a second column of four memory cells 100 (SZ2=4) of the second memory cell array 200b. See, for example, FIG. 9A to FIG. 9G showing exemplarily that for SZ=3 the plateline PL-1g may be configured to operate respective columns of three memory cells 100 of each of the memory cell arrays 200a, 200b, 200c, 200d, 200e, 200f. In this configuration, the number of wordlines and/or bitlines may be the same as the number (SZ) of (lateral) memory cell sub-arrays stacked over one another. In some aspects, each of the bitlines or one or more of the bitlines may define the size of the respective (lateral) sub-array and, in other aspects, each of the wordlines or one or more of the wordlines may define the size of the respective (lateral) sub-array. As an example, each (lateral) sub-array may include a row of memory cells 100 connected to a respective bitline (see FIG. 9E to FIG. 9G) or to a respective wordline (see FIG. 9A to FIG. 9D). The memory chip 200 may be configured to have any suitable number of memory cells 100 included in each of the (lateral) sub-arrays, e.g., 32, 64, 128, 256, 512, 1024, 2048 memory cells (each connected and operated by a respective one of the bitlines and/or bitlines).

According to various aspects, each plateline PL of the set of platelines may be connected to a first number (SP1) of memory cells of the first memory cell array (e.g., memory cell array 200a) and to a second number (SP2) of memory cells of the second memory cell array (e.g., memory cell array 200b), see, for example, FIGS. 3A, 3D, 3E, 3G, 3I, 3L, 3M and FIGS. 4A, 4E, 4G, 4H, 4J and FIG. 5A to FIG. 5C and FIGS. 6A, 6E, 6G, 6H, 6J and FIG. 7A to FIG. 7C and FIG. 8A to FIG. 8J and FIG. 9A to FIG. 9G only as some examples. In some aspects, both the first number (SP1) of memory cells of the first memory cell array and the second number (SP2) of memory cells of the second memory cell array are greater than the number (SZ) of memory cell sub-arrays stacked over one another. In other words, the total number of memory cells that share a very same plateline is greater than the number (SZ) of the corresponding memory cell sub-arrays stacked over one another including the total number of memory cells that share a very same plateline. In some aspects, all memory cells of the first memory cell array may share a plateline and all memory cells of the second memory cell array may share a plateline (see, for example, FIGS. 3D, 3I, 4C, 4G, 5B, 5C, 6C, 6G, 7B, 7C only as some examples). In some aspects, both all memory cells of the first memory cell array (e.g., memory cell array 200a) and all memory cells of the second memory cell array (e.g., memory cell array 200b) may share a very same plateline (see, for example, FIGS. 31, 4G, 5B, 5C, 6G, 7B, 7C only as some examples). In some aspects, the first number (SP1) of memory cells of the first memory cell array (e.g., memory cell array 200a) sharing a same plateline equals the second number (SP2) of memory cells of the second memory cell array (e.g., memory cell array 200b) sharing the same plateline.

According to various aspects, each bitline BL of the set of bitlines may be connected to a first number (SB1) of memory cells of the first memory cell array (e.g., memory cell array 200a) and to a second number (SB2) of memory cells of the second memory cell array (e.g., memory cell array 200b), see, for example, FIGS. 3B, 3D, 3F, 3H, 3J, 3K, 3N and FIGS. 4B, 4C, 4D, 4F, 4I and FIG. 5A to FIG. 5C and FIG. 6A to FIG. 6J and FIG. 7A to FIG. 7C and FIGS. 8A, 8E, 8G, 8H, 8J and FIG. 9A to FIG. 9G only as some examples. In some aspects, both the first number (SB1) of memory cells of the first memory cell array and the second number (SB2) of memory cells of the second memory cell array are greater than the number (SZ) of memory cell sub-arrays stacked over one another. In other words, the total number of memory cells that share a very same bitline is greater than the number (SZ) of the corresponding memory cell sub-arrays stacked over one another including the total number of memory cells that share a very same bitline. In some aspects, all memory cells of the first memory cell array may share a bitline and all memory cells of the second memory cell array may share a bitline (see, for example, FIGS. 3D, 3J, 8C, 8G, 9B, 9C only as some examples). In some aspects, both all memory cells of the first memory cell array and all memory cells of the second memory cell array may share a very same bitline (see, for example, FIGS. 3J, 8G, 9B, 9C only as some examples). In some aspects, the first number (SB1) of memory cells of the first memory cell array (e.g., memory cell array 200a) sharing a same bitline equals the second number (SB2) of memory cells of the second memory cell array (e.g., memory cell array 200b) sharing the same bitline.

According to various aspects, each wordline WL of the set of wordlines may be connected to a first number (SW1) of memory cells of the first memory cell array (e.g., memory cell array 200a) and to a second number (SW2) of memory cells of the second memory cell array (e.g., memory cell array 200b), see, for example, FIG. 4A to FIG. 4J and FIG. 5A to FIG. 5C and FIGS. 6B, 6C, 6D, 6F, 6I and FIG. 7A to FIG. 7C and FIGS. 8B, 8C, 8D, 8F, 8I and FIG. 9A to FIG. 9G only as some examples. In some aspects, both the first number (SW1) of memory cells of the first memory cell array and the second number (SW2) of memory cells of the second memory cell array are greater than the number (SZ) of memory cell sub-arrays stacked over one another. In other words, the total number of memory cells that share a very same wordline is greater than the number (SZ) of the corresponding memory cell sub-arrays stacked over one another including the total number of memory cells that share a very same wordline. In some aspects, all memory cells of the first memory cell array may share a wordline and all memory cells of the second memory cell array may share a wordline. In some aspects, both all memory cells of the first memory cell array and all memory cells of the second memory cell array may share a very same wordline (see, for example, FIGS. 9E, 9F only as some examples). In some aspects, the first number (SW1) of memory cells of the first memory cell array (e.g., memory cell array 200a) sharing a same wordline equals the second number (SW2) of memory cells of the second memory cell array (e.g., memory cell array 200b) sharing the same wordline.

FIG. 13A shows exemplarily a schematic cross-sectional view of memory stack 1300 including a number NL of memory capacitor layers (Layer 1 to Layer NL). Each memory capacitor layer includes a plurality of memory capacitors 120 embedded in a support material 130 (e.g., the support material 130 may be a dielectric material, e.g., silicon oxide, e.g., silicon nitride, e.g., silicon oxynitride), according to various aspects. The plurality of memory capacitors 120 in each memory capacitor layer forms a two-dimensional array of memory capacitors arranged in a plane substantially perpendicular to the vertical direction Ve. Each memory capacitor 120 (provided by a memory layer stack) includes a memory element 124 disposed between a first electrode 126 and a second electrode 128, as described herein (see for example FIG. 1A and FIG. 1B).

As an example, the memory capacitor 120 described herein may be fabricated by forming a core structure (e.g., a pillar, a tube, a sheet, only as example) 1300c, and conformally covering the core structure 1300c by one or more layers that form a memory layer stack that provides the memory capacitor 120. The core structure 1300c may include (e.g., may be) the first electrode 126 of the memory capacitor 120, at least one first conformal layer 1300m of the memory layer stack may include the memory material and form the memory element 124 of the memory capacitor 120, and at least one second conformal layer 1300e of the memory layer stack may include (e.g., may be) the second electrode 128 of the memory capacitor 120. The core structure 1300c and therefore the memory capacitor 120 may extend along the in-plane direction IPD.

FIG. 13B to FIG. 13N show schematic cross-sectional views substantially perpendicular to the in-plane direction IPD of one or more memory capacitors 120 each provided by a memory layer stack embedded in the support material 130 (related to the memory capacitors 120 illustrated in FIG. 13A). FIG. 13B illustrates each of the memory capacitors 120 configured in a concentric arrangement of layers, wherein the core structure 1300c that includes (e.g., is) the first electrode 126 is completely surrounded by the at least one first conformal layer 1300m that includes the memory material and forms the memory element 124, and wherein the at least one first conformal layer 1300m is completely surrounded by the at least one second conformal layer 1300e that includes (e.g., is) the second electrode 128. In the case that the core structure 1300c (e.g., the first electrode 126) has a hollow shape (e.g., a shape of a hollow tube), as illustrated in FIG. 13D, the at least one first conformal layer 1300m completely surrounds an inner surface of the core structure 1300c and an outer surface of the core structure 1300c. In other words, the memory material can cover two opposing surfaces of the first electrode 126 to increase capacitance of the memory capacitor 120. In this case, the at least one second conformal layer 1300m completely surrounds an inner surface of the memory element 124 and an outer surface of the memory element. In other words, the second electrode may contact both a first portion of the memory material disposed over the inner surface of the core structure 1300c and a second portion of the memory material disposed over the outer surface of the core structure 1300c.

In the case that the core structure 1300c (e.g., the first electrode 126) has a hollow shape (e.g., a shape of a hollow tube), as illustrated in FIG. 13D, the second electrode 128 may be provided by a conformal layer deposited into the hollow shape (e.g., after the memory material is deposited conformally into the hollow shape) and completely fill the hollow shape with electrode material of the second electrode 128. Alternatively, the conformal electrode layer deposited into the hollow shape may only partially fill the hollow shape and an airgap may remain within the memory capacitor 120.

As illustrated in FIG. 13B and FIG. 13D, a spontaneously polarizable memory layer (included in and/or provided by the at least one first conformal layer 1300m) may completely surround the first electrode 126 (included in and/or provided by the core structure 1300c) with respect to a plane substantially perpendicular to the in-plane direction (IPD). Furthermore, the second electrode 128 (included in and/or provided by the at least one second conformal layer 1300e) may completely surround the spontaneously polarizable memory layer (included in and/or provided by the at least one first conformal layer 1300m) with respect to the plane substantially perpendicular to the in-plane direction.

As illustrated in an exemplary schematic cross-sectional view in FIG. 13D and FIG. 13E, a spontaneously polarizable memory layer (included in and/or provided by the at least one first conformal layer 1300m) may completely surround the first electrode 126 (included in and/or provided by the core structure 1300c) with respect to a plane substantially perpendicular to the in-plane direction (IPD). As illustrated in an exemplary schematic cross-sectional view in FIG. 13F and FIG. 13G, a spontaneously polarizable memory layer (included in and/or provided by the at least one first conformal layer 1300m) may only partially surround the first electrode 126 (included in and/or provided by the core structure 1300c) with respect to a plane substantially perpendicular to the in-plane direction (IPD). Furthermore, the second electrode 128 (included in and/or provided by the at least one second conformal layer 1300e) may only partially surround the spontaneously polarizable memory layer (included in and/or provided by the at least one first conformal layer 1300m) with respect to the plane substantially perpendicular to the in-plane direction. In this case, the formed memory capacitor can be a single memory capacitor in that case that the at least two portions of the second electrode 128 are electrically conductively connected with one another and therefore are controlled as a single second electrode. Alternatively, two distinct memory capacitors may be formed by at least two distinct portions of the second electrode 128 in the case that the at least two distinct portions of the second electrode 128 are electrically separated from one another and therefore are controlled as at least two distinct second electrodes.

As illustrated in an exemplary schematic cross-sectional view in FIG. 13H and FIG. 13I, a spontaneously polarizable memory layer (included in and/or provided by the at least one first conformal layer 1300m) may completely surround the first electrode 126 (included in and/or provided by the core structure 1300c) with respect to a plane substantially perpendicular to the in-plane direction (IPD). Furthermore, the second electrode 128 (included in and/or provided by the at least one second conformal layer 1300e) may only partially (see FIG. 13H) or completely (see FIG. 13I) surround the spontaneously polarizable memory layer (included in and/or provided by the at least one first conformal layer 1300m) with respect to the plane substantially perpendicular to the in-plane direction. In some aspects, the first electrode 126 may include at least two electrode portions. In this case, the formed memory capacitor can be a single memory capacitor in that case that the at least two portions of the first electrode 126 are electrically conductively connected with one another and therefore are controlled as a single first electrode 126. Alternatively, two distinct memory capacitors may be formed by at least two distinct portions of the first electrode 126 in the case that the at least two distinct portions of the first electrode 126 are electrically separated from one another and therefore are controlled as at least two distinct second electrodes.

Various memory capacitors are illustrated to have a circular arrangement of layers in the cross-sectional view, see for example FIG. 13B to FIG. 13I. However, the memory layer stack that forms the respective memory capacitor may have any other geometry that is suitable within the memory stack 1300. FIG. 13J to FIG. 13N show schematic cross-sectional views substantially perpendicular to the in-plane direction IPD of a memory capacitor 120, wherein the memory layer stack forms planar configurations of the memory capacitor 120. In the planar configurations, a spontaneously polarizable memory layer (included in and/or provided by the at least one first conformal layer 1300m) may partially (see FIG. 13L and FIG. 13M) or completely (see FIGS. 13J, 13K, 13N) surround the first electrode 126 (included in and/or provided by the core structure 1300c) with respect to a plane substantially perpendicular to the in-plane direction (IPD). Furthermore, the second electrode 128 (included in and/or provided by the at least one second conformal layer 1300e) may partially (see FIG. 13L and FIG. 13M) or completely (see FIGS. 13J, 13K, 13N) surround the spontaneously polarizable memory layer (included in and/or provided by the at least one first conformal layer 1300m) with respect to the plane substantially perpendicular to the in-plane direction.

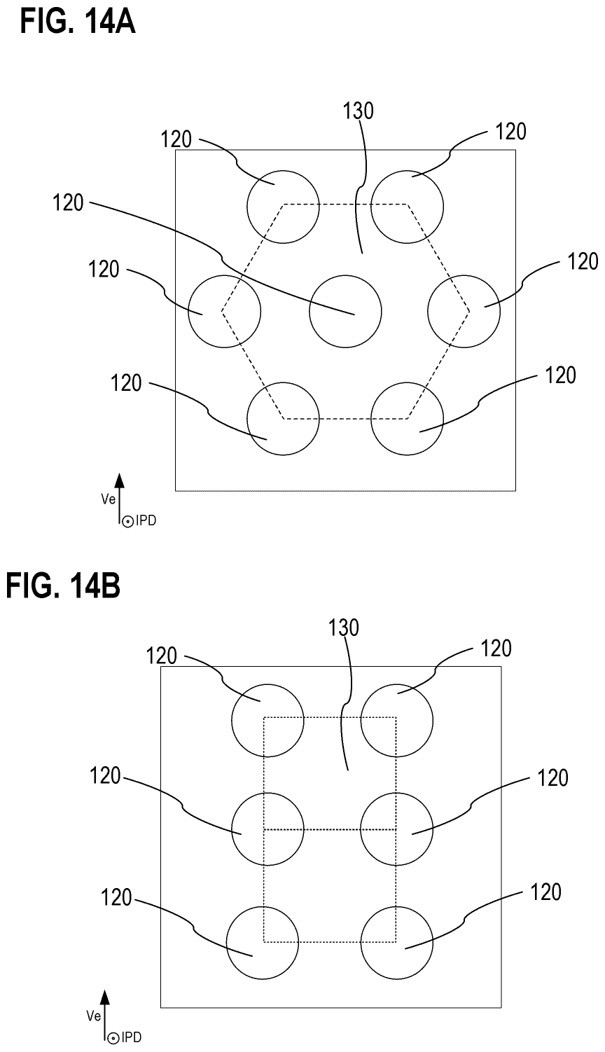

FIG. 14A shows a schematic hexagonal arrangement of the memory cells 120 with reference to a cross sectional plane substantially perpendicular to the in-plane direction IPD, according to various aspects. FIG. 14B shows a schematic rectangular arrangement of the memory cells 120 with reference to a cross sectional plane substantially perpendicular to the in-plane direction IPD, according to various aspects. The hexagonal arrangement (see FIG. 14A) may have, in some aspects, advantages in terms of packing density of the stacked memory cells 120. However, the rectangular (e.g., square) arrangement (see FIG. 14B) may have, in some aspects, advantages in terms of fabrication complexity.

According to various aspects, the spontaneously polarizable memory layer (included in and/or provided by the at least one first conformal layer 1300m) may surround (e.g., cover in direct physical contact) to opposing surfaces of the first electrode 126. This configuration may increase the capacitance of the memory capacitor 120. According to various aspects, two or more second electrodes 128 of two or more memory capacitors 120 may share a single first electrode 126 (see, for example, FIGS. 13D, 13F, 13M). According to various aspects, two or more first electrodes 126 of two or more memory capacitors 120 may share a single second electrode 128 (see, for example, FIG. 13I). According to various aspects, one or more first electrodes 126 of one or more memory capacitors 120 and/or one or more second electrodes 128 of one or more memory capacitors 120 may share a spontaneously polarizable memory layer (see, for example, FIG. 13K), e.g., included in and/or provided by the at least one first conformal layer 1300m.

FIG. 15A to FIG. 15F show various exemplary configurations of a memory capacitor 120, wherein a metal electrode layer of the memory capacitor 120 is formed over and/or embedded in a support material 130 according to various aspects. The support material 130 may be an oxide material, e.g., silicon oxide. As described herein, the memory capacitor 120 may include the memory element 124 (e.g., substantially consisting of one or more transition-metal-oxides), the first electrode 126 (which may also be referred to as bottom electrode), and the second electrode 128 (which may also be referred to as top electrode).

With reference to FIG. 15A, FIG. 15C, FIG. 15E, and FIG. 15F, the first electrode 126 may include a first electrically conductive electrode layer 132 and a first functional layer 134. The first electrically conductive electrode layer 132 may be disposed between (and optionally in direct contact with) the first functional layer 134 and the memory element 124.

According to various aspects, the first electrically conductive electrode layer 132 may substantially consist of a first metal, such as Copper (Cu), Platinum (Pt), Iridium (Ir), Rhenium (Re), Rhodium (Rh), Palladium (Pd), Ruthenium (Ru), Titanium (Ti), Osmium (Os), Molybdenum (Mo), Chromium (Cr), Tungsten (W), Silver (Ag), Aluminum (Al), Gold (Au), Cobalt (Co), only as example. According to various aspects, the first electrically conductive electrode layer 132 may include a conductive metal oxide, such as preferably tungsten oxide. According to various aspects, the first electrically conductive electrode layer 132 may include both a metal and a conductive metal oxide of the metal, such as preferably both tungsten and tungsten oxide.

The first functional layer 134 may substantially consist of a first metal nitride or a first metal-oxynitride. The metal of the first metal nitride or the first metal-oxynitride may be Copper (Cu), Platinum (Pt), Iridium (Ir), Rhenium (Re), Rhodium (Rh), Palladium (Pd), Ruthenium (Ru), Titanium (Ti), Osmium (Os), Molybdenum (Mo), Chromium (Cr), Tungsten (W), Silver (Ag), Aluminum (Al), Gold (Au), Cobalt (Co), etc. In some aspects, the metal of the first metal nitride or the first metal-oxynitride may be the same metal as the first metal. In other aspects, the metal of the first metal nitride or the first metal-oxynitride may be a metal different from the first metal.

For example, in the case that the support material 130 includes the oxide layer at its interface to the memory capacitor or in the case that the support material 130 is an oxide structure or an oxide layer stack (e.g., the support material 130 may substantially consist of a low-k oxide material, such as silicon oxide), depositing a metal material (e.g., the first electrically conductive electrode layer 132) directly on the oxide layer using ALD may, for some metal materials, not be beneficial. As an example, the deposition process may result in a damaged interface (due to an etching of a surface of the oxide layer), thereby significantly affecting the electronic properties of the memory capacitor 120. The use of the first functional layer 134 between an oxide material interface and the first electrically conductive electrode layer may allow for a more efficient fabrication.

The second electrode 128 may include a second electrically conductive electrode layer 136. As shown in FIG. 15A, FIG. 15C, FIG. 15E, and FIG. 15F, the second electrically conductive electrode layer 136 may be disposed over (e.g., directly on) the memory element 124. This may be beneficial in the case that the second electrically conductive electrode layer 136 does not substantially consist of a metal material. As an example, in this case, the second electrically conductive electrode layer 136 may include (e.g., may consist of) a metal nitride. The metal nitride may be, for example, a titanium-based alloy (e.g., TiN, e.g., Ti—C—N, e.g., Ti—Al—N, e.g., TiN—TaN), a tantalum-based alloy (e.g., TaN, e.g., Ta—C—N, e.g., TaN—TiN), or a tungsten-based nitride (e.g., WN). As another example, in this case, the second electrically conductive electrode layer 136 may include (e.g., may consist of) an oxidation resistant metal (e.g., a noble metal). This may reduce a possible oxidation of the interface of the second electrically conductive electrode layer 136. The oxidation resistant metal may include (e.g., consist of), for example, tungsten, platinum, iridium, ruthenium, palladium, osmium, rhodium, molybdenum, cobalt, rhenium, or nickel.

With reference to FIG. 15B, FIG. 15D, FIG. 15E, and FIG. 15F, the second electrode 128 may include a second functional layer 138. The second functional layer 138 may be disposed between (and optionally in direct contact with) the memory element 124 and the second electrically conductive electrode layer 136.

According to various aspects, the second electrically conductive electrode layer 136 may substantially consist of a second metal, such as Copper (Cu), Platinum (Pt), Iridium (Ir), Rhenium (Re), Rhodium (Rh), Palladium (Pd), Ruthenium (Ru), Titanium (Ti), Osmium (Os), Molybdenum (Mo), Chromium (Cr), Tungsten (W), Silver (Ag), Aluminum (Al), Gold (Au), Cobalt (Co), etc. In some aspects, the first metal and the second metal may be a same metal material. In other aspects, the second metal may be a metal different from the first metal.

The second functional layer 138 may substantially consist of a second metal nitride or a second metal-oxynitride. The metal of the second metal nitride or the second metal-oxynitride may be Copper (Cu), Platinum (Pt), Iridium (Ir), Rhenium (Re), Rhodium (Rh), Palladium (Pd), Ruthenium (Ru), Titanium (Ti), Osmium (Os), Molybdenum (Mo), Chromium (Cr), Tungsten (W), Silver (Ag), Aluminum (Al), Gold (Au), Cobalt (Co), etc. In some aspects, the metal of the second metal nitride or the second metal-oxynitride may be the same metal as the second metal. In other aspects, the metal of the second metal nitride or the second metal-oxynitride may be a metal different from the second metal. According to various aspects, the second electrically conductive electrode layer 136 may include a conductive metal oxide, such as preferably tungsten oxide. According to various aspects, the second electrically conductive electrode layer 136 may include both a metal and a conductive metal oxide of the metal, such as preferably both tungsten and tungsten oxide.

For example, in the case that the memory element 124 includes an oxide material (e.g., in the case that the memory element 124 substantially consists of one or more transition-metal-oxides, such as HZO), depositing a metal material (e.g., the second electrically conductive electrode layer 136) directly on the memory element 124 using ALD may, for some metal materials, not be beneficial and may, for example, result in a damaged interface (due to an etching of a surface of the memory element 124), thereby affecting the electronic properties of the memory capacitor 120. The use of the second functional layer 138 between the memory element 124 and the second electrically conductive electrode layer 136 may be beneficial.

As shown in FIG. 15B and FIG. 15D, the memory capacitor 120 may include, in some aspects, the second functional layer 138 but not the first functional layer 134. This may be the case, if the first electrically conductive electrode layer 132 is not deposited using ALD and/or if the support material 130 does not have the oxide layer at its interface to the memory capacitor 120 and/or if the first electrically conductive electrode layer 132 does not substantially consist of a metal material. As an example, in this scenario, the first electrically conductive electrode layer 132 may include (e.g., may consist of) a metal nitride. The metal nitride may be, for example, a titanium-based alloy (e.g., TiN, e.g., Ti—C—N, e.g., Ti—Al—N, e.g., TiN—TaN), a tantalum-based alloy (e.g., TaN, e.g., Ta—C—N, e.g., TaN—TiN), or a tungsten-based nitride (e.g., WN). As another example, in this scenario, the first electrically conductive electrode layer 132 may include (e.g., may consist of) an oxidation resistant metal (e.g., a noble metal). This may avoid an oxidation of the interface of the first electrically conductive electrode layer 132. The oxidation resistant metal may include (e.g., consist of), for example, tungsten, platinum, iridium, ruthenium, palladium, osmium, rhodium, molybdenum, cobalt, rhenium, or nickel.

Thus, according to various aspects, the first electrically conductive electrode layer 132 may be deposited on the first functional layer 134 using ALD and/or the second electrically conductive electrode layer 136 may be deposited on the second functional layer 138 using ALD. Illustratively, the first functional layer 134 and the second functional layer 138 can be a nucleation layer for the respective electrode layer 132/136. In the case that the first metal and/or the second metal is tungsten, it may not be easily possible to deposit tungsten directly on an oxide material (e.g., on silicon oxide of the support material 130 and/or on one or more transition-metal-oxides of the memory element 124) using ALD as a conformal deposition process needed to fabricate the memory stack 1300.

According to various aspects, the first electrode 126 and/or the second electrode 128 may be in a symmetric configuration relative to its coverage by additional material. Thus, the first electrode 126 may, in addition to the first functional layer 134, further include a further first functional layer 140 over (e.g., directly on) the first electrically conductive electrode layer 132 (see, for example, FIG. 15C and FIG. 15F). Accordingly, the second electrode 128 may, in addition to the second functional layer 138, further include a further second functional layer 142 over (e.g., directly on) the second electrically conductive electrode layer 136 (see, for example, FIG. 15D and FIG. 15F). Having such a symmetric electrode may improve the electronic properties of the memory capacitor 120. Illustratively, the respective electrically conductive electrode layer may be sandwiched between two functional layers.

According to various aspects, the memory element 124 may substantially consist of one or more transition-metal-oxides and the metal of the metal nitride or metal-oxynitride of the first functional layer 134 and/or the second functional layer 138 may be a transition metal of the one or more transition-metal-oxides. Hence, the metal nitride may, for example, be hafnium nitride or zirconium nitride in the case that the memory element 124 substantially consists of hafnium oxide, zirconium oxide, or hafnium zirconium oxide.

According to various aspects, a memory cell arrangement (e.g., a dynamic random access memory, DRAM) may include a plurality of memory cells each including the memory capacitor 120 described herein. The memory chip 200 may include a carrier 1000 (also referred to as a substrate) having the patterned support material 130 disposed thereon to fabricate at least a part of the memory capacitors 120 in the three-dimensional arrangement described herein.

According to various aspects, the memory capacitors 120 may have no functional layers included therein, as shown in FIG. 15G, wherein the respective electrode layers 132/136 are both in direct physical contact with the memory element 124.

FIG. 16A and FIG. 16B illustrate a schematic view of a memory chip 200 that includes a sense circuit 1600 associated with the set of memory cells 100, according to various aspects. The sense circuit 1600 may include a total number (NC) of sense elements 1610 (e.g., sense elements 1610(1) to 1610(NC)) associated with the set of bitlines BL (e.g., bitlines BL(1) to BL(NB)). A total number (NM) of memory cells (e.g., NM≥512, e.g., NM≥1024, e.g., NM≥2048) of the set of memory cells 100 may share a very same wordline WL of the set of wordlines and may be connected to a total number (NB) of bitlines BL of the set of bitlines (e.g., NB≥512, e.g., NB≥1024, e.g., NB≥2048).

In some aspects, the total number (NC) of sense elements may be at least equal to the total number (NB) of bitlines connected to the total number (NM) of memory cells of the set of memory cells that share the very same wordline WL, as illustrated in FIG. 16A. In this configuration, all NM memory cells 100 (e.g., memory cells 100(1 to NM)) addressed by the very same wordline WL are operable (e.g., can be read and/or written) at the same time via the NC sense elements 1610 (e.g., sense elements 1610(1 to NC)) and the corresponding NB bitlines BL (e.g., bitlines BL(1 to NB)). In this case the condition is as follows: NC=NB=NM.

In other aspects, as illustrated in FIG. 16B, the total number (NC) of sense elements (e.g., sense elements 1610(1 to NC)) may be less than the total number (NB) of bitlines (e.g., bitlines BL(1 to NB)) connected to the total number (NM) of memory cells (e.g., memory cells 100(1 to NM)) of the set of memory cells that share the very same wordline WL. In this configuration, only a subset of memory cells 100 addressed by the very same wordline WL can be operated (read out and/or written) at the same time via the NC sense elements 1610. In some aspects, a selection circuit (e.g., a multiplexer circuit) 1620 may be configured to select a subset of memory cells 100 to be operated (read and/or written) via the sense elements 1610. As an example, n₁ memory cells (e.g., memory cells 100(1 to n₁)) of a first subset of the NM memory cells 100(1 to NM) may be selectively coupled to the NC sense elements 1610(1 to NC) of the sense circuit 1600 via a corresponding first subset of n1 bitlines BL(1 to n₁) and the selection circuit (e.g., the multiplexer circuit) 1620. Furthermore, n₁ other memory cells (e.g., memory cells 100(n₁+1 to 2·n₁+1) of a second subset of the NM memory cells 100(1 to NM) may be selectively coupled to the NC sense elements 1610(1 to NC) of the sense circuit 1600 via the corresponding second subset of n1 bitlines BL(n₁+1 to 2·n₁+1) and the selection circuit (e.g., the multiplexer circuit) 1620. According to various aspects, two or more memory cells 100 of the memory chip 200 (e.g., two or more memory cells 100 that share a wordline) may share a sense element 1610 (e.g., a sense amplifier) of the sense circuit 1600. In some aspects, the first subset of memory cells (e.g., memory cells 100(1 to n₁)) may be operated by the NC sense elements 1610(1 to NC) of the sense circuit 1600 in a first time interval and the second subset of memory cells (e.g., memory cells 100(n₁+1 to 2·n₁+1)) may be operated by the NC sense elements 1610(1 to NC) of the sense circuit 1600 in a second time interval distinct from the first time interval.

Several aspects are described with reference to a structure (e.g., a memory capacitor that is a capacitive memory structure) and it is noted that such a structure may include solely the respective element (e.g., a capacitive memory); or, in other aspects, a structure may include the respective element and one or more additional elements.

The term “switch” may be used herein to describe a modification of the memory state a memory cell is residing in. For example, in the case that a memory cell is residing in a first memory state (e.g., a first remanent polarization state), the memory state the memory cell is residing in may be switched such that, after the switch, the memory cell may reside in a second memory state (e.g., a second remanent polarization state), different from the first memory state. The term “switch” may thus be used herein to describe a modification of the memory state a memory cell is residing in, from a first memory state to a second memory state. The term “switch” may also be used herein to describe a modification of a polarization, for example of a spontaneously polarizable memory element (e.g., of a spontaneously polarizable layer, such as a remanent-polarizable layer). For example, a polarization of a spontaneously polarizable memory element may be switched, such that the sign of the polarization varies from positive to negative or from negative to positive, while the absolute value of the polarization may remain in some aspects substantially unaltered. According to various aspects, writing a memory cell may include bringing the memory cell from one of at least two memory states into another one of the at least two memory states of the memory cell. In that case that a read operation is destructive, the read operation may include a write back operation to restore the read memory state after the destructive read operation.

The term “connected” may be used herein with respect to nodes, terminals, integrated circuit elements, and the like, to mean electrically connected, which may include a direct connection or an indirect connection, wherein an indirect connection may only include additional structures in the current path that do not influence the substantial functioning of the described circuit or device. The term “electrically conductively connected” that is used herein to describe an electrical connection between one or more terminals, nodes, regions, contacts, etc., may be understood as an electrically conductive connection with, for example, ohmic behavior, e.g., provided by a metal or degenerate semiconductor in absence of p-n junctions in the current path. The term “electrically conductively connected” may be also referred to as “galvanically connected”.

The term “coupled to” used herein with reference to functional parts of a memory cell (e.g., functional parts of a memory structure) that are coupled to respective nodes (e.g., plate-line node, bit-line node, and/or word-line node) of the memory cell may be understood as follows: the respective functional parts are electrically conductively connected to corresponding nodes and/or the respective functional parts itself provide the corresponding nodes. As an example, a source/drain node of a field-effect transistor access device may be electrically conductively connected to the bit-line and/or to the storage node of the memory cell 100. Therefore, in the case that the access device is open, the memory capacitor 120 (more particular the first electrode 126 of the memory capacitor 120 and/or storage node 104) of the memory cell 100 is electrically conductively connected to the bit-line.

The term “voltage” may be used herein with respect to “one or more bitline voltages”, “one or more wordline voltages”, “one or more plateline voltages”, “one or more control line voltages”, and the like. As an example, the term “base voltage” may be used herein to denote a reference voltage and/or a reference potential for the circuit. With respect to an electrical circuit, the base voltage may be also referred to as ground voltage, ground potential, virtual ground voltage, or zero volts (0 V). The base voltage of an electrical circuit may be defined by the power supply used to operate the electronic circuit. As another example, the term “control line voltage” may be used herein to denote a voltage that is provided to a control line, e.g., of a memory cell arrangement (for example a “wordline voltage” may be provided to a “wordline”, a “bitline voltage” may be provided to a bitline, and a “plateline voltage” may be provided to a plateline). The sign of a voltage difference (e.g., a voltage drop) may be defined as a potential inside a memory cell (e.g., at a first electrode portion) minus a potential at a second electrode portion of the memory cell.

Illustratively, a voltage provided to a node or a terminal may assume any suitable value depending on the intended operation of the circuit including the node or terminal. For example, a bitline voltage may be varied depending on the intended operation of the memory cell arrangement. Analogously, a wordline voltage, a plateline voltage, may be varied depending on the intended operation of a memory cell arrangement. A voltage provided to a node or terminal may be defined by the respective potential applied to that node or terminal relative to the base voltage of the circuit. Further, a voltage drop associated with two distinct nodes or terminals of a circuit may be defined by the respective voltages/potentials applied at the two nodes or terminals. As an example, a bitline voltage drop associated with a memory cell of a memory cell arrangement (e.g., an electrode of the memory cell) may be defined by the respective voltages/potentials applied at the corresponding memory cell (e.g., the electrode of the memory cell).

In some aspects, two voltages may be compared with one another by relative terms such as “greater”, “higher”, “lower”, “less”, or “equal”, for example. It is understood that, in some aspects, a comparison may include the sign (positive or negative) of the voltage value or, in other aspects, the absolute voltage values (also referred to as the magnitude, or as the amplitude, e.g., of a voltage pulse) are considered for the comparison.

The term “metal” or “metal material” may be used herein to describe a metal (e.g., a pure or substantially pure metal) or a mixture of more than one metal, viz. a metal alloy. A “metal” may be an intermetallic material. Illustratively, the term “metal” may be used herein to describe a material having an electrical conductivity typical of a metal. The term “metal material” may be used herein to describe a material having the Fermi level inside at least one band. Therefore, in some aspects, the term “metal” may refer to a metalloid (also referred to as half-metal or semi-metal).

The term “region” used with regards to a “source region”, “drain region”, “channel region”, and the like, may be used herein to mean a continuous region of a semiconductor portion (e.g., of a semiconductor wafer or a part of a semiconductor wafer, a semiconductor layer, a fin, a semiconductor nanosheet, a semiconductor nanowire, etc.,). In some aspects, the continuous region of a semiconductor portion may be provided by semiconductor material having only one dominant doping type.

The word “over”, used herein to describe forming a feature, e.g., a layer “over” a side or surface, may be used to mean that the feature, e.g., the layer, may be formed “directly on”, e.g., in direct contact with, the implied side or surface. The word “over”, used herein to describe forming a feature, e.g., a layer “over” a side or surface, may be used to mean that the feature, e.g., the layer, may be formed “indirectly on” the implied side or surface with one or more additional layers being arranged between the implied side or surface and the formed layer.

The term “lateral” used with regards to a lateral dimension (in other words a lateral extent) of a structure, a portion, a structure element, a layer, etc., provided, for example, over and/or in a carrier (e.g., a layer, a substrate, a wafer, etc.) or “laterally” next to, may be used herein to mean an extent or a positional relationship along a surface of the carrier. That means, in some aspects, that a surface of a carrier (e.g., a surface of a layer, a surface of a substrate, a surface of a wafer, etc.) may serve as reference, commonly referred to as the main processing surface.

According to various aspects, the properties and/or the structure of the memory element, an electrode, an electrically conductive electrode layer, and/or a functional layer as described herein may be evaluated with techniques known in the art. As an example, transmission electron microscopy (TEM) may be used to determine the structure of an electrode, for example the presence of one or more electrode layers and/or the presence of one or more functional layers in the electrode. TEM may be used for identifying a layer, an interface, a crystal structure, a microstructure, and other properties. As another example, X-ray crystallography (X-ray diffraction) may be used to determine various properties of a layer or a material, such as the crystal structure, the lattice properties, the size and shape of a unit cell, the chemical composition, the phase or alteration of the phase, the presence of stress in the crystal structure, the microstructure, and the like. As a further example, energy-dispersive X-ray spectroscopy (EDS) may be used to determine the chemical composition of a layer or a material, e.g. the presence and/or the content of an element in the layer or material. As a further example, Rutherford backscattering spectrometry (RBS) may be used to determine the structure and/or the composition of a material. As a further example, secondary ion mass spectrometry (SIMS) may be used to analyze the molecular composition of the upper monolayers of a solid, e.g. for analyzing the spatial distribution (e.g., the gradient) of an element across the solid.

A composition of a layer, a concentration of one or more materials within the layer, a composition of a layer, and/or a concentration of one or more materials within the spontaneously polarizable memory element, etc. may be determined with techniques known in the art. For example, energy-dispersive X-ray spectroscopy (EDS) (e.g., in combination with scanning electron microcopy (SEM) or transmission electron microscopy (TEM)), Rutherford backscattering spectrometry (RBS), and/or secondary ion mass spectrometry (SIMS) may be used to analyze the composition and/or concentration. However, the composition of the layer, the concentration of the one or more materials within the layer, the composition of the spontaneously polarizable memory element, and/or the concentration of the one or more materials within the spontaneously polarizable memory element may be also apparent from a manufacturing protocol for manufacturing the respective layer. For example, a layer may be manufactured by means of deposition, such as atomic layer deposition (ALD) and the respective composition and/or concentration may be directly apparent from the used deposition protocol (e.g., the used ALD deposition protocol).

The terms “at least one” and “one or more” may be understood to include any integer number greater than or equal to one, i.e. one, two, three, four, [ . . . ], etc. The term “a plurality” or “a multiplicity” may be understood to include any integer number greater than or equal to two, i.e. two, three, four, five, [ . . . ], etc. The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

The phrase “unambiguously assigned” may be used herein to mean a one-to-one-assignment (e.g., allocation, e.g., correspondence) or a bijective assignment. As an example, a first element being unambiguously assigned to a second element may include that the second element is unambiguously assigned to the first element. As another example, a first group of elements being unambiguously assigned to a second group of element may include that each element of the first group of elements is unambiguously assigned to a corresponding element of the second group of elements and that that corresponding element of the second group of elements is unambiguously assigned to the element of the first group of elements.

An “electrically conductive” connection or coupling, as described herein, may include a direct electrical connection or an indirect electrical connection, wherein an indirect connection may include additional structures in the current path that have no influence on the substantial functioning of the described circuit or device.

It is noted that one or more functions described herein with reference to a memory cell, a memory cell arrangement, etc., may be accordingly part of a method, e.g., part of a method for operating a memory cell arrangement. Vice versa, one or more functions described herein with reference to a method, e.g., with reference to a method for operating a memory cell arrangement, may be implemented accordingly in a device or in a part of a device, for example, in a memory cell, a memory cell arrangement, etc.

It is noted that various figures that include schematic views of control lines for operating the memory cells of the memory cell arrangement. For better recognition of the features shown in the figures, some of the control lines are not depicted; it is clear that various other control lines can be included in the memory cell arrangement to allow for the explained operation all memory cells similar to the operation of the memory cells with depicted control lines.

The following examples described various aspects of a memory chip (e.g., such as the memory chip 200 described herein) and/or aspects of one or more memory cell arrangements (e.g., such as the memory cell arrangements 101C, 101D, 101E described herein) and/or one or more memory cell arrays (e.g., such as the memory cell arrays 200a, 200b, 200c, 200d, 200e, 200f described herein).

Example 1 is a memory chip including: a memory stack including a plurality of memory cell layers stacked over one another along a stacking direction, wherein each of the plurality of memory capacitor layers includes one or more memory cell arrays such that the memory stack includes one or more three-dimensional memory cell arrays; a set of wordlines, a set of bitlines, and a set of platelines, wherein each memory cell of the one or more three-dimensional memory cell arrays is addressable by a corresponding wordline of the set of wordlines, a corresponding bitline of the set of bitlines, and a corresponding plateline of the set of platelines, and wherein each memory cell of the one or more three-dimensional memory cell arrays includes a memory capacitor that is elongated along an in-plane direction of the memory chip substantially perpendicular to the stacking direction; and wherein: (I) each wordline of the set of wordlines connects memory cells of the one or more three-dimensional memory cell arrays arranged along a wordline direction; (II) each bitline of the set of bitlines connects memory cells of the one or more three-dimensional memory cell arrays arranged along a bitline direction; (III) each plateline of the set of platelines connects memory cells of the one or more three-dimensional memory cell arrays arranged along a plateline direction; and/or (IV) at least one of the wordline direction, the bitline direction, and/or the plateline direction is substantially parallel to the stacking direction and substantially perpendicular to the in-plane direction.

In Example 2, the memory chip of example 1 may optionally further include that (e.g., to allow for an individual addressing of all memory cells of the one or more three-dimensional memory cell arrays) the wordline direction is substantially perpendicular to the bitline direction, and that both the wordline direction and the bitline direction are substantially perpendicular to the in-plane direction.

In Example 3, the memory chip of example 1 may optionally further include that the plateline direction is substantially parallel to the wordline direction and substantially perpendicular to the bitline direction; or that the plateline direction is substantially parallel to the bitline direction and substantially perpendicular to the wordline direction.

In Example 4, the memory chip of example 1 may optionally further include that (e.g., to allow for an individual addressing of all memory cells of the one or more three-dimensional memory cell arrays) the wordline direction is substantially parallel to the bitline direction and the plateline direction is substantially perpendicular to both the wordline direction and the bitline direction, and that the wordline direction, the bitline direction, and the plateline direction are substantially perpendicular to the in-plane direction.

In Example 5, the memory chip of example 1 may optionally further include that each memory cell of the one or more three-dimensional memory cell arrays includes an access device connected to the memory capacitor of the memory cell.

In Example 6, the memory chip of example 1 may optionally further include that each memory cell of the one or more three-dimensional memory cell arrays is operable (e.g., addressable) by a corresponding wordline of the set of wordlines connected to the access device of the memory cell and a corresponding bitline of the set of bitlines connected to the access device of the memory cell, and a corresponding plateline of the set of platelines connected to the memory capacitor of the memory cell.

In Example 7, the memory chip of example 6 may optionally further include that the access device includes a field-effect transistor structure. Furthermore, in this example, a gate of the field-effect transistor structure is connected to the corresponding wordline, and a channel of the field-effect transistor structure connects the corresponding bitline to the memory capacitor.

In Example 8, the memory chip of example 7 may optionally further include that the channel of the field-effect transistor structure is a polysilicon channel.

In Example 9, the memory chip of example 8 may optionally further include that a length of the polysilicon channel along the in-plane direction is less than 100 nm.

In Example 10, the memory chip of any one of examples 6 to 9 may optionally further include that the memory capacitor includes a first electrode connected to the corresponding bitline via the access device, that the memory capacitor includes a second electrode connected to the corresponding plateline, and that the memory capacitor includes a spontaneously polarizable memory layer disposed between the first electrode and the second electrode.

In Example 11, the memory chip of example 10 may optionally further include that the second electrode of each memory capacitor of a subset of memory capacitors form at least a part of a plateline to address the subset of memory cells corresponding to the plateline.

In Example 12, the memory chip of examples 10 or 11 may optionally further include that the spontaneously polarizable memory layer completely surrounds the first electrode with respect to a plane substantially perpendicular to the in-plane direction (IPD); and that the second electrode completely surrounds the spontaneously polarizable memory layer with respect to the plane substantially perpendicular to the in-plane direction.

In Example 13, the memory chip of examples 10 or 11 may optionally further include that the spontaneously polarizable memory layer completely surrounds the first electrode with respect to a plane substantially perpendicular to the in-plane direction; and that the second electrode only partially surrounds the spontaneously polarizable memory layer with respect to the plane substantially perpendicular to the in-plane direction.

In Example 14, the memory chip of examples 10 or 11 may optionally further include that the spontaneously polarizable memory layer only partially surrounds the first electrode with respect to a plane substantially perpendicular to the in-plane direction; and that the second electrode only partially surrounds the spontaneously polarizable memory layer with respect to the plane substantially perpendicular to the in-plane direction.

In Example 15, the memory chip of examples 10 or 11 may optionally further include that the spontaneously polarizable memory layer only partially surrounds the first electrode with respect to a plane substantially perpendicular to the in-plane direction; and that the second electrode completely surrounds the spontaneously polarizable memory layer with respect to the plane substantially perpendicular to the in-plane direction.

In Example 16, the memory chip of any one of examples 5 to 15 may optionally further include that the access device is configured to allow for an off-current through the access device of greater than 1012 ampere. In some aspects, the off-current through the access device can be higher than for a dielectric memory capacitor using dielectric charge storage since polarization of spontaneously polarizable (e.g., a remanent-polarizable) memory material creates sufficient switching charge and switching current for a read out stored permanently even in the case that the access device would be open.

In Example 17, the memory chip of any one of examples 1 to 16 may optionally further include that a first dimension of the memory capacitor along the in-plane direction is greater than a second dimension of the memory capacitor along the bitline direction and/or that the/a first dimension of the memory capacitor along the in-plane direction is greater than a third dimension of the memory capacitor along a direction substantially perpendicular to both the in-plane direction and the bitline direction.

In Example 18, the memory chip of any one of examples 1 to 17 may optionally further include that a first dimension of the memory capacitor along the in-plane direction is greater by at least a factor of 3 and less by a factor of 20 than a second dimension of the memory capacitor along the bitline direction and/or that the/a first dimension of the memory capacitor along the in-plane direction is greater by at least a factor of 3 and less by a factor of 20 than a third dimension of the memory capacitor along a direction substantially perpendicular to both the in-plane direction and the bitline direction.

In Example 19, the memory chip of examples 17 or 18 may optionally further include that the second dimension is different from the third dimension. In some aspects, the second dimension is less than the third dimension.

In Example 20, the memory chip of any one of examples 17 to 19 may optionally further include that the first dimension is greater than 30 nm and less than 900 nm.

In Example 21, the memory chip of any one of examples 17 to 20 may optionally further include that the second dimension is greater than 10 nm and less than 100 nm.

In Example 22, the memory chip of any one of examples 17 to 21 may optionally further include that the third dimension is greater than 10 nm and less than 200 nm.

In Example 23, the memory chip of any one of examples 1 to 22 may optionally further include that the memory capacitor is a spontaneously polarizable memory capacitor with a dielectric capacitance less than 10 fF and with an effective capacitance greater than 10 fF. The effective capacitance may be defined for example by ΔQ/ΔV and may include both dielectric polarization and spontaneous polarization.

In Example 24, the memory chip of any one of examples 1 to 23 may optionally further include that the memory capacitor is voltage switchable into at least two distinct memory states defined by at least two distinct remanent polarization states of a ferroelectric memory layer of the memory capacitor.

In Example 25, the memory chip of any one of examples 1 to 24 may optionally further include that the one or more three-dimensional memory cell arrays include a first memory cell array and a second memory cell array arranged laterally next to one another, that the first memory cell array and the second memory cell array each includes a number (SZ) of memory cell sub-arrays stacked over one another along a stacking direction substantially perpendicular to a main surface of the memory chip and that the in-plane direction is substantially parallel to the main surface of the memory chip.

In Example 26, the memory chip of example 25 may optionally further include that the wordline direction is substantially parallel to the main surface of the memory chip, and that the bitline direction is substantially perpendicular to the main surface of the memory chip and substantially parallel to the stacking direction.

In Example 27, the memory chip of examples 25 or 26 may optionally further include that a respective bitline of the set of bitlines is configured to operate both a first number (SZ1) of memory cells of the first memory cell array that equals the number (SZ) of memory cell sub-arrays and a second number (SZ2) of memory cells of the second memory cell array that equals the number (SZ) of memory cell sub-arrays.

In Example 28, the memory chip of example 25 may optionally further include that the bitline direction is substantially parallel to the main surface of the memory chip and that the wordline direction is substantially perpendicular to the main surface of the memory chip and substantially parallel to the stacking direction.

In Example 29, the memory chip of examples 25 or 28 may optionally further include that each wordline of the set of wordlines is configured to operate both a first number (SZ1) of memory cells of the first memory cell array that equals the number (SZ) of memory cell sub-arrays and a second number (SZ2) of memory cells of the second memory cell array that equals the number (SZ) of memory cell sub-arrays.

In Example 30, the memory chip of example 25 may optionally further include that at least one of the bitline direction and/or the wordline direction is substantially parallel to the main surface of the memory chip and that the plateline direction is substantially perpendicular to the main surface of the memory chip and substantially parallel to the stacking direction.

In Example 31, the memory chip of examples 25 or 30 may optionally further include that each plateline of the set of platelines is configured to operate both a first number (SZ1) of memory cells of the first memory cell array that equals the number (SZ) of memory cell sub-arrays and a second number (SZ2) of memory cells of the second memory cell array that equals the number (SZ) of memory cell sub-arrays.

In Example 32, the memory chip of any one of examples 25 to 31 may optionally further include that each wordline of the set of wordlines is connected to a first number (SW1) of memory cells of the first memory cell array and to a second number (SW2) of memory cells of the second memory cell array.

In Example 33, the memory chip of example 32 may optionally further include that both the first number (SW1) of memory cells of the first memory cell array and the second number (SW2) of memory cells of the second memory cell array are greater than the number (SZ) of memory cell sub-arrays.

In Example 34, the memory chip of examples 32 or 33 may optionally further include that the first number (SW1) of memory cells of the first memory cell array equals the second number (SW2) of memory cells of the second memory cell array.

In Example 35, the memory chip of any one of examples 25 to 34 may optionally further include that each bitline of the set of bitlines is connected to a first number (SB1) of memory cells of the first memory cell array and to a second number (SB2) of memory cells of the second memory cell array.

In Example 36, the memory chip of example 35 may optionally further include that both the first number (SB1) of memory cells of the first memory cell array and the second number (SB2) of memory cells of the second memory cell array are greater than the number (SZ) of memory cell sub-arrays.

In Example 37, the memory chip of examples 35 or 36 may optionally further include that the first number (SB1) of memory cells of the first memory cell array equals the second number (SB2) of memory cells of the second memory cell array.

In Example 38, the memory chip of any one of examples 25 to 37 may optionally further include that each plateline of the set of platelines is connected to a first number (SP1) of memory cells of the first memory cell array and to a second number (SP2) of memory cells of the second memory cell array.

In Example 39, the memory chip of example 38 may optionally further include that both the first number (SP1) of memory cells of the first memory cell array and the second number (SP2) of memory cells of the second memory cell array are greater than the number (SZ) of memory cell sub-arrays.

In Example 40, the memory chip of examples 38 or 39 may optionally further include that the first number (SP1) of memory cells of the first memory cell array equals the second number (SP2) of memory cells of the second memory cell array.

In Example 41, the memory chip of any one of examples 1 to 40 may optionally further include: a sense circuit associated with the one or more three-dimensional memory cell arrays, wherein the sense circuit includes a total number (NC) of sense elements associated with the set of bitlines. Furthermore, a total number (NM) of memory cells of the one or more three-dimensional memory cell arrays share a very same wordline of the set of wordlines and are connected to a total number (NB) of bitlines of the set of bitlines, and the total number (NC) of sense elements is less than the total number (NB) of bitlines connected to the total number (NM) of memory cells of the one or more three-dimensional memory cell arrays that share the very same wordline.

In Example 42, the memory chip of example 41 may optionally further include that each sense element of the set of sense elements includes a sense amplifier.

In Example 43, the memory chip of any one of examples 1 to 42 may optionally further include that all memory cells of the one or more three-dimensional memory cell arrays that are connected to a very same wordline of the set of wordlines are connected to a very same plateline of the set of platelines.

In Example 44, the memory chip of any one of examples 1 to 42 may optionally further include that all memory cells of the one or more three-dimensional memory cell arrays that are connected to a very same wordline of the set of wordlines are connected to two or more platelines of the set of platelines.

In Example 45, the memory chip of any one of examples 1 to 44 may optionally further include that a first subset of memory cells of the one or more three-dimensional memory cell arrays and a second subset of memory cells of one or more three-dimensional memory cell arrays are operated by a very same wordline of the set of wordlines, and that all memory cells of the first subset of memory cells are connected to a first plateline of the set of platelines and wherein all memory cells of the second subset of memory cells are connected to a second plateline of the set of platelines.

In Example 46, the memory chip of example 45 may optionally further include that the first subset of memory cells and the second subset of memory cells operated by the very same wordline each includes a plurality of memory cells of the set memory cells.

In Example 47, the memory chip of any one of examples 1 to 46 may optionally further include that the memory stack includes a first number of memory cell sub-arrays stacked over one another along a stacking direction, a second number of memory cell sub-arrays arranged next to one another along the in-plane direction, and a third number of memory cell sub-arrays arranged next to one another along a direction substantially perpendicular to both the stacking direction and the in-plane direction, wherein the first number of memory cell sub-arrays is less than both the second number of memory cell sub-arrays and the third number of memory cell sub-arrays.

In Example 48, the memory chip of any one of examples 1 to 47 may optionally further include that the memory stack is configured as a memory sector of the memory chip sharing a sense circuit to operate all memory cells of the memory stack.

Example 51 is a memory chip including: a set of wordlines defining a wordline direction, a set of bitlines defining a bitline direction, a set of platelines defining a plateline direction, and a set of memory cells, wherein each memory cell of the set of memory cells is addressable by a corresponding wordline of the set of wordlines, a corresponding bitline of the set of bitlines, and a corresponding plateline of the set of platelines, and wherein each memory cell of the set of memory cells includes a memory capacitor that is elongated along an in-plane direction of the memory chip; and wherein (I) (e.g., to allow for an individual operation of memory cells selected by the wordline/bitline pair and the plateline) the wordline direction is substantially perpendicular to the bitline direction and the plateline direction is substantially parallel to the bitline direction, and wherein the wordline direction, the bitline direction, and the plateline direction are substantially perpendicular to the in-plane direction; or (II) (e.g., to allow for a subset wise switching of memory cells to operate memory cells that share a wordline/bitline pair) the wordline direction is substantially perpendicular to the bitline direction and the plateline direction is substantially parallel to the wordline direction, and wherein the wordline direction, the bitline direction, and the plateline direction are substantially perpendicular to the in-plane direction; or (III) (e.g., to allow for an individual operation of memory cells selected by the wordline/plateline pair, wherein an inhibition scheme can be applied to not switch other memory cells than the memory cells to be operated) the wordline direction is substantially parallel to the bitline direction and the plateline direction is substantially perpendicular to both the wordline direction and the bitline direction, and wherein the wordline direction, the bitline direction, and the plateline direction are substantially perpendicular to the in-plane direction.

In Example 52, the memory chip of example 51 may optionally further include that each memory cell of the set of memory cells includes an access device connected to the memory capacitor of the memory cell.

In Example 53, the memory chip of example 52 may optionally further include that each memory cell of the set of memory cells is operable (e.g., addressable) by (I) a corresponding wordline of the set of wordlines connected to the access device of the memory cell and by (II) a corresponding bitline of the set of bitlines connected to the access device of the memory cell and by (III) a corresponding plateline of the set of platelines connected to the memory capacitor of the memory cell.

In Example 54, the memory chip of example 53 may optionally further include that the access device includes a field-effect transistor structure, wherein a gate of the field-effect transistor structure is connected to the corresponding wordline and wherein a channel of the field-effect transistor structure connects the corresponding bitline to the memory capacitor.

In Example 55, the memory chip of example 54 may optionally further include that the channel of the field-effect transistor structure is a polysilicon channel.

In Example 56, the memory chip of example 55 may optionally further include that a length of the polysilicon channel along the in-plane direction is less than 100 nm (e.g., less than 80 nm, e.g., less than 60 nm). A reduced channel length may allow for a higher lateral integration density considering the alignment of the memory capacitors as described herein.

In Example 57, the memory chip of any one of examples 53 to 56 may optionally further include that the memory capacitor includes a first electrode connected to the corresponding bitline via the access device, that the memory capacitor includes a second electrode connected to the corresponding plateline, and that the memory capacitor includes a spontaneously polarizable memory layer disposed between the first electrode and the second electrode.

In Example 58, the memory chip of example 57 may optionally further include that the spontaneously polarizable memory layer completely surrounds the first electrode with respect to a plane substantially perpendicular to the in-plane direction (IPD); and that the second electrode completely surrounds the spontaneously polarizable memory layer with respect to the plane substantially perpendicular to the in-plane direction.

In Example 59, the memory chip of example 57 may optionally further include that the spontaneously polarizable memory layer completely surrounds the first electrode with respect to a plane substantially perpendicular to the in-plane direction; and that the second electrode only partially surrounds the spontaneously polarizable memory layer with respect to the plane substantially perpendicular to the in-plane direction.

In Example 60, the memory chip of example 57 may optionally further include that the spontaneously polarizable memory layer only partially surrounds the first electrode with respect to a plane substantially perpendicular to the in-plane direction; and that the second electrode only partially surrounds the spontaneously polarizable memory layer with respect to the plane substantially perpendicular to the in-plane direction.

In Example 61, the memory chip of example 57 may optionally further include that the spontaneously polarizable memory layer only partially surrounds the first electrode with respect to a plane substantially perpendicular to the in-plane direction; and that the second electrode completely surrounds the spontaneously polarizable memory layer with respect to the plane substantially perpendicular to the in-plane direction.

In Example 62, the memory chip of any one of examples 52 to 61 may optionally further include that the access device is configured to allow for an off-current through the access device of greater than 10-12 ampere.

In Example 63, the memory chip of any one of examples 51 to 62 may optionally further include that a first dimension of the memory capacitor along the in-plane direction is greater than both a second dimension of the memory capacitor along the wordline direction and a third dimension of the memory capacitor along the bitline direction.

In Example 64, the memory chip of any one of examples 51 to 63 may optionally further include that a first dimension of the memory capacitor along the in-plane direction is greater by at least a factor of 3 and less by a factor of 20 than both a second dimension of the memory capacitor along a first direction substantially perpendicular to the in-plane direction and a third dimension of the memory capacitor along a second direction substantially perpendicular to the in-plane direction different from (e.g., substantially perpendicular to) the first direction.

In Example 65, the memory chip of examples 63 or 64 may optionally further include that the second dimension is different from (e.g., less than) the third dimension.

In Example 66, the memory chip of any one of examples 63 to 65 may optionally further include that the first dimension is greater than 30 nm and less than 900 nm.

In Example 67, the memory chip of any one of examples 63 to 66 may optionally further include that the second dimension is greater than 10 nm and less than 100 nm.

In Example 68, the memory chip of any one of examples 63 to 66 may optionally further include that the third dimension is greater than 10 nm and less than 200 nm.

In Example 69, the memory chip of any one of examples 63 to 68 may optionally further include that the memory capacitor is a spontaneously polarizable memory capacitor with a dielectric capacitance less than 10 fF and with an effective capacitance greater than 10 fF.

In Example 70, the memory chip of any one of examples 51 to 69 may optionally further include that the memory capacitor is voltage switchable into at least two distinct memory states defined by at least two distinct remanent polarization states of a ferroelectric memory layer of the memory capacitor.

In Example 71, the memory chip of any one of examples 51 to 70 may optionally further include that the set of memory cells includes a first memory cell array and a second memory cell array arranged laterally next to one another, wherein the first memory cell array and the second memory cell array each includes a number (SZ) of memory cell sub-arrays stacked over one another along a stacking direction substantially perpendicular to a main surface of the memory chip and wherein the in-plane direction is substantially parallel to the main surface of the memory chip.

In Example 72, the memory chip of example 71 may optionally further include that the wordline direction is substantially parallel to the main surface of the memory chip, and that the bitline direction is substantially perpendicular to the main surface of the memory chip and substantially parallel to the stacking direction.

In Example 73, the memory chip of example 71 or 72 may optionally further include that a respective bitline of the set of bitlines is configured to operate both a first number (SZ1) of memory cells of the first memory cell array that equals the number (SZ) of memory cell sub-arrays and a second number (SZ2) of memory cells of the second memory cell array that equals the number (SZ) of memory cell sub-arrays.

In Example 74, the memory chip of example 71 may optionally further include that the bitline direction is substantially parallel to the main surface of the memory chip and wherein the wordline direction is substantially perpendicular to the main surface of the memory chip and substantially parallel to the stacking direction.

In Example 75, the memory chip of example 74 may optionally further include that each wordline of the set of wordlines is configured to operate both a first number (SZ1) of memory cells of the first memory cell array that equals the number (SZ) of memory cell sub-arrays and a second number (SZ2) of memory cells of the second memory cell array that equals the number (SZ) of memory cell sub-arrays.

In Example 76, the memory chip of example 71 may optionally further include that at least one of the bitline direction and/or the wordline direction is substantially parallel to the main surface of the memory chip and wherein the plateline direction is substantially perpendicular to the main surface of the memory chip and substantially parallel to the stacking direction.

In Example 77, the memory chip of example 76 may optionally further include that each plateline of the set of platelines is configured to operate both a first number (SZ1) of memory cells of the first memory cell array that equals the number (SZ) of memory cell sub-arrays and a second number (SZ2) of memory cells of the second memory cell array that equals the number (SZ) of memory cell sub-arrays.

In Example 78, the memory chip of any one of examples 71 to 77 may optionally further include that each wordline of the set of wordlines is connected to a first number (SW1) of memory cells of the first memory cell array and to a second number (SW2) of memory cells of the second memory cell array.

In Example 79, the memory chip of example 78 may optionally further include that both the first number (SW1) of memory cells of the first memory cell array and the second number (SW2) of memory cells of the second memory cell array are greater than the number (SZ) of memory cell sub-arrays.

In Example 80, the memory chip of examples 78 or 79 may optionally further include that the first number (SW1) of memory cells of the first memory cell array equals the second number (SW2) of memory cells of the second memory cell array.

In Example 81, the memory chip of any one of examples 71 to 80 may optionally further include that each bitline of the set of bitlines is connected to a first number (SB1) of memory cells of the first memory cell array and to a second number (SB2) of memory cells of the second memory cell array.

In Example 82, the memory chip of any example 81 may optionally further include that both the first number (SB1) of memory cells of the first memory cell array and the second number (SB2) of memory cells of the second memory cell array are greater than the number (SZ) of memory cell sub-arrays.

In Example 83, the memory chip of examples 81 or 82 may optionally further include that the first number (SB1) of memory cells of the first memory cell array equals the second number (SB2) of memory cells of the second memory cell array.

In Example 84, the memory chip of any one of examples 71 to 83 may optionally further include that each plateline of the set of platelines is connected to a first number (SP1) of memory cells of the first memory cell array and to a second number (SP2) of memory cells of the second memory cell array.

In Example 85, the memory chip of example 84 may optionally further include that both the first number (SP1) of memory cells of the first memory cell array and the second number (SP2) of memory cells of the second memory cell array are greater than the number (SZ) of memory cell sub-arrays.

In Example 86, the memory chip of examples 84 or 85 may optionally further include that the first number (SP1) of memory cells of the first memory cell array equals the second number (SP2) of memory cells of the second memory cell array.

In Example 87, the memory chip of any one of examples 51 to 86 may optionally further include: a sense circuit associated with the set of memory cells, wherein the sense circuit includes a total number (NC) of sense elements associated with the set of bitlines. Furthermore, a total number (NM) of memory cells of the set of memory cells share a very same wordline of the set of wordlines and are connected to a total number (NB) of bitlines of the set of bitlines, and the total number (NC) of sense elements is less than the total number (NB) of bitlines connected to the total number (NM) of memory cells of the set of memory cells that share the very same wordline.

In Example 88, the memory chip of example 87 may optionally further include that each sense element of the set of sense elements includes a sense amplifier.

In Example 89, the memory chip of any one of examples 51 to 88 may optionally further include that all memory cells of the set of memory cells that are connected to a very same wordline of the set of wordlines are connected to a very same plateline of the set of platelines.

In Example 90, the memory chip of any one of examples 51 to 88 may optionally further include that all memory cells of the set of memory cells that are connected to a very same wordline of the set of wordlines are connected to two or more platelines of the set of platelines.

In Example 91, the memory chip of any one of examples 51 to 90 may optionally further include that a first subset of memory cells of the set of memory cells and a second subset of memory cells of the set of memory cells are operated by a very same wordline of the set of wordlines, and that all memory cells of the first subset of memory cells are connected to a first plateline of the set of platelines and wherein all memory cells of the second subset of memory cells are connected to a second plateline of the set of platelines.

In Example 92, the memory chip of example 91 may optionally further include that the first subset of memory cells and the second subset of memory cells operated by the very same wordline each includes a plurality of memory cells of the set memory cells.

In Example 93, the memory chip of any one of examples 51 to 92 may optionally further include that the set of memory cells includes a first number of memory cell sub-arrays stacked over one another along a stacking direction, a second number of memory cell sub-arrays arranged next to one another along the in-plane direction, and a third number of memory cell sub-arrays arranged next to one another along a direction substantially perpendicular to both the stacking direction and the in-plane direction. In some aspects, the first number of memory cell sub-arrays is less than both the second number of memory cell sub-arrays and the third number of memory cell sub-arrays.

In Example 94, the memory chip of any one of examples 51 to 93 may optionally further include that the set of memory cells is configured as a memory sector of the memory chip sharing a sense circuit to operate all memory cells of the memory stack.

Example 95 is a memory chip including: a memory stack including a plurality of memory cell layers stacked over one another along a stacking direction, wherein each of the plurality of memory capacitor layers includes one or more memory cell arrays such that the memory stack includes one or more three-dimensional memory cell arrays; a set of bitlines and a set of platelines, wherein each memory cell of the one or more three-dimensional memory cell arrays is addressable by a corresponding bitline of the set of bitlines and a corresponding plateline of the set of platelines, and wherein each memory cell of the one or more three-dimensional memory cell arrays includes a memory capacitor that is elongated along an in-plane direction of the memory chip substantially perpendicular to the stacking direction; and wherein each bitline of the set of bitlines connects memory cells of the one or more three-dimensional memory cell arrays arranged along a bitline direction and each plateline of the set of platelines connects memory cells of the one or more three-dimensional memory cell arrays arranged along a plateline direction substantially perpendicular to the bitline direction; and wherein the bitline direction or the plateline direction is substantially parallel to the in-plane direction.

While the invention has been particularly shown and described with reference to specific aspects, it should be understood by those skilled in the art that various changes in form and detail may be made therein without departing from the spirit and scope of the invention as defined by the appended claims. The scope of the invention is thus indicated by the appended claims and all changes, which come within the meaning and range of equivalency of the claims, are therefore intended to be embraced.

What is claimed is:

1. A memory chip comprising:
a memory stack comprising a plurality of memory cell layers stacked over one another along a stacking direction, wherein each of the plurality of memory capacitor layers comprises one or more memory cell arrays such that the memory stack comprises one or more three-dimensional memory cell arrays;
a set of wordlines, a set of bitlines, and a set of platelines, wherein each memory cell of the one or more three-dimensional memory cell arrays is addressable by a corresponding wordline of the set of wordlines, a corresponding bitline of the set of bitlines, and a corresponding plateline of the set of platelines, and wherein each memory cell of the one or more three-dimensional memory cell arrays comprises a memory capacitor that is elongated along an in-plane direction of the memory chip substantially perpendicular to the stacking direction; and wherein:
each wordline of the set of wordlines connects memory cells of the one or more three-dimensional memory cell arrays arranged along a wordline direction;
each bitline of the set of bitlines connects memory cells of the one or more three-dimensional memory cell arrays arranged along a bitline direction;
each plateline of the set of platelines connects memory cells of the one or more three-dimensional memory cell arrays arranged along a plateline direction; and
at least one of the wordline direction, the bitline direction, and/or the plateline direction is substantially parallel to the stacking direction and substantially perpendicular to the in-plane direction.

2. The memory chip of claim 1,
wherein the wordline direction is substantially perpendicular to the bitline direction, and both the wordline direction and the bitline direction are substantially perpendicular to the in-plane direction.

3. The memory chip of claim 2,
wherein the plateline direction is substantially parallel to the wordline direction and substantially perpendicular to the bitline direction; or
wherein the plateline direction is substantially parallel to the bitline direction and substantially perpendicular to the wordline direction.

4. The memory chip of claim 1,
wherein the wordline direction is substantially parallel to the bitline direction and the plateline direction is substantially perpendicular to both the wordline direction and the bitline direction, and
wherein the wordline direction, the bitline direction, and the plateline direction are substantially perpendicular to the in-plane direction.

5. The memory chip of claim 1,
wherein each memory cell of the one or more three-dimensional memory cell arrays comprises an access device connected to the memory capacitor of the memory cell.

6. The memory chip of claim 5,
wherein each memory cell of the one or more three-dimensional memory cell arrays is operable by a corresponding wordline of the set of wordlines connected to the access device of the memory cell and a corresponding bitline of the set of bitlines connected to the access device of the memory cell, and a corresponding plateline of the set of platelines connected to the memory capacitor of the memory cell.

7. The memory chip of claim 6,
wherein the access device comprises a field-effect transistor structure, wherein a gate of the field-effect transistor structure is connected to the corresponding wordline, and wherein a channel of the field-effect transistor structure connects the corresponding bitline to the memory capacitor.

8. The memory chip of claim 7,
wherein the channel of the field-effect transistor structure is a polysilicon channel, and
wherein a length of the polysilicon channel along the in-plane direction is less than 100 nm.

9. The memory chip of claim 6,
wherein the memory capacitor comprises a first electrode connected to the corresponding bitline via the access device,
wherein the memory capacitor comprises a second electrode connected to the corresponding plateline, and
wherein the memory capacitor comprises a spontaneously polarizable memory layer disposed between the first electrode and the second electrode.

10. The memory chip of claim 9,
wherein the spontaneously polarizable memory layer completely surrounds the first electrode with respect to a plane substantially perpendicular to the in-plane direction and the second electrode completely surrounds the spontaneously polarizable memory layer with respect to the plane substantially perpendicular to the in-plane direction; or
wherein the spontaneously polarizable memory layer completely surrounds the first electrode with respect to a plane substantially perpendicular to the in-plane direction and the second electrode only partially surrounds the spontaneously polarizable memory layer with respect to the plane substantially perpendicular to the in-plane direction; or
wherein the spontaneously polarizable memory layer only partially surrounds the first electrode with respect to a plane substantially perpendicular to the in-plane direction and the second electrode only partially surrounds the spontaneously polarizable memory layer with respect to the plane substantially perpendicular to the in-plane direction; or
wherein the spontaneously polarizable memory layer only partially surrounds the first electrode with respect to a plane substantially perpendicular to the in-plane direction and the second electrode completely surrounds the spontaneously polarizable memory layer with respect to the plane substantially perpendicular to the in-plane direction.

11. The memory chip of claim 1,
wherein a first dimension of the memory capacitor along the in-plane direction is greater than both a second dimension of the memory capacitor along the bitline direction and a third dimension of the memory capacitor along a direction substantially perpendicular to both the in-plane direction and the bitline direction.

12. The memory chip of claim 11,
wherein the second dimension is different from the third dimension.

13. The memory chip of claim 1,
wherein a first dimension of the memory capacitor along the in-plane direction is less than 35 times of a second dimension of the memory capacitor substantially perpendicular to the in-plane direction and wherein the second dimension is less than 65 nm; or
wherein a first dimension of the memory capacitor along the in-plane direction is less than 50 times of a second dimension of the memory capacitor substantially perpendicular to the in-plane direction and wherein the second dimension is less than 45 nm; or
wherein a first dimension of the memory capacitor along the in-plane direction is less than 100 times of a second dimension of the memory capacitor substantially perpendicular to the in-plane direction and wherein the second dimension is less than 35 nm.

14. The memory chip of claim 13,
wherein the memory capacitor is a spontaneously polarizable memory capacitor with a dielectric capacitance less than 10 fF and with an effective capacitance greater than 10 fF.

15. The memory chip of claim 1,
wherein the one or more three-dimensional memory cell arrays comprise a first memory cell array and a second memory cell array arranged laterally next to one another,
wherein the first memory cell array and the second memory cell array each comprises a number of memory cell sub-arrays stacked over one another along a stacking direction substantially perpendicular to a main surface of the memory chip and wherein the in-plane direction is substantially parallel to the main surface of the memory chip.

16. The memory chip of claim 15,
wherein a respective bitline of the set of bitlines is configured to operate both a first number of memory cells of the first memory cell array that equals the number of memory cell sub-arrays and a second number of memory cells of the second memory cell array that equals the number of memory cell sub-arrays; or
wherein each wordline of the set of wordlines is configured to operate both a first number of memory cells of the first memory cell array that equals the number of memory cell sub-arrays and a second number of memory cells of the second memory cell array that equals the number of memory cell sub-arrays; or
wherein each plateline of the set of platelines is configured to operate both a first number of memory cells of the first memory cell array that equals the number of memory cell sub-arrays and a second number of memory cells of the second memory cell array that equals the number of memory cell sub-arrays.

17. The memory chip of claim 15,
wherein each wordline of the set of wordlines is connected to a first number of memory cells of the first memory cell array and to a second number of memory cells of the second memory cell array; and/or
wherein each bitline of the set of bitlines is connected to a first number of memory cells of the first memory cell array and to a second number of memory cells of the second memory cell array; and/or
wherein each plateline of the set of platelines is connected to a first number of memory cells of the first memory cell array and to a second number of memory cells of the second memory cell array.

18. The memory chip of claim 1, further comprising:
a sense circuit associated with the one or more three-dimensional memory cell arrays, wherein the sense circuit comprises a total number of sense elements associated with the set of bitlines;
wherein a total number of memory cells of the one or more three-dimensional memory cell arrays share a very same wordline of the set of wordlines and are connected to a total number of bitlines of the set of bitlines, and
wherein the total number of sense elements is less than the total number of bitlines connected to the total number of memory cells of the one or more three-dimensional memory cell arrays that share the very same wordline.

19. A memory chip comprising:
a set of wordlines defining a wordline direction, a set of bitlines defining a bitline direction, a set of platelines defining a plateline direction, and a set of memory cells, wherein each memory cell of the set of memory cells is addressable by a corresponding wordline of the set of wordlines, a corresponding bitline of the set of bitlines, and a corresponding plateline of the set of platelines, and wherein each memory cell of the set of memory cells comprises a memory capacitor that is elongated along an in-plane direction of the memory chip; and wherein:
the wordline direction is substantially perpendicular to the bitline direction and the plateline direction is substantially parallel to the bitline direction, and wherein the wordline direction, the bitline direction, and the plateline direction are substantially perpendicular to the in-plane direction; or
the wordline direction is substantially perpendicular to the bitline direction and the plateline direction is substantially parallel to the wordline direction, and wherein the wordline direction, the bitline direction, and the plateline direction are substantially perpendicular to the in-plane direction; or
the wordline direction is substantially parallel to the bitline direction and the plateline direction is substantially perpendicular to both the wordline direction and the bitline direction, and wherein the wordline direction, the bitline direction, and the plateline direction are substantially perpendicular to the in-plane direction.

20. A memory chip comprising:
a memory stack comprising a plurality of memory cell layers stacked over one another along a stacking direction, wherein each of the plurality of memory capacitor layers comprises one or more memory cell arrays such that the memory stack comprises one or more three-dimensional memory cell arrays;
a set of bitlines and a set of platelines, wherein each memory cell of the one or more three-dimensional memory cell arrays is addressable by a corresponding bitline of the set of bitlines and a corresponding plateline of the set of platelines, and wherein each memory cell of the one or more three-dimensional memory cell arrays comprises a memory capacitor that is elongated along an in-plane direction of the memory chip substantially perpendicular to the stacking direction; and wherein each bitline of the set of bitlines connects memory cells of the one or more three-dimensional memory cell arrays arranged along a bitline direction and each plateline of the set of platelines connects memory cells of the one or more three-dimensional memory cell arrays arranged along a plateline direction substantially perpendicular to the bitline direction; and wherein the bitline direction or the plateline direction is substantially parallel to the in-plane direction.
